(19) United States
(12) Patent Application Publication
(10) Pub. No.: US 2022/0119686 A1
(43) Pub. Date: Apr. 21, 2022

(54) PRESSURE SENSITIVE ADHESIVE SHEET, LAMINATE, DISPLAY DEVICE, AND ORGANIC ELECTROLUMINESCENT DISPLAY DEVICE

(71) Applicant: FUJIFILM Corporation, Tokyo (JP)

(72) Inventors: Naoya SHIBATA, Kanagawa (JP); Takashi KATOU, Kanagawa (JP)

(73) Assignee: FUJIFILM Corporation, Tokyo (JP)

(21) Appl. No.: 17/563,614

(22) Filed: Dec. 28, 2021

Related U.S. Application Data
(63) Continuation of application No. PCT/JP2020/025522, filed on Jun. 29, 2020.

(30) Foreign Application Priority Data
Jul. 9, 2019 (JP) 2019-127934
Sep. 27, 2019 (JP) 2019-176626

(51) Int. Cl. C09J 7/38; C09J 133/10; C09K 19/04; G02B 5/30

(52) U.S. Cl. CPC C09J 7/385; C09J 133/10; C09K 19/04; C09J 2301/302; C09J 2203/326; C09J 2203/318; C09K 2019/0448; G02B 5/3016

(57) ABSTRACT

Provided is a pressure sensitive adhesive sheet having excellent light resistance (particularly, excellent light resistance for light having a wavelength of 370 to 400 nm), a laminate, a display device, and an organic EL display device. The pressure sensitive adhesive sheet includes a (meth)acrylic pressure sensitive adhesive and a compound represented by Formula (I), in which the (meth)acrylic pressure sensitive adhesive is formed of a (meth)acrylic resin, and an absolute value of a difference between a log P value of the (meth)acrylic resin and a log P value of the compound represented by Formula (I) is 2.50 or more.

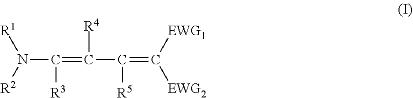

### CROSS-REFERENCE TO RELATED APPLICATIONS

This application is a Continuation of PCT International Application No. PCT/JP2020/025522 filed on Jun. 29, 2020, which claims priority under 35 U.S.C. § 119(a) to Japanese Patent Application No. 2019-127934 filed on Jul. 9, 2019 and Japanese Patent Application No. 2019-176626 filed on Sep. 27, 2019. Each of the above applications is hereby expressly incorporated by reference, in its entirety, into the present application.

### BACKGROUND OF THE INVENTION

### 1. Field of the Invention

The present invention relates to a pressure sensitive adhesive sheet, a laminate, a display device, and an organic electroluminescent display device.

### 2. Description of the Related Art

A variety of members including a display element such as an organic electroluminescent (hereinafter, referred to simply as “EL”) display element or a liquid crystal cell, and an optical film such as a polarizing plate are used in a display device (flat panel display: FPD) such as an organic EL display device or a liquid crystal display device. Since an organic EL compound, a liquid crystal compound, or the like used for these members is an organic substance, deterioration thereof due to ultraviolet rays (UV) tends to be a problem. In particular, a liquid crystal compound exhibiting reverse wavelength dispersibility is inferior in light resistance and therefore tends to be easily decomposed by ultraviolet rays.

In order to solve such a problem, measures such as adding an ultraviolet absorber to a protective film of the polarizing plate used in the display device are taken. For example, JP2006-308936A discloses a polarizing plate to which an ultraviolet absorber having an excellent ability to absorb ultraviolet rays in a wavelength range of 370 nm or shorter, but having a small absorption of visible light of 400 nm or longer is added so as not to affect the display.

In addition, with the progress of thinning of display devices in recent years, there are cases where a thinned protective film is used and cases where an optical film having a polarizing plate without a protective film is used.

In such a protective film and such an optical film, it is necessary to formulate an ultraviolet absorber, which has been conventionally added to the protective film, into another member. For example, it is conceivable to apply an ultraviolet absorber to a pressure sensitive adhesive sheet.

On the other hand, JP2017-119700A discloses that a light selective absorption compound having a merocyanine structure (corresponding to an ultraviolet absorber) has a high absorbance tor light in a short wavelength range of 370 to 410 am, exhibits an excellent affinity in a composition for forming a pressure sensitive adhesive sheet, and is difficult to bleed out.

### SUMMARY OF THE INVENTION

It has conventionally been considered that various members constituting a display device are deteriorated by ultraviolet rays in a wavelength range of 370 nm or shorter, but it has become clear that the performance deterioration progresses even with light in a wavelength range of 370 to 400 am, in addition to ultraviolet rays having a wavelength of 370 nm or shorter. Therefore, an optical film such as a polarizing plate containing an optically anisotropic layer is required to have absorption characteristics particularly for light in the vicinity of 370 to 400 nm, in addition to ultraviolet rays having a wavelength of 370 nm or shorter.

On the other hand, according to the studies by the present inventors, the polarizing plate disclosed in JP2006-308936A had low absorption characteristics for light in the vicinity of 370 to 400 nm, and was not always satisfactory in terms of light resistance of a member (particularly, an optically anisotropic layer).

In addition, it was found that, even in a case of a pressure sensitive adhesive sheet containing a merocyanine compound having a high absorbance for light in the vicinity of 370 to 400 nm, a photodurabilily of the merocyanine compound itself was not sufficient depending on the combination with a (meth)acrylic resin used in a case of forming the pressure sensitive adhesive sheet. Therefore, there is a problem that the optical characteristics of an optically anisotropic layer change in a case where the pressure sensitive adhesive sheet is used in combination with the optically anisotropic layer and the optically anisotropic layer is irradiated with ultraviolet rays through the pressure sensitive adhesive sheet.

In view of the above circumstances, an object of the present invention, is to provide a pressure sensitive adhesive sheet having excellent light resistance (particularly, excellent light resistance for light having a wavelength of 370 to 400 run).

Another object of the present invention is to provide a laminate, a display device, and an organic EL display device.

As a result of extensive studies, the present inventors have found that the foregoing objects can be achieved by the following configurations.

(1) A pressure sensitive adhesive sheet comprising:

a (meth)acrylic pressure sensitive adhesive; and

a compound represented by Formula (I) which will be described later,

in which the (meth)acrylic pressure sensitive adhesive is formed of a (meth)acrylic resin, and

an absolute value of a difference between a log P value of the (meth)acrylic resin and a log P value of the compound represented by Formula (I) is 2.50 or more.

(2) The pressure sensitive adhesive sheet according to (1), in which the absolute value of the difference is 3.50 or more.

(3) The pressure sensitive adhesive sheet according to (1) or (2), in which a maximal absorption wavelength of the compound represented by Formula (I) is in a range of 365 to 385 nm.

(4) The pressure sensitive adhesive sheet according to any one of (1) to (3), in which a content of the compound represented by Formula (I) is 2.5% to 30% by mass with respect to a total mass of the (meth)acrylic resin.

(5) The pressure sensitive adhesive sheet according to any one of (1) to (4), in which a content of the compound represented by Formula (I) is 5.5% to 20% by mass with respect to a total mass of the (meth)acrylic resin.

(6) The pressure sensitive adhesive sheet according to any one of (1) to (5), in which EWG₁ and EWG₂ each independently represent COOR⁶, SO₂R⁷, CN, or COR⁸, and R⁶, R⁷, and R⁸ each independently represent an alkyl group, an aryl group, or a heteroaryl group.

(7) The pressure sensitive adhesive sheet according to any one of (1) to (6), in which EWG₁ represents SO₂R⁷, EWG₂ represents COOR⁶, and R⁶ and R⁷ each independently represent an alkyl group, an aryl group, or a heteroaryl group.

(8) The pressure sensitive adhesive sheet according to any one of (1) to (7), in which the (meth)acrylic resin has a repeating unit derived from a (meth)acrylic acid ester monomer represented by Formula (A-1) which will be described later,

a content of the repeating unit derived from the (meth)acrylic acid ester monomer represented by Formula (A-1) is 70.0% to 99.9% by mass with respect to all the repeating units of the (meth)acrylic resin, and

a weight-average molecular weight of the (meth)acrylic resin is 300,000 to 3,000,000.

(9) The pressure sensitive adhesive sheet according to any one of (1) to (8), in which the (meth)acrylic resin has a repeating unit derived from butyl acrylate, and

a content of the repeating unit, derived from butyl acrylate is 50% to 99.9% by mass with respect to all the repeating units of the (meth)acrylic resin.

(10) The pressure sensitive adhesive sheet according to any one of (1) to (9), in which a thickness of the pressure sensitive adhesive sheet is less than 20 μm.

(11) The pressure sensitive adhesive sheet according to any one of (1) to (10), in which a thickness of the pressure sensitive adhesive sheet is less than 10 μm.

(12) The pressure sensitive adhesive sheet according to any one of (1) to (11), in which a thickness of the pressure sensitive adhesive sheet is 5 μm or less.

(13) A laminate having the pressure sensitive adhesive sheet according to any one of (1) to (12), and

an optically anisotropic layer formed of a composition containing a polymerizable liquid crystal compound exhibiting reverse wavelength dispersibility.

(14) The laminate according to (13), in which the polymerizable liquid crystal compound includes a polymerizable liquid crystal compound having a partial structure represented by Formula (II) which will be described later.

(15) The laminate according to (13) or (14), further having a polarizer layer.

(16) The laminate according to (15), in which the laminate has the polarizer layer, the pressure sensitive adhesive sheet, and the optically anisotropic layer in this order.

(17) The laminate according to (15) or (16), in which the polarizer layer is a polarizer layer having a dichroic coloring agent.

(18) The laminate according to any one of (15) to (17), in which the laminate has a first pressure sensitive adhesive sheet, the polarizer layer, a second pressure sensitive adhesive sheet, and the optically anisotropic layer in this order, and

at least one of the first pressure sensitive adhesive sheet or the second pressure sensitive adhesive sheet is the above-mentioned pressure sensitive adhesive sheet.

(19) A display device having the laminate according to airy one of (13) to (18).

(20) An organic electroluminescent display device having the laminate according to any one of (13) to (18).

According to an aspect of the present invention, it is possible to provide a pressure sensitive adhesive sheet having excellent light resistance (particularly, excellent light resistance for light having a wavelength of 370 to 400 nm).

According to another aspect of the present invention, it is possible to provide a laminate, a display device, and an organic EL display device.

### BRIEF DESCRIPTION OF THE DRAWINGS

FIG. 1 is a schematic cross-sectional view showing am example of a laminate of the present invention.

FIG. 2 is a schematic cross-sectional view showing an example of a laminate of the present invention.

FIG. 3 is a schematic cross-sectional view showing ail example of a laminate of the present invention.

### DESCRIPTION OF THE PREFERRED EMBODIMENTS

Hereinafter, the present invention will be described in more detail.

The description of configuration requirements described below may be made based on representative embodiments of the present invention, but the present invention is not limited to such embodiments.

In the present specification, the numerical range expressed by using “to” means a range including numerical values described before and after “to” as a lower limit value and an upper limit value, respectively.

In addition, in the present specification, parallel and orthogonal do not mean parallel and orthogonal in a strict sense, but mean a range of ±5° from parallel or orthogonal, respectively.

In addition, in the present specification, “(meth)acrylic” is a generic term for acrylic and methacrylic.

In addition, in the present specification, the liquid crystal composition and the liquid crystal compound also include, as a concept, those which no longer exhibit liquid crystallinity due to curing or the like.

The feature point of the present invention is that the absolute value of the difference between the log P of the (meth)acrylic resin and the log P of the predetermined ultraviolet absorber (the compound represented by Formula (I) which will be described later) is adjusted. Although the details of the mechanism by which the effect of the present invention can be obtained by the above aspect have not yet been clarified, the present inventors presume that this is due to the following reasons.

Therefore, it is presumed that, by a configuration in which the absolute value of the difference in log P value between the (meth)acrylic resin and the compound represented by Formula (I) which will be described later (hereinafter, also simply referred to as a “specific compound”) is separated by 2.50 or more in the pressure sensitive adhesive sheet, the specific compound undergoes phase separation to some extent in the pressure sensitive adhesive sheet to form a small associate. It is considered that forming such a fine associate of the specific compound leads to improved light resistance as compared with a state in which the specific compound is dispersed, and as a result, a pressure sensitive adhesive sheet having excellent light resistance is obtained.

<Pressure Sensitive Adhesive Sheet>

The pressure sensitive adhesive sheet according to the embodiment of the present invention is a pressure sensitive adhesive sheet containing a (meth)acrylic pressure sensitive adhesive and a specific compound, in which the (meth)acrylic pressure sensitive adhesive is formed by using a (meth)acrylic resin, and an absolute value of a difference between the log P value of the (meth)acrylic resin and the log P value of the specific compound is 2.50 or more.

The pressure sensitive adhesive sheet according to the embodiment of the present invention can effectively block light in a wavelength range of 370 to 400 nm, has excellent light resistance, does not easily become yellowish, and has sufficient suitability as a pressure sensitive adhesive sheet.

In the pressure sensitive adhesive sheet according to the embodiment of the present invention, the absolute value of the difference between the log P value of the (meth)acrylic resin and the log P value of the specific compound is 2.50 or more. From the viewpoint that the light resistance of the pressure sensitive adhesive sheet is more excellent (hereinafter, also simply referred to as “the viewpoint that the effect of the present invention is more excellent”), the absolute value of the difference between the log P value of the (meth)acrylic resin and the log P value of the specific compound is preferably 3.50 or more, more preferably 4.00 or more, and still more preferably 4.50 or more. The upper limit thereof is not particularly limited and is preferably 10.00 or less from the viewpoint that the precipitation of the specific compound is further suppressed.

The log P value is an indicator expressing properties of hydrophilicity and hydrophobicity of a chemical structure, and may be referred to as a hydrophilic-hydrophobic parameter. The log P value of each compound can be calculated using software such as ChemBioDraw Ultra or HSPiP (Ver. 4.1.07). In addition, the log P value can also be experimentally obtained by, for example, a method described in OECD Guidelines for the Testing of Chemicals, Sections 1, Test No, 117. In the present invention, unless otherwise specified, a value calculated by inputting a structural formula of a compound into HSPiP (Ver. 4.1.07) is adopted as the log P value.

The log P value of the (meth)acrylic resin is calculated by summing the products of log P values of the monomer as each repeating unit constituting the (meth)acrylic resin and mass ratios of each repeating unit to all the repeating units. For example, the log P value of the (meth)acrylic resin is calculated by the following expression in a ease where the (meth)acrylic resin contains a repeating unit derived from monomer A having a log P value of “PA” and a repeating unit derived from monomer B having a log P value of “PB”, the content of the repeating unit derived from monomer A with respect to all the repeating units is 20% by mass, and the content of the repeating unit derived from monomer B with respect to all the repeating units is 80% by mass.

Log P value of (meth)acrylic resin={PA×0.2}+{PB×0.8}

The range of the log P value of the specific compound is not particularly limited, and is sufficient such that a predetermined relationship is satisfied with the log P value of the (meth)acrylic resin. Above all, the log P value of the specific compound is preferably 5.00 to 9.00, more preferably 5.50 to 8.00, and still more preferably 6.00 to 8.00, from the viewpoint that the effect of the present invention is more excellent.

The range of the log P value of the (meth)acrylic resin is not particularly limited, and is sufficient such that a predetermined relationship is satisfied with the log P value of the specific compound. Above all, the log P value of the (meth)acrylic resin is preferably LOO to 5.00 and more preferably 1.50 to 3.00, from the viewpoint that the effect of the present invention is more excellent.

(Compound Represented by Formula (I))

The pressure sensitive adhesive sheet contains a compound represented by Formula (I) (a specific compound).

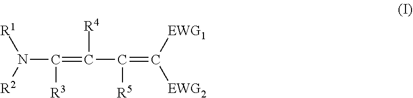

First, a “substituent” (that is, a substituent represented by R³, R⁴, and R⁶ in Formula (I)) will be described in detail.

The type of “substituent” in the present invention is not particularly limited, and examples thereof include known substituents. Examples of the substituent include the groups exemplified in Substituent Group shown below.

Substituent Group: a halogen atom, an alkyl group, an alkenyl group, an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyl oxy group, a carbamoyloxy group, an alkoxycarbonyloxy group, an aryloxycarbonyloxy group, an amino group, an acylamino group, an aminocarbonylamino group, an alkoxycarbonylamino group, an aryloxycarbonylamino group, a sulfamoylamino group, an alkylsulfonylamino group, an arylsulfonylamino group, a mercapto group, an alkyl thio group, an arylthio group, a heterocyclic thio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, an imide group, a phosphino group, a phosphinyl group, a phosphinyloxy group, a phosphinylamino group, a silyl group, and a group obtained by combining these groups.

The above-mentioned substituent may be further substituted with a substituent.

The substituent is preferably an alkyl group, an alkenyl group, an alkynyl group, an aryl group, or an aralkyl group.

The alkyl group may be an unsubstituted alkyl group or a substituted alkyl group.

The “substituted alkyl group” means an alkyl group in which the hydrogen atom of the alkyl group is substituted with the other substituent. Similarly, a substituted alkenyl group, a substituted alkynyl group, and a substituted aralkyl group, which will be described later, also mean that the hydrogen atom of each group is substituted with the other substituent. Examples of the “other substituent” include the groups exemplified in the Substituent Group.

The alkyl group may have a linear, branched, or cyclic molecular structure.

The number of carbon atoms in the alkyl group is preferably 1 to 20, more preferably 1 to 18, still more preferably 1 to 10, and particularly preferably 1 to 5. It should be noted that the number of carbon atoms does not include the number of carbon atoms in a substituent in a ease where the alkyl group further has such a substituent.

The alkenyl group may be an unsubstituted alkenyl group or a substituted alkenyl group.

The alkenyl group may have a linear, branched, or cyclic molecular structure.

The number of carbon atoms in the alkenyl group is preferably 2 to 20 and more preferably 2 to 18. It should be noted that the number of carbon atoms does not include the number of carbon atoms in a substituent in a case where the alkenyl group further has such a substituent.

The alkynyl group may be an unsubstituted alkynyl group or a substituted alkynyl group.

The alkynyl group may have a linear, branched, or cyclic molecular structure.

The number of carbon atoms in the alkynyl group is preferably 2 to 20 and more preferably 2 to 18. It should be noted that the number of carbon atoms does not include the number of carbon atoms in a substituent in a case where the alkynyl group further has such a substituent.

The aryl group may be an unsubstituted aryl group or a substituted aryl group.

The number of carbon atoms in the aryl group is preferably 6 to 20 and more preferably 6 to 10. It should be noted that the number of carbon atoms does not include the number of carbon atoms in a substituent in a case where the aryl group further has such a substituent.

The aralkyl group may be an unsubstituted aralkyl group or a substituted aralkyl group.

The alkyl moiety of the aralkyl group is the same as the alkyl group which is the above-mentioned substituent.

The aryl moiety of the aralkyl group may be condensed with an aliphatic ring, another aromatic ring, or a heterocyclic ring.

The aryl moiety of the aralkyl group is the same as the aryl group which is the above-mentioned substituent.

The substituent (that is, the other substituent) contained in the substituted alkyl group, the substituted alkenyl group, the substituted alkynyl group, the substituted aryl group, and the substituted aralkyl group can be selected from the Substituent Group.

Reference can be made to the description in JP2007-262165A for details of examples of the substituent contained in the substituted alkyl group, the substituted alkenyl group, the substituted alkynyl group, and the substituted aralkyl group.

In Formula (I), EWG₁ and EWG₂ each independently represent a group having a Hammett's substituent constant op value of 0.20 or more, provided that EWG₁ and EWG₂ are not bonded to each other to form, a ring structure.

Above all, from the viewpoint that the effect of the present invention is more excellent, the group having a Hammett's substituent constant op value of 0.20 or more is preferably a group having a Hammett's substituent constant op value of 0.30 or more and more preferably a group having a Hammett's substituent constant op value of 0.40 or more.

The upper limit of the σp value is not particularly limited, and is preferably 1.00 or less.

The “Hammett's substituent constant” in the present invention is a constant specific to a substituent in a relational expression established as the Hammett equation. A positive Hammett's substituent constant σ value indicates that the substituent is electron-withdrawing.

The Hammett equation is an empirical rule proposed by L. P. Hammett in 1935 in order to quantitatively treat an effect of a substituent on a reaction or equilibrium of a benzene derivative, which is widely considered to be reasonable today. There are a op value and a σm value as substituent constants obtained by the Hammett equation. These values are found in many general documents. In the present specification, the values described in Chem. Rev., 1991, Vol. 91, pp. 165 to 195 are adopted. For substituents not described in the above document, the values calculated according to the calculation method described in the document “The Effect of Structure upon the Reactions of Organic Compounds. Benzene Derivatives” (J. Am. Chem. Soc. 1937, 59, 1, pp. 96 to 103) are adopted.

Examples of the group having a Hammett's substituent constant op value of 0.20 or more include a cyano group (0.66), a carboxy group (—COOH: 0.45), an alkoxycarbonyl group (—COOMe: 0.45, —COOC₈H₁₇: 0.44, —COOC₉H₁₉: 0.44, —COOC₁₃H₂₇: 0.44), an aryloxycarbonyl group (—COOPh: 0.44), a carbamoyl group (—CONH₂: 0.36), an acetyl group (—COMe: 0.50), an arylcarbonyl group (—COPh: 0.43), an alkylsulfonyl group (—SO₂Me: 0.72), and an arylsulfonyl group (—SO₂Ph: 0.68).

The substituents and numerical values in parentheses are representative substituents and op values thereof extracted from Chem. Rev., 1991, Vol. 91, pp. 165 to 195. In addition, a sulfamoyl group, a sulfinyl group, a heterocyclic group, and the like are also included in the group having a Hammett's substituent constant op value of 0.20 or more.

In the present specification, “Me” represents a methyl group and “Ph” represents a phenyl group.

From the viewpoint that the effect of the present invention is more excellent, EWG₁ and EWG₂ each independently preferably represent COOR⁵, SO₂R⁷, CN, or COR⁸. R⁶, R⁷, and R⁸ each independently represent an alkyl group, an aryl group, or a heteroaryl group.

The alkyl group represented by R⁶, R⁷, and R⁸ may be an unsubstituted alkyl group or a substituted alkyl group. The substituent contained in the substituted alkyl group can be selected from, for example, the Substituent Group. Suitable aspects of the alkyl group represented by R⁶, R⁷, and R⁸ include suitable aspects of the alkyl group represented by R⁵ and R², which will be described later.

The aryl group represented by R⁶, R⁷, and R⁸ may be an unsubstituted aryl group or a substituted aryl group. The substituent contained in the substituted aryl group can be selected from, for example, the Substituent Group. Suitable aspects of the aryl group represented by R⁶, R⁷, and R⁸ include suitable aspects of the aryl group represented by R¹ and R², which will be described later.

The heteroaryl group represented by R⁶, R⁷, and R⁸ may be an unsubstituted heteroaryl group or a substituted heteroaryl group. The substituent contained in the substituted heteroaryl group can be selected from, for example, the Substituent Group. Suitable aspects of the heteroaryl group represented by R⁶, R⁷, and R⁸ include suitable aspects of the heteroaryl group represented by R¹ and R², which will be described later.

Specific examples of EWG₁ or EWG₂ include an alkoxycarbonyl group, an arylcarbonyl group, an aryloxycarbonyl group, an alkylsulfonyl group, an arylsulfonyl group, a cyano group, and an acyl group.

The number of carbon atoms in the alkoxycarbonyl group is not particularly limited, and is preferably 2 to 20 and more preferably 2 to 9. Specific examples of the alkoxycarbonyl group having 2 to 20 carbon atoms include a methoxycarbonyl group, an ethoxy-carbonyl group, a t-butoxycarbonyl group, an octyloxycarbonyl group, a nonyloxycarbonyl group, a tridecyloxycarbonyl group, and a benzyloxycarbonyl group.

The number of carbon atoms in the arylcarbonyl group is not particularly limited, and is preferably 7 to 20 and more preferably 7 to 15. Specific examples of the arylcarbonyl group having 7 to 20 carbon atoms include a phenylcarbonyl group.

The number of carbon atoms in the alkylsulfonyl group is not particularly limited, and is preferably 6 to 20 and more preferably 6 to 15. Specific examples of the alkylsulfonyl group having 6 to 20 carbon atoms include a hexylsulfonyl group, an octylsulfonyl group, and a dodecylsulfonyl group.

The number of carbon atoms in the arylsulfonyl group is not particularly limited, and is preferably 6 to 15. Specific examples of the arylsulfonyl group having 6 to 15 carbon atoms include a phenylsulfonyl group, a benzenesulfonyl group, a p-toluenesulfonyl group, a p-chlorobenzenesulfonyl group, and a naphthalenesulfonyl group.

The number of carbon atoms in the acyl group is not particularly limited, and is preferably 2 to 20 and more preferably 2 to 5. Specific examples of the acyl group having 2 to 20 carbon atoms include an acetyl group and a propionyl group.

The number of carbon atoms in tire aryloxycarbonyl group is not particularly limited, and is preferably 7 to 20 and more preferably 7 to 15. Specific examples of the aryloxycarbonyl group having 7 to 20 carbon atoms include a phenoxycarbonyl group and a p-nitrophenoxycarbonyl group.

From the viewpoint that the effect of the present invention is more excellent, it is preferable that one of EWG₁ and EWG₂ represents COOR⁶, the other represents SO₂R⁷, and R⁶ and R⁷ each independently represent an alkyl group, an aryl group, or a heteroaryl group. Above all, it is more preferable that EWG₁ represents SO₂R⁷, EWG₂ represents COOR⁶, and R⁶ and 1% each independently represent an alkyl group, an aryl group, or a heteroaryl group.

R⁷ preferably represents an aryl group and R⁶ and R⁸ each independently preferably represent an alkyl group.

R¹ and R² each independently represent an alkyl group, an aryl group, or a heteroaryl group, provided that R¹ and R² are not bonded to each other to form a ring structure.

R¹ and R² each independently preferably represent an alkyl group or an aryl group, and more preferably an alkyl group.

The alkyl group represented by R¹ and R² may be an unsubstituted alkyl group or a substituted alkyl group. In addition, the alkyl group represented by R¹ and R² may have a linear, branched, or cyclic molecular structure.

The number of carbon atoms in the alkyl group represented by R¹ and R² is not particularly limited, and is preferably 1 to 20, more preferably 1 to 15, and still more preferably 1 to 10.

The substituent contained in the substituted alkyl group can be selected from, for example, the Substituent Group.

The aryl group represented by R¹ and R² may be an unsubstituted aryl group or a substituted aryl group. In addition, the aryl group represented by R¹ and R² may be condensed with an aliphatic ring, another aromatic ring, or a heterocyclic ring.

The number of carbon atoms in the aryl group represented by R¹ and R² is not particularly limited, and is preferably 6 to 30, more preferably 6 to 20, and still more preferably 6 to 15.

The aryl group represented by R¹ and R² is preferably a phenyl group or a naphthyl group, and more preferably a phenyl group.

The aryl moiety of the substituted aryl group is the same as the above-mentioned aryl group.

The substituent contained in the substituted aryl group can be selected from, for example, the Substituent Group.

The heteroaryl group represented by R¹ and R² may be an unsubstituted heteroaryl group or a substituted heteroaryl group. In addition, the heteroaryl group represented by R¹ and R² may be condensed with an aliphatic ring, an aromatic ring, or another heterocyclic ring.

The heteroaryl group represented by R¹ and R² preferably contains a 5- or 6-membered unsaturated heterocyclic ring.

Examples of the heteroatom in the heteroaryl group represented by R¹ and R² include B, N, O, S, Se, and Te, among which N, O, or S is preferable.

In the heteroaryl group represented by R¹ and R², it is preferable that the carbon atom has a free valence (monovalent) (that is, the heteroaryl group is bonded at the carbon atom).

The number of carbon atoms in the heteroaryl group represented by R¹ and R² is not particularly limited, and is preferably 1 to 40, more preferably 1 to 30, and still more preferably 1 to 20.

Examples of the unsaturated heterocyclic ring contained in the heteroaryl group include imidazole, thiazole, benzothiazole, benzoxazole, benzotriazole, benzoselenazole, pyridine, pyrimidine, and quinoline.

The heteroaryl moiety of the substituted heteroaryl group is the same as the above-mentioned heteroaryl group.

The substituent contained in the substituted heteroaryl group can be selected from, for example, the Substituent Group.

R³, R⁴, and R³ in Formula (I) each independently represent a hydrogen atom or a substituent, preferably a hydrogen atom, an alkyl group having 1 to 10 carbon atoms, or an aryl group having 6 to 10 carbon atoms, and more preferably a hydrogen atom or an alkyl group having 1 to 5 carbon atoms, and all of R³, R⁴, and R⁵ still more preferably represent a hydrogen atom.

Specific examples of the specific compound include Exemplary Compounds (I-1) to (I-10). However, the compound represented by Formula (I) is not limited to these exemplary compounds (log P values and maximal absorption wavelengths are described under the structures).

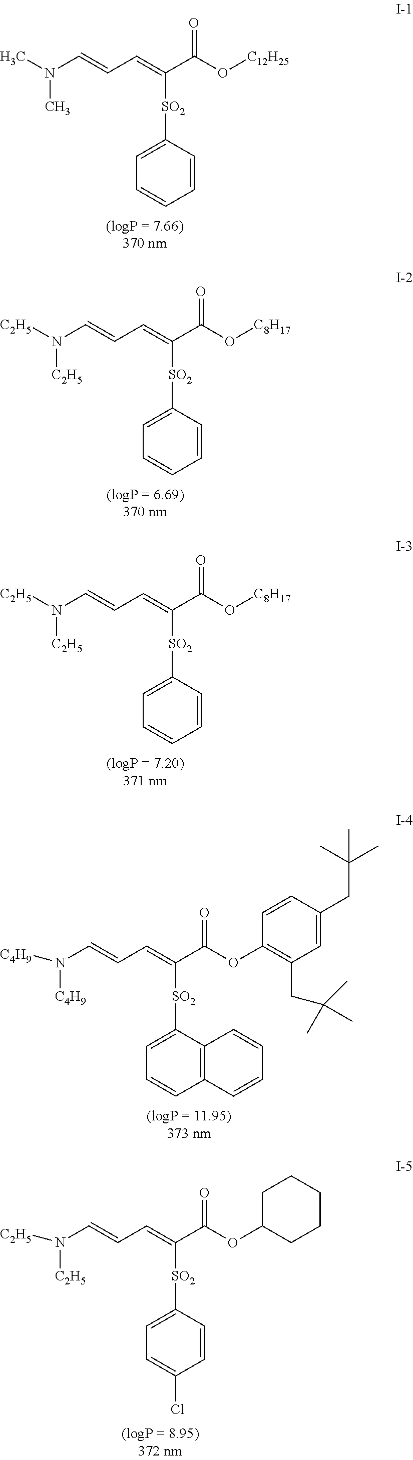

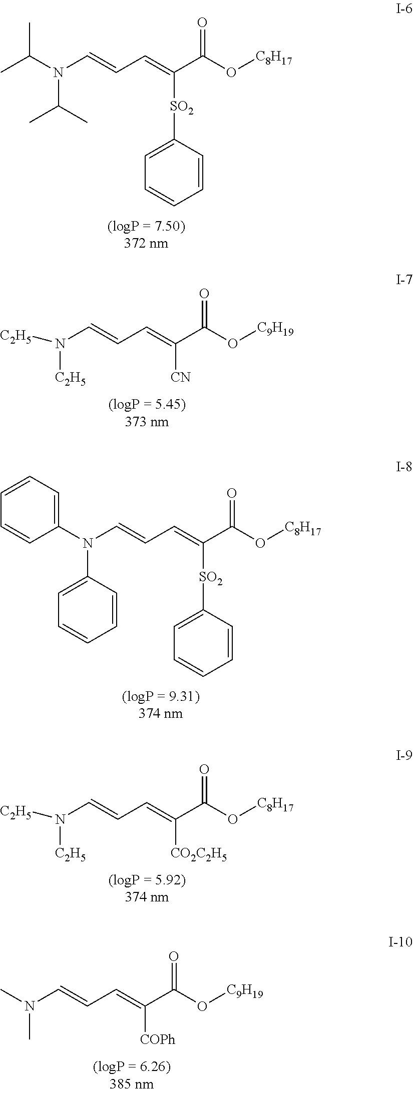

The maximal absorption wavelength of the specific compound is preferably located in a range of 365 to 385 nm. In a case where the maximum absorption wavelength of the specific compound is within the above range, the yellow coloring of the pressure sensitive adhesive sheet can be suppressed even in a case where the specific compound is added at a high concentration.

The maximal absorption wavelength of the specific compound is a value measured by dissolving the specific compound in a 2-butanone solvent.

The pressure sensitive adhesive sheet may contain, only one type of the specific compound, or may contain two or more types of the specific compounds.

The pressure sensitive adhesive sheet may contain an ultraviolet absorber other than the specific compound as long as the effect of the present invention is not impaired.

Examples of the other ultraviolet absorber include organic ultraviolet absorbers such as an oxybenzophenone-based ultraviolet absorber, a benzotriazole-based ultraviolet absorber, a salicylate ester-based ultraviolet absorber, a benzophenone-based ultraviolet absorber, a cyanoacrylate-based ultraviolet absorber, and a triazine-based ultraviolet absorber. More specific examples of the other ultraviolet absorber include 5-chloro-2-(3,5-di-sec-butyl-2-hydroxyphenyl)-2H-benzotriazole, (2-2H-benzotriazol-2-yl)-6-(linear and side chain dodecyl)-4-methylphenol, 2-hydroxy-4-benzyloxybenzophenone, and 2,4-benzyloxybenzophenone.

A commercially available product may be used as the other ultraviolet absorber. Examples of a triazine-based ultraviolet absorber include “KEMISORB 102” (trade name, manufactured by Chemipro Kasei Kaisha, Ltd.), “ADEKA STAB LA 46” and “ADEKA STAB LA F70” (both trade names, manufactured by ADEKA Corporation), and “TINUVIN 109”, “TINUVIN 171”, “TINUVIN 234”, “TINUVIN 326”, “TINUVIN 327”, “TINUVIN 328”, “TINUVIN 928”, “TINUVIN 400”, “TINUVIN 460”, “TINUVIN 405”, and “TINUVIN 477” (all trade name, manufactured by BASF Japan Ltd.). Examples of a benzotriazole-based ultraviolet absorber include “ADEKA STAB LA 31” and “ADEKA STAB LA 36” (both trade names, manufactured by ADEKA Corporation), “SUMISORB 200”, “SUMISORB 250”, “SUMISORB 300”, “SUMISORB 340”, and “SUMISORB 350” (all trade names, manufactured by Sumika Chemtex Co., Ltd.), “KEMISORB 74”, “KEMISORB 79”, and “KEMISORB 279” (all trade names, manufactured by Chemipro Kasei Kaisha, Ltd.), and “TINUVIN 99-2”, “TINUVIN 900”, and “TINUVIN 928” (ail trade names, manufactured by BASF SE).

The content of the specific compound in the pressure sensitive adhesive sheet is not particularly limited, and is preferably 1.0% by mass or more, more preferably 2.5% by mass or more, and still more preferably 5.5% by mass or more with respect to the total mass of the (meth)acrylic resin, from the viewpoint that sufficient absorption characteristics can be obtained even with a thin pressure sensitive adhesive sheet. In addition, the upper limit of the content of the specific compound is preferably 30% by mass or less and more preferably 20% by mass or less with respect to the total mass of the (meth)acrylic resin, from the viewpoint that the pressure sensitive adhesive properties of the pressure sensitive adhesive sheet are more excellent.

In a case where the content of the specific compound in the pressure sensitive adhesive sheet is within the above range, the compatibility between the specific compound and the (meth)acrylic resin is favorable, and therefore the specific compound is less likely to precipitate and haze is less likely to occur. Since the specific compound has a high molar absorption coefficient in a wavelength range of 370 to 400 nm, blue light in this wavelength range can be satisfactorily blocked even in a case where the content of the specific compound in the pressure sensitive adhesive sheet is within the above range.

In one suitable embodiment of the present invention, the specific compound may be contained in another member such as a transparent resin film used as a support, in addition to the pressure sensitive adhesive sheet.

((Meth)Acrylic Pressure Sensitive Adhesive)

The pressure sensitive adhesive sheet contains a (meth)acrylic pressure sensitive adhesive.

The (meth)acrylic pressure sensitive adhesive means a pressure sensitive adhesive using a (meth)acrylic resin as a base polymer. The (meth)acrylic resin refers to a polymer whose main component is a repeating unit derived from a monomer having at least one (meth)acryloyl group in one molecule (hereinafter, this may be referred to as “(meth)acrylic monomer”). The “main component” means that the content of the repeating unit derived from the (meth)acrylic monomer is 50% by mass or more with respect to all the repeating units constituting the (meth)acrylic resin.

The (meth)acrylic pressure sensitive adhesive in the present invention is a compound formed by using a (meth)acrylic resin. For example, the (meth)acrylic pressure sensitive adhesive is preferably a compound obtained by reacting a (meth)acrylic resin with a crosslinking agent. In addition, in a case where the (meth)acrylic resin itself exhibits a predetermined pressure sensitive adhesiveness, the (meth)acrylic resin itself may be used as the (meth)acrylic pressure sensitive adhesive.

The (meth)acrylic resin is preferably a (meth)acrylic resin having a repeating unit derived from a (meth)acrylic acid ester monomer represented by Formula (A-1).

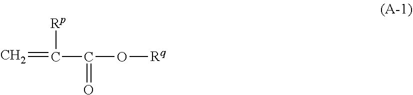

In Formula (A-1), R^{p} is a hydrogen atom or a methyl group.

R^{q} represents an alkyl group having 1 to 8 carbon atoms or an aralkyl group having 1 to 8 carbon atoms, among which an alkyl group having 1 to 6 carbon atoms or an aralkyl group having 1 to 6 carbon atoms is preferable.

The hydrogen atom constituting the alkyl group and the aralkyl group may be substituted with —O—(C₂H₄O)ₙ—R^{r}.

n represents an integer of 0 to 4 and preferably an integer of 0 to 3.

R^{r} represents an alkyl group having 1 to 12 carbon atoms or an aryl group having 1 to 12 carbon atoms, among which an alkyl group having 1 to 4 carbon atoms or an aryl group having 1 to 6 carbon atoms is preferable.

Examples of the (meth)acrylic acid ester monomer (A-1) represented by Formula (A-1) (hereinafter, also referred to as “monomer (A-1)”) include linear acrylic acid alkyl esters such as methyl acrylate, ethyl acrylate, propyl acrylate, n-butyl acrylate, and n-octyl acrylate; branched acrylic acid alkyl esters such as isobutyl acrylate, 2-ethylhexyl acrylate, and isooctyl acrylate; linear methacrylic acid alkyl esters such as methyl methacrylate, ethyl methacrylate, propyl methacrylate, n-butyl methacrylate, and n-octyl methacrylate; branched methacrylic acid alkyl esters such as isobutyl methacrylate, 2-ethylhexyl methacrylate, and isooctyl methacrylate; acrylic acid esters having an aromatic group such as acrylic acid phenyl ester and acrylic acid benzyl ester; and methacrylic acid esters having an aromatic group, such as acrylic acid phenoxy ester, methacrylic acid phenyl ester, and methacrylic acid benzyl ester.

The monomer (A-1) may be used alone or in combination of two or more thereof. Above all, n-butyl acrylate is preferable from the viewpoint of developing pressure sensitive adhesiveness.

The (meth)acrylic resin preferably has a repeating unit derived from an unsaturated monomer (A-2) having a polar functional group (hereinafter, also referred to as “monomer (A-2)”).

The type of polar functional group in the monomer (A-2) is not particularly limited, and examples thereof include a free carboxyl group, a hydroxyl group, an amino group, and a heterocyclic group (for example, an epoxy ring group).

The monomer (A-2) is preferably a (meth)acrylic acid-based compound having a polar functional group. Examples of the monomer (A-2) include unsaturated monomers having a free carboxyl group such as acrylic acid, methacrylic acid, and β-carboxyethyl acrylate; unsaturated monomers having a hydroxyl group such as 2-hydroxyethyl (meth)acrylate, 2-hydroxypropyl (meth)acrylate, 2- or 3-chloro-2-hydroxypropyl (meth)acrylate, and diethylene glycol mono(meth)acrylate; unsaturated monomers having a heterocyclic group such as acryloylmorpholin, vinyl caprolactam, N-vinyl-2-pyrrolidone, tetrahydrofurfuryl (meth)acrylate, caprolactone-modified tetrahydrofurfuryl acrylate, 3,4-epoxycyclohexylmethyl (meth)acrylate, glycidyl (meth)acrylate, and 2,5-dihydrofuran; and unsaturated monomers having an amino group different from that of a heterocyclic ring such as N,N-dimethylaminoethyl (meth)acrylate.

The monomer (A-2) may be used alone or in combination of two or more thereof.

The monomer (A-2) is preferably an unsaturated monomer having a hydroxyl group, from the viewpoint of increasing the adhesive force of the pressure sensitive adhesive sheet to further improve the durability.

In a (meth)acrylic resin having a repeating unit derived from the monomer (A-1) and a repeating unit derived from the monomer (A-2), the content of the repeating unit derived from the monomer (A-1) is preferably 50% to 99.9% by mass and more preferably 70% to 99.9% by mass with respect, to all the repeating units of the (meth)acrylic resin.

In addition, the content of the repeating unit derived from the monomer (A-2) is preferably 0.1% to 50% by mass and more preferably 0.1% to 30% by mass with respect to all the repeating units of the (meth)acrylic resin.

In a case where the content of each of the repeating unit derived from the monomer (A-1) and the repeating unit derived from the monomer (A-2) is within the above range, the effect of the present invention, is more excellent, and a pressure sensitive adhesive sheet having more excellent workability can be obtained.

Further, the (meth)acrylic resin may contain a repeating unit derived from another monomer (hereinafter, also referred to as “monomer (A-3)”) other than the repeating unit derived from the monomer (A-1) and the repeating unit derived from the monomer (A-2).

Examples of the other monomer include a (meth)acrylic acid ester having an alicyclic structure in a molecule thereof, a styrene-based, monomer, a vinyl-based monomer, a monomer having a plurality of (meth)acryloyl groups in a molecule thereof and a (meth)acrylamide derivative.

The alicyclic structure is a cycloparaffin structure having usually 5 or more carbon atoms, preferably about 5 to 7 carbon atoms.

Examples of the acrylic acid ester having an alicyclic structure include isobornyl acrylate, cyclohexyl acrylate, dicyclopentanyl acrylate, cyclododecyl acrylate, methyl cyclohexyl acrylate, trimethylcyclohexyl acrylate, tert-butyl cyclohexyl acrylate, cyclohexyl α-ethoxyacrylate, and cyclohexylphenyl acrylate.

Examples of the methacrylic acid ester having an alicyclic structure include isobornyl methacrylate, cyclohexyl methacrylate, dicyclopentanyl methacrylate, cyclododecyl methacrylate, methylcyclohexyl methacrylate, trimethylcyclohexyl methacrylate, tert-butylcyclohexyl methacrylate, and cyclohexylphenyl methacrylate.

Examples of the styrene-based monomer include styrene; alkyl styrenes such as methyl styrene, dimethyl styrene, trimethyl styrene, ethyl styrene, diethyl styrene, triethyl styrene, propyl styrene, butyl styrene, hexyl styrene, heptyl styrene, and octyl styrene; halogenated styrenes such as fluorostyrene, chlorostyrene, bromostyrene, dibromostyrene, and iodostyrene; nitrostyrene; acetylstyrene; methoxystyrene; and divinylbenzene.

Examples of the vinyl-based monomer include fatty acid vinyl esters such as vinyl acetate, vinyl propionate, vinyl butyrate, vinyl 2-ethylhexanate, and vinyl laurate; vinyl halides such as vinyl chloride and vinyl bromide; vinylidene halides such as vinylidene chloride; nitrogen-containing aromatic vinyls such as vinylpyridine, vinylpyrrolidone, and vinylcarbazole; conjugated diene monomers such as butadiene, isoprene, and chloroprene; acrylonitrile; and methacrylonitrile.

Examples oi the monomer having a plurality of (meth)acryloyl groups in a molecule thereof include monomers having two (meth)acryloyl groups in a molecule thereof, such as 1,4-butanediol di(meth)acrylate, 1,6-hexanediol di(meth)acrylate, 1,9-nonanediol di(meth)acrylate, ethylene glycol di(meth)acrylate, diethylene glycol di(meth)acrylate, tetraethylene glycol di(meth)acrylate, and tripropylene glycol di(meth)acrylate; and monomers having three (meth)acryloyl groups in a molecule thereof, such as trimethylolpropane tri(meth)acrylate.

Examples of the (meth)acrylamide derivative include N-methylol (meth)acrylamide, 2-hydroxyethyl (meth)acrylamide, 3-hydroxypropyl (meth)acrylamide, 4-hydroxybutyl (meth)acrylamide, 5-hydroxypentyl (meth)acrylamide, 6-hydroxyhexyl (meth)acrylamide, N-methoxymethyl (meth)acrylamide, N-ethoxymethyl (meth)acrylamide, N-propoxymethyl (meth)acrylamide, N-butoxymethyl (meth)acrylamide, N,N-dimethyl (meth)acrylamide, N,N-diethyl (meth)acrylamide, N-isopropyl (meth)acrylamide, N-dimethylaminopropyl (meth)acrylamide, N-(1,1-dimethyl-3-oxobutyl)(meth)acrylamide, N-[2-(2-oxo-1-imidazolidinyl)ethyl] (meth)acrylamide, and 2-acryloylamino-2-methyl-1-propane sulfonic acid.

The monomer (A-3) may be used alone or in combination of two or more thereof.

The content of the repeating unit derived from the monomer (A-3) is preferably 0% to 20% by mass and more preferably 0% to 10% by mass with respect to all the repeating units of the (meth)acrylic resin.

The (meth)acrylic resin may be used alone or in combination of two or more thereof.

The weight-average molecular weight (Mw) of the (meth)acrylic resin in terms of standard polystyrene by gel permeation chromatography (GPC) is not particularly limited, and is preferably 300,000 to 3,000,000, more preferably 500,000 to 2,000,000, and still more preferably 700,000 to 1,700,000.

In a case where the weight-average molecular weight is 300,000 or more, the adhesiveness of the pressure sensitive adhesive sheet under high temperature and high humidity is improved, the possibility of floating or peeling between the glass substrate (image display element) and the pressure sensitive adhesive sheet tends to decrease, and the peeling property in reworking process tends to improve, which is preferable. In addition, in a case where the weight-average molecular weight is 3,000,000 or less, the pressure sensitive adhesive sheet can change according to the dimensional changes of an optical film even in a ease where the dimensions of the optical film change in a case where the pressure sensitive adhesive sheet is bonded to the optical film or the like. Therefore, there is no difference between brightness of a peripheral portion and brightness of a central portion of an image display element such as a liquid crystal cell, and white spots and color unevenness tend to be suppressed, which is preferable.

The molecular weight distribution represented by a ratio (Mw/Mn) of the weight-average molecular weight (Mw) to the number average molecular weight (Mn) is preferably 2 to 10.

The (meth)acrylic resin can be produced by various known methods such as a solution polymerization method, an emulsion polymerization method, a bulk polymerization method, and a suspension polymerization method.

It is preferable to use a polymerization initiator in the production of the (meth)acrylic resin. The amount of the polymerization initiator used is preferably 0.001 to 5 parts by mass with respect to 100 parts by mass in total of all the monomers used in the production of the (meth)acrylic resin.

Examples of the polymerization initiator include a thermal polymerization initiator and a photopolymerization initiator.

Examples of the photopolymerization initiator include 4-(2-hydroxyethoxy)phenyl(2-hydroxy-2-propyl)ketone.

Examples of the thermal polymerization initiator include azo-based compounds such as 2,2′-azobisisobutyronitrile, 2,2′-azobis(2-methylbutyronitrile), 1,1′-azobis(cyclohexane-1-carbonitrile), 2,2′-azobis(2,4-dimethylvaleronitrile), 2,2′-azobis(2,4-dimethyl-4-methoxyvaleronitrile), dimethyl-2,2′-azobis(2-methylpropionate), and 2,2′-azobis(2-hydroxymethylpropionitrile); organic peroxides such as lauryl peroxide, tert-butyl hydroperoxide, benzoyl peroxide, tert-butyl peroxybenzoate, cumene hydroperoxide, diisopropylperoxydicarbonate, dipropylperoxydicarbonate, tert-butylperoxyneodecanoate, tert-butylperoxypivalate, and (3,5,5-trimethylhexanoyl) peroxide; and inorganic peroxides such as potassium persulfate, ammonium persulfate, and hydrogen peroxide.

In addition, for example, a redox-based initiator in which a peroxide and a reducing agent are used in combination can also be used as the polymerization initiator.

As the method for producing the (meth)acrylic resin, the solution polymerization method is preferable among the methods shown above. A specific method of the solution polymerization method may be, for example, a method in which a desired monomer and an organic solvent are mixed to prepare a reaction solution, and a thermal polymerization initiator is added to the reaction solution under a nitrogen atmosphere, followed by stirring at about 40° C. to 90° C. (preferably about 50° C. to 80° C.) for about 3 to 20 hours.

In addition, in order to control the reaction, the monomer and the thermal polymerization initiator may be added continuously or intermittently during the polymerization, or may be added in a state of being dissolved in an organic solvent.

Examples of the organic solvent include aromatic hydrocarbons such as toluene and xylene; esters such as ethyl acetate and butyl acetate; aliphatic alcohols such as propyl alcohol and isopropyl alcohol; and ketones such as acetone, 2-butanone, and methyl isobutyl ketone.

(Crosslinking Agent)

The crosslinking agent is a compound tor reacting with a (meth)acrylic resin to form a (meth)acrylic pressure sensitive adhesive. The crosslinking agent is preferably a compound that reacts with a polar functional group in the (meth)acrylic resin to crosslink the (meth)acrylic resin.

The crosslinking agent preferably has a functional group capable of reacting with the polar functional group in the (meth)acrylic resin. The number of functional groups capable of reacting with the polar functional group is not particularly limited, and is preferably 2 or more, more preferably 2 to 10, and still more preferably 2 to 6.

Examples of the crosslinking agent include an isocyanate-based compound, an epoxy-based compound, an aziridine-based compound, and a metal chelate compound.

The isocyanate-based compound, the epoxy-based compound, and the aziridine-based compound preferably each has at least two functional groups capable of reacting with the polar functional group in the (meth)acrylic resin, in a molecule thereof.

The crosslinking agent may be used alone or in combination of two or more thereof.

The isocyanate-based compound is preferably a compound having at least two isocyanato groups (—NCO) in a molecule thereof.

Examples of the isocyanate-based compound include tolylene diisocyanate, hexamethylene diisocyanate, isophorone diisocyanate, xylylene diisocyanate, hydrogenated xylylene diisocyanate, diphenylmethane diisocyanate, hydrogenated diphenylmethane diisocyanate, naphthalene diisocyanate, and triphenylmethane triisocyanate. In addition, an adduct obtained by reacting such an isocyanate-based compound with a polyol such as glycerol or trimethylolpropane, and a compound obtained by converting the isocyanate-based compound into a dimer, a trimer, or the like can also serve as the crosslinking agent.

The epoxy-based compound is preferably a compound having at least two epoxy groups in a molecule thereof.

Examples of the epoxy-based compound include bisphenol A type epoxy resin, ethylene glycol diglycidyl ether, polyethylene glycol diglycidyl ether, glycerin diglycidyl ether, glycerin triglycidyl ether, 1,6-hexanediol diglycidyl ether, trimethylolpropane triglycidyl ether, N,N-diglycidyl aniline, N,N,N′,N′-tetraglycidyl-m-xylene diamine, and 1,3-bis(N,N′-diglycidylaminomethyl)cyclohexane.

The aziridine-based compound is preferably a compound having at least turn 3-membered ring skeletons consisting of one nitrogen atom and two carbon atoms in a molecule thereof, which is also referred to as ethyleneimine.

Examples of the aziridine-based compound include diphenylmethane-4,4′-bis(1-aziridinecarboxamide), toluene-2,4-bis(1-aziridinecarboxamide), triethylenemelamine, isophthaloylbis-1-(2-methylaziridine), tris-1-aziridinylphosphine oxide, hexamethylene-1,6-bis(1-aziridinecarboxamide), trimethylolpropane-tri-β-aziridinylpropionate, and tetramethylolmethane-tri-β-aziridinylpropionate.

Examples of the metal chelate compound include a compound in which acetylacetone or ethyl acetoacetate is coordinated with a polyvalent metal such as aluminum, iron, copper, zinc, tin, titanium, nickel, antimony, magnesium, vanadium, chromium, or zirconium.

The crosslinking agent is preferably an isocyanate-based compound, among which xylylene diisocyanate, tolylene diisocyanate, hexamethylene diisocyanate, or an adduct obtained by reacting such an isocyanate-based compound with a polyol such as glycerol or trimethylolpropane is preferable. In addition, the crosslinking agent is also preferably a mixture of a dimer, a trimer, or the like of an isocyanate-based compound.

Examples of the isocyanate-based compound include tolylene diisocyanate, an adduct obtained by reacting tolylene diisocyanate with a polyol, a dimer of tolylene diisocyanate, a trimer of tolylene diisocyanate, hexamethylene diisocyanate, an adduct obtained by reacting hexamethylene diisocyanate with a polyol, a dimer of hexamethylene diisocyanate, and a trimer of hexamethylene diisocyanate.

The amount of the crosslinking agent used is preferably 0.01 to 10 parts by mass, more preferably 0.01 to 5 parts by mass, and still more preferably 0.01 to 2 parts by mass with respect to 100 parts by mass of the solid content of the (meth)acrylic resin. In a case where the amount of the crosslinking agent used is 0.01 parts by mass or more, the durability of the pressure sensitive adhesive sheet is improved, and in a case where the amount of the crosslinking agent used is 10 parts by mass or less, the white spots in a ease where the pressure sensitive adhesive sheet is applied to a liquid crystal display device become less noticeable.

The method of reacting the (meth)acrylic resin with the crosslinking agent is not particularly limited, and examples thereof include a method of mixing the (meth)acrylic resin and the crosslinking agent. If necessary, a heat treatment may be carried out during the reaction. The conditions of the heat treatment are not particularly limited, and the heating temperature is preferably 60° C. to 170° C. and more preferably 60° C. to 150° C.

As will be described later, in a case of forming the pressure sensitive adhesive sheet, there is a method of using a composition for forming a pressure sensitive adhesive sheet containing a (meth)acrylic resin, a crosslinking agent, and a specific compound. In this method, in a case of forming the pressure sensitive adhesive sheet, the (meth)acrylic resin and the crosslinking agent can be reacted to form a pressure sensitive adhesive sheet containing a (meth)acrylic pressure sensitive adhesive and a specific compound.

<Method for Forming Pressure Sensitive Adhesive Sheet>

The method for forming a pressure sensitive adhesive sheet is not particularly limited, and a known method can be mentioned. Above all, a method for forming a pressure sensitive adhesive sheet using a composition for forming a pressure sensitive adhesive sheet containing a (meth)acrylic resin, a crosslinking agent, and a specific compound is preferable.

More specifically, there is a method in which a composition for forming a pressure sensitive adhesive sheet containing a (meth)acrylic resin, a crosslinking agent, and a specific compound is coated on a predetermined support, and if necessary, a drying treatment is carried out to form a pressure sensitive adhesive sheet.

The composition for forming a pressure sensitive adhesive sheet contains the (meth)acrylic resin, the crosslinking agent, and the specific compound described above, and may contain components other than the above components.

The (meth)acrylic resin (a mixture of (meth)acrylic resins in a case where two or more types of (meth)acrylic resins are combined) contained in the composition for forming a pressure sensitive adhesive sheet is such that a solution prepared by dissolving the (meth)acrylic resin in ethyl acetate to adjust a concentration of solid contents to 20% by mass preferably exhibits a viscosity of 20 Pa·s or less at 25° C., and more preferably a viscosity of 0.1 to 7 Pa·s at 25° C.

In a case where the viscosity is 20 Pa·s or less, the adhesiveness of the pressure sensitive adhesive sheet under high temperature and high humidity is improved, the possibility of floating or peeling between the display element and the pressure sensitive adhesive sheet tends to decrease, and the peeling property in reworking process tends to improve, which is preferable.

The viscosity can be measured with a Brookfield viscometer.

The composition for forming a pressure sensitive adhesive sheet preferably contains a silane-based compound. In particular, it is preferable to mix the (meth)acrylic resin before formulating the crosslinking agent with the silane-based compound.

Since the silane-based compound improves the pressure sensitive adhesive force of the pressure sensitive adhesive sheet on the glass substrate, the adhesiveness between the display element interposed between the glass substrates and the pressure sensitive adhesive sheet is improved by including the silane-based compound.

Examples of the silane-based compound include vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloyloxypropyltrimethoxysilane, 3-mercaptopropyltrimethoxysilane, 3-glycidoxypropyltrimethoxysilane, 3-glycidoxylpropyltriethoxysilane, 3-glycidoxypropyldimethoxymethylsilane, and 3-glycidoxypropylethoxydimethylsilane.

The silane-based compound may be of a silicone oligomer type. In a case where the silicone oligomer is shown in the form of a (monomer) oligomer, for example, the following can be mentioned.

Mercaptopropyl group-containing copolymers, such as 3-mercaptopropyltrimethoxysilane-tetramethoxysilane copolymer, 3-mercaptopropyltrimethoxysilane-tetraethoxysilane copolymer, 3-mercaptopropyl triethoxysilane-tetramethoxysilane copolymer, and 3-mercaptopropyltriethoxysilane-tetraethoxysilane copolymer;

Mercaptomethyl group-containing copolymers, such as mercaptomethyltrimethoxysilane-tetramethoxysilane copolymer, mercaptomethyltrimethoxysilane-tetraethoxysilane copolymer, mercaptomethyltriethoxysilane-tetramethoxysilane copolymer, and mercaptomethyltriethoxysilane-tetraethoxysilane copolymer;

Methacryloyloxypropyl group-containing copolymers such as 3-methacryloyloxypropyltrimethoxysilane-tetramethoxysilane copolymer, 3-methacryloyloxypropyltrimethoxysilane-tetraethoxysilane copolymer, 3-methacryloyloxypropyltrimethoxysilane-tetramethoxysilane copolymer, 3-methacryloyloxypropyltriethoxysilane-tetraethoxysilane copolymer, 3-methacryloyloxypropylmethyldimethoxysilane-tetramethoxysilane copolymer, 3-methacryloyloxypropylmethyldimethoxysilane-tetraethoxysilane copolymer, 3-methacryloyloxypropylmethyldiethoxysilane-tetramethoxysilane copolymer, and 3-methacryloyloxypropylmethyldiethoxysilane-tetraethoxysilane copolymer;

Acryloyloxypropyl group-containing copolymers such as 3-acryloyloxypropyltrimethoxysilane-tetramethoxysilane copolymer, 3-acryloyloxypropyltrimethoxysilane-tetraethoxysilane copolymer, 3-acryloyloxypropyltriethoxysilane-tetramethoxysilane copolymer, 3-acryloyloxypropyltriethoxysilane-tetraethoxysilane copolymer, 3-acryloyloxypropylmethyldimethoxysilane-tetramethoxysilane copolymer, 3-acryloyloxypropylmethyldimethoxysilane-tetraethoxysilane copolymer, 3-acryloyloxypropylmethyldiethoxysilane-tetramethoxysilane copolymer, and 3-acryloyloxypropylmethyldiethoxysilane-tetraethoxysilane copolymer;

Vinyl group-containing copolymers such as vinyltrimethoxysilane-tetramethoxysilane copolymer, vinyltrimethoxysilane-tetraethoxysilane copolymer, vinyltriethoxysilane-tetramethoxysilane copolymer, vinyltriethoxysilane-tetraethoxysilane copolymer, vinylmethyldimethoxysilane-tetramethoxysilane copolymer, vinylmethyldimethoxysilane-tetraethoxysilane copolymer, vinylmethyldiethoxysilane-tetramethoxysilane copolymer, and vinylmethyldiethoxysilane-tetraethoxysilane copolymer;

Amino group-containing copolymers such as 3-aminopropyltrimethoxysilane-tetramethoxysilane copolymer, 3-aminopropyltrimethoxysilane-tetraethoxysilane copolymer, 3-aminopropyltriethoxysilane-tetramethoxysilane copolymer, 3-aminopropyltriethoxysilane-tetraethoxysilane copolymer, 3-aminopropylmethyldimethoxysilane-tetramethoxysilane copolymer, 3-aminopropylmethyldimethoxysilane-tetraethoxysilane copolymer, 3-aminopropylmethyldiethoxysilane-tetramethoxysilane copolymer, and 3-aminopropylmethyldiethoxysilane-tetraethoxysilane copolymer;

The content of the silane-based compound in the composition for forming a pressure sensitive adhesive sheet is not particularly limited, and is preferably 0.01 to 10 parts by mass and more preferably 0.01 to 5 parts by mass with respect to 100 parts by mass of the solid content of the (meth)acrylic resin.

In a case where the content of the silane-based compound is 0.01 parts by mass or more, the adhesiveness between the pressure sensitive adhesive sheet and the display element is further improved. In addition, in a case where the content of the silane-based compound is 10 parts by mass or less, bleeding out of the silane-based compound from the pressure sensitive adhesive sheet is suppressed.

The silane-based compound may be used alone or in combination of two or more thereof.

The composition for forming a pressure sensitive adhesive sheet may further contain a crosslinking catalyst, an antistatic agent, a weathering stabilizer, a tackifier, a plasticizer, a softener, a dye, a pigment, an inorganic filler, and the like. Above all, in a case where a crosslinking catalyst is formulated with a crosslinking agent in the composition for forming a pressure sensitive adhesive sheet, the pressure sensitive adhesive sheet can be prepared by aging in a short time, and therefore the occurrence of floating or peeling between the polarizer layer, the protective film, or the like and the pressure sensitive adhesive sheet, and the occurrence of foaming in the pressure sensitive adhesive sheet can be suppressed, and the peeling property in reworking process may be improved.

Examples of the crosslinking catalyst include amine-based compounds such as hexamethylenediamine, ethylenediamine, polyethyleneimine, hexamethylenetetramine, diethylenetriamine, triethylenetetramine, isophoronediamine, trimethylenediamine, a polyamino resin, and a melamine resin.

In a case where the amine-based compound is used as the crosslinking catalyst in the composition for forming a pressure sensitive adhesive sheet, an isocyanate-based compound is suitable as the crosslinking agent.

The composition for forming a pressure sensitive adhesive sheet may contain a solvent.

Examples of the solvent include alcohol solvents such as methanol, ethanol, ethylene glycol, isopropyl alcohol, propylene glycol, methyl cellosolve, butyl cellosolve, and propylene glycol monomethyl ether; ester solvents such, as ethyl acetate, butyl acetate, ethylene glycol methyl ether acetate, γ-butyrolactone, propylene glycol monomethyl ether acetate, and ethyl lactate; ketone solvents such as acetone, 2-butanone, cyclopentanone, cyclohexanone, methyl amyl ketone, and methyl isobutyl ketone; aliphatic hydrocarbon solvents such as pentane, hexane, and heptane; aromatic hydrocarbon solvents such as toluene and xylene; nitrile solvents such as acetonitrile; ether solvents such as tetrahydrofuran and dimethoxyethane; and chlorinated hydrocarbon solvents such as chloroform and chlorobenzene.

Among them, 2-butanone or methyl isobutyl ketone is preferable from the viewpoint of solubility of each component and reduction of environmental load.

The method for coating the composition for forming a pressure sensitive adhesive sheet is not particularly limited, and a known method can be mentioned. For example, there is a method of coating on a predetermined support by a die coater or a gravure coater.

After the coating, the coating film may be subjected to a drying treatment if necessary. Examples of the drying treatment method include a heat treatment. The (meth)acrylic resin may be reacted with the crosslinking agent during the drying treatment (preferably a heat treatment).

In addition, the composition for forming a pressure sensitive adhesive sheet may be coated on a temporary support such as a plastic film that has been subjected to a release treatment to form a pressure sensitive adhesive sheet, and then the pressure sensitive adhesive sheet may be transferred on a film or layer to be laminated.

The thickness of the pressure sensitive adhesive sheet is not particularly limited, and is often 1 to 100 μm. From the viewpoint of thinning, the thickness of the pressure sensitive adhesive sheet is preferably less than 20 μm, more preferably 15 μm or less, still more preferably less than 10 μm, and most preferably 5 μm or less.

<Laminate>

The laminate according to the embodiment of the present invention is a laminate having at least the above-mentioned pressure sensitive adhesive sheet.

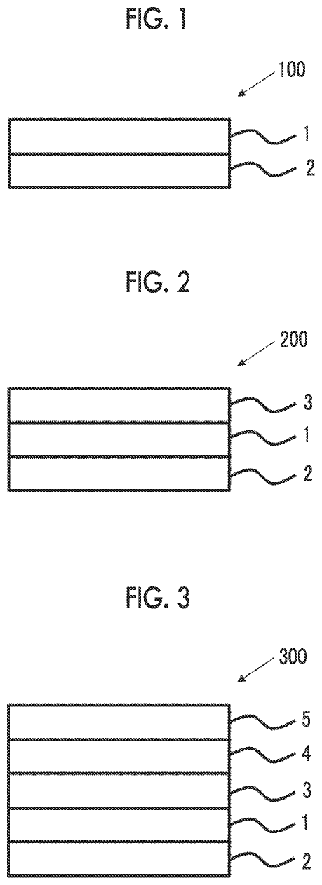

FIG. 1, FIG. 2, and FIG. 3 show a schematic cross-sectional view showing an example of the laminate according to the embodiment of the present, invention.

Here, a laminate 100 shown in FIG. 1 is a laminate with a layer configuration having a pressure sensitive adhesive sheet 1 and an optically anisotropic layer 2 in this order.

In addition, a laminate 200 shown in FIG. 2 is a laminate with a layer configuration having a polarizer layer 3, the pressure sensitive adhesive sheet 1, and the optically anisotropic, layer 2 in this order.

In addition, a laminate 300 shown in FIG. 3 is a laminate with a layer configuration having a surface protective layer 5, a pressure sensitive adhesive sheet 4, the polarizer layer 3, the pressure sensitive adhesive sheet 1, and the optically anisotropic layer 2 in this order. That is, the laminate may take an aspect having a first pressure sensitive adhesive sheet, a polarizer layer, a second pressure sensitive adhesive sheet, and an optically anisotropic layer in this order.

In FIGS. 1 to 3, the pressure sensitive adhesive sheets 1 and 4 correspond to the above-mentioned pressure sensitive adhesive sheet. The above is an aspect in which the pressure sensitive adhesive sheets 1 and 4 are both pressure sensitive adhesive sheets containing a specific compound, but the present invention is not limited to such an aspect, and one of the pressure sensitive adhesive sheets 1 and 4 may be a pressure sensitive adhesive sheet containing a specific compound.

The laminate according to the embodiment of the present invention includes at least a pressure sensitive adhesive sheet.

Hereinafter, each member included in the laminate will be described in detail.

<Optically Anisotropic Layer>

The laminate has an optically anisotropic layer. The optically anisotropic layer is a layer formed of a composition containing a polymerizable liquid crystal compound exhibiting reverse wavelength dispersibility (hereinafter, also simply referred to as “liquid crystal composition”).

In the following, first, the components in the liquid crystal composition used for forming the optically anisotropic layer will be described in detail, and then the production method and characteristics of the optically anisotropic layer will be described in detail.

Here, the liquid crystal compound exhibiting “reverse wavelength dispersibility” in the present specification refers to a liquid crystal compound in which an in-plane retardation (Re) value corresponds to or becomes higher than an increase in a measurement wavelength in a case where the Re value at a specific wavelength (visible light range) of an optically anisotropic layer prepared using this compound is measured.

The polymerizable liquid crystal compound exhibiting reverse wavelength dispersibility is not particularly limited as long as it can form a film exhibiting reverse wavelength dispersibility as described above, and examples thereof include the compounds represented by General Formula (I) described in JP2008-297210A (particularly, the compounds described in paragraphs [0034] to [0039]), the compounds represented by General Formula (I) described in JP2010-084032A (particularly, the compounds described in paragraphs [0067] to [0073]), and the compounds represented by General Formula (I) described in JP2016-081035A (particularly, the compounds described in paragraphs [0043] to [0055]).

The polymerizable liquid crystal compound is preferably a polymerizable liquid crystal compound having a partial structure represented by Formula (II), from the viewpoint that the effect of the present invention is more excellent.

(Polymerizable liquid crystal compound having a partial structure represented by Formula (II))

Formula (II)

*-D₁-Ar-D₂-* (II)

Here, in Formula (II),

D₁ and D₂ each independently represent a single bond, —O—, —CO—, —CO—O—, —C(—S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other.

Ar represents any aromatic ring selected from the group consisting of groups represented by Formulae (Ar-1) to (Ar-7).

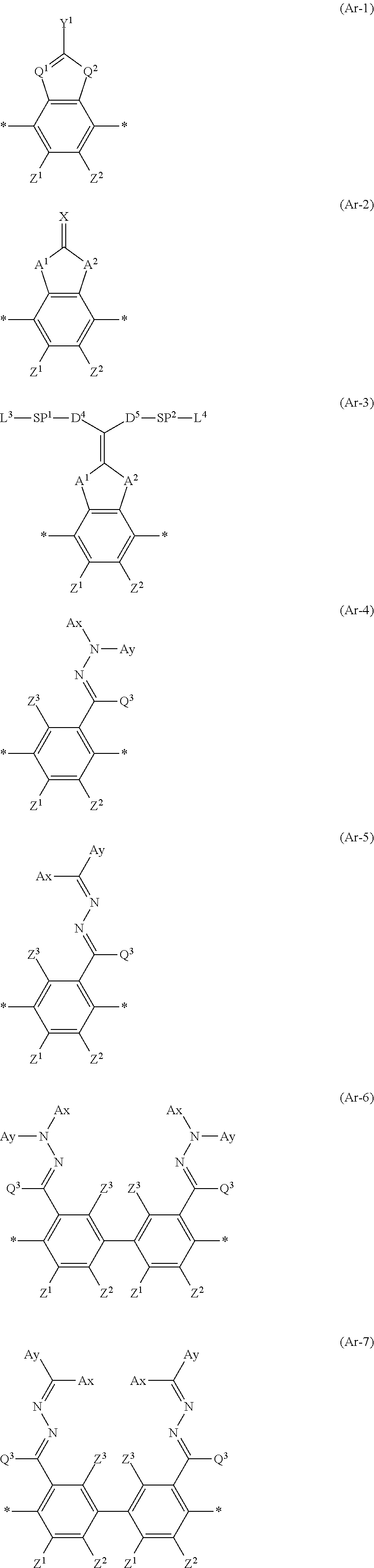

The polymerizable liquid crystal compound having a partial structure represented by Formula (II) is preferably a polymerizable liquid crystal compound represented by Formula (III).

The polymerizable liquid crystal compound represented by Formula (III) is a compound exhibiting liquid crystallinity.

L₁-G₁-D₁-Ar-D₂-G₂-L₂ (III)

In Formula (III), D₁ and D₂ each independently represent a single bond, —O—, —CO—, —CO—O—, —C(═S)O—, —CR¹R²—, —CR¹R²—CR³R⁴—, —O—CR¹R²—, —CR³R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²CO—O—CR⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'S, R³'S, and R⁴'s, the plurality of R¹'s, the plurality of R²'s, the plurality of R³'s, and the plurality of R⁴'s each may be the same as or different from each other.

G₁ and G₂ each, independently represent a divalent alicyclic hydrocarbon group having 5 to 8 carbon atoms, a group in which a plurality of the alicyclic hydrocarbon groups are linked, an aromatic hydrocarbon group, or a group in which a plurality of the aromatic hydrocarbon groups are linked, and the methylene group contained in the alicyclic hydrocarbon group may be substituted with —O—, —S—, or —NH—.

The group in which a plurality of the alicyclic hydrocarbon groups are linked means a group in which divalent alicyclic hydrocarbon groups having 5 to 8 carbon atoms are linked by a single bond. In addition, the group in which a plurality of the aromatic hydrocarbon groups are linked means a group in which aromatic hydrocarbon groups are linked by a single bond.

L₁ and L₂ each independently represent a monovalent organic group, and at least one selected from the group consisting of L₁ and L₂ represents a monovalent monovalent group having a polymerizable group.

Ar represents any aromatic ring selected from the group consisting of groups represented by Formulae (Ar-1) to (Ar-7).

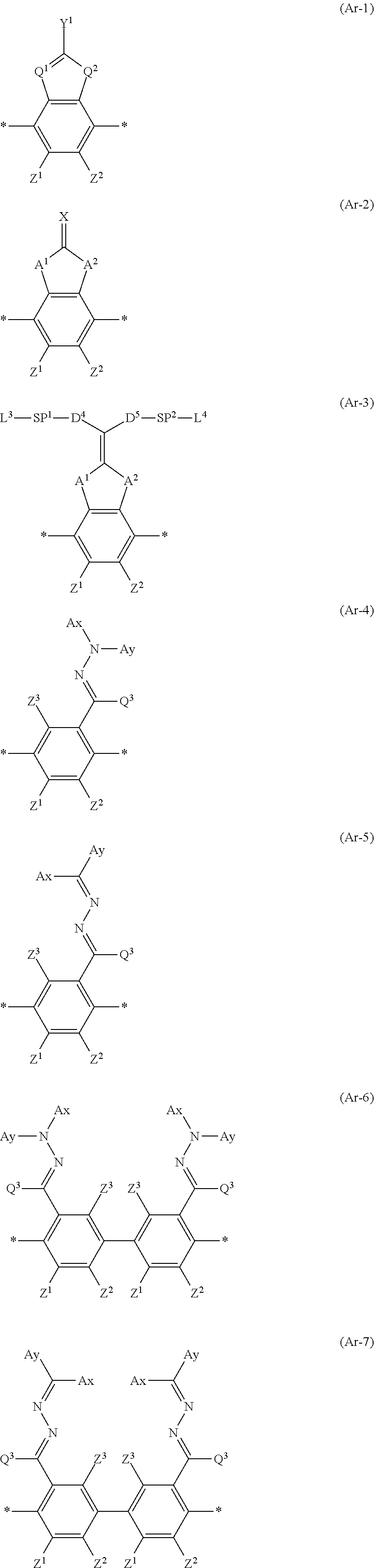

In Formula (Ar-1), Q¹ represents N or CH, Q² represents —S—, —O—, or —N(R⁷)—, R⁷ represents a hydrogen atom or an alkyl group having 1 to 6 carbon atoms, and Y¹ represents an aromatic hydrocarbon group having 6 to 12 carbon atoms or an aromatic heterocyclic group having 3 to 12 carbon atoms, each of which may have a substituent.

Examples of the alkyl group having 1 to 6 carbon atoms represented by R⁷ include a methyl group, an ethyl group, a propyl group, an isopropyl group, an n-butyl group, an isobutyl group, a see-butyl group, a tert-butyl group, an n-pentyl group, and an n-hexyl group.

Examples of the aromatic hydrocarbon group having 6 to 12 carbon atoms represented by Y¹ include aryl groups of a phenyl group, a 2,6-diethylphenyl group, and a naphthyl group.

Examples of the aromatic heterocyclic group having 3 to 12 carbon atoms represented by Y¹ include heteroaryl groups of a thienyl group, a thiazolyl group, a furyl group, and a pyridyl group.

In addition, examples of the substituent that Y¹ may have include an alkyl group, an alkoxy group, and a halogen atom.

The alkyl group is preferably an alkyl group having 1 to 18 carbon atoms, more preferably an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group), still more preferably an alkyl group having 1 to 4 carbon atoms, and particularly preferably a methyl group or an ethyl group. The alkyl group may be linear, branched, or cyclic.

The alkoxy group is, for example, preferably an alkoxy group having 0.1 to 18 carbon atoms, more preferably an alkoxy group having 1 to 8 carbon atoms (for example, a methoxy group, an ethoxy group, an n-butoxy group, and a methoxy ethoxy group), still more preferably an alkoxy group having 1 to 4 carbon atoms, and particularly preferably a methoxy group or an ethoxy group.

Examples of the halogen atom include a fluorine atom, a chlorine atom, a bromine atom, and an iodine atom, among which a fluorine atom or a chlorine atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom, or an alkyl group having 1 to 6 carbon atoms, and Z¹ and Z² may be bonded to each other to form an aromatic ring.

The monovalent aliphatic hydrocarbon group having 1 to 20 carbon atoms is preferably an alkyl group having 1 to 15 carbon atoms, more preferably an alkyl group having 1 to 8 carbon atoms, still more preferably a methyl group, an ethyl group, an isopropyl group, a tert-pentyl group (1,1-dimethylpropyl group), a ten-butyl group, or a 1,1-dimethyl-3,3-dimethyl-butyl group, and particularly preferably a methyl group, an ethyl group, or a tert-butyl group.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group, monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and cyclodecadiene; and polycyclic saturated hydrocarbon groups such as a bicyclo[2.2.1]heptyl group, a bicyclo[2.2.2]octyl group, a tricyclo[5.2.1.0^{2,6}]decyl group, a tricyclofo[3.3.1.1^{3,7}]decyl group, a tetracyclo[6.2.1.1^{3,6}.0^{2,7}]dodecyl group, and an adamantyl group.

Examples of the monovalent aromatic hydrocarbon group having 6 to 20 carbon atoms include a phenyl group, a 2,6-diethylphenyl group, a naphthyl group, and a biphenyl group, among which an aryl group having 6 to 12 carbon atoms (particularly, a phenyl group) is preferable.

Examples of the halogen atom include a fluorine atom, a chlorine atom, a bromine atom, and an iodine atom, among which a fluorine atom, a chlorine atom, or a bromine atom is preferable.

Examples of the alkyl group having 1 to 6 carbon atoms represented by R⁸ to R¹¹ include a methyl group, an ethyl group, a propyl group, an isopropyl group, an n-butyl group, an isobutyl group, a sec-butyl group, a tert-butyl group, an n-pentyl group, and an n-hexyl group.

In addition, in Formulae (Ar-2) and (Ar-3), A¹ and A² each independently represent a group selected from the group consisting of —O—, —N(R¹²)—, —S—, and —CO—, and R¹² represents a hydrogen atom or a substituent.

Examples of the substituent represented by R¹² include the same substituents that, Y⁵ in Formula (Ar-1) may have.

In addition, in Formula (Ar-2), X represents a non-metal atom of Groups 14 to 16 to which a hydrogen atom or a substituent may be bonded.

In addition, examples of the non-metal atom of Groups 14 to 16 represented by X include an oxygen atom, a sulfur atom, a nitrogen atom having a hydrogen atom or a substituent, and a carbon atom having a hydrogen atom or a substituent (for example, ═C(CN)₂), and examples of the substituent include an alkyl group, an alkoxy group, an alkyl-substituted alkoxy group, a cyclic alkyl group, an aryl group (for example, a phenyl group and a naphthyl group), a cyano group, an amino group, a nitro group, an alkylcarbonyl group, a sulfo group, and a hydroxyl group.

In addition, in Formula (Ar-3), D⁴ and D⁵ each independently represent a single bond or —CO—, —O—, —S—, —C(═S)—, —CR^{1a}R^{2a}—, —CR^{3a}═CR^{4a}—, —NR⁵*—, or a divalent linking group consisting of two or more combinations of these groups, and R^{3d} to R^{3a} each independently represent a hydrogen atom, a fluorine atom, or an alkyl group having 1 to 4 carbon atoms.

Here, examples of the divalent linking group include —CO—, —O—, —CO—O—, —C(═S)O—, —CR^{1b}R^{2b}—, —CR^{1b}R^{2b}—CR^{3b}R^{2b}—, —O—CR^{1b}R^{2b}—, —CR^{1b}R^{2b}—O—CR^{1b}R^{2b}—, —CO—O—CR^{1b}R^{2b}—, —O—CO—CR^{1b}R^{2b}—, —CR^{1b}R^{2b}—O—CO—CR^{1b}R^{2b}—, —CR^{1b}R^{2b}—CO—O—CR^{1b}R^{2b}—, —NR^{3b}—CR^{1b}R^{2b}—, and —CO—NR^{3b}—. R^{1b}, R^{2b}, and R^{3b} each independently represent a hydrogen atom, a fluorine atom, or an alkyl group having 1 to 4 carbon atoms.

In addition, in Formula (Ar-3), SP¹ and SP² each independently represent a single bond, a linear or branched alkylene group having 1 to 12 carbon atoms, or a divalent linking group in which one or more of —CH₂— constituting a linear or branched alkylene group having 1 to 12 carbon atoms are substituted with —O—, —S—, —NH—, —N(Q)-, or —CO—, and Q represents a substituent. Examples of the substituent include the same substituents that Y³ in Formula (Ar-1) may have.

Here, the linear or branched alkylene group having 1 to 12 carbon atoms is preferably, for example, a methylene group, an ethylene group, a propylene group, a butylene group, a pentylene group, a hexylene group, a methylhexylene group, or a heptylene group.

In addition, in Formula (Ar-3), L³ and L⁴ each independently represent a monovalent organic group.

Examples of the monovalent organic group include an alkyl group, an aryl group, and a heteroaryl group. The alkyl group may be linear, branched, or cyclic and is preferably linear. The number of carbon atoms in the alkyl group is preferably 1 to 30, more preferably 1 to 20, and still more preferably 1 to 10. In addition, the aryl group may be monocyclic or polycyclic and is preferably monocyclic. The number of carbon atoms in the aryl group is preferably 6 to 25 and more preferably 6 to 10. In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms m the heteroaryl group is preferably 6 to 18 and more preferably 6 to 12. In addition, the alkyl group, the aryl group, and the heteroaryl group may be unsubstituted or may have a substituent. Examples of the substituent include the same substituents that Y³ in Formula (Ar-1) may have.

In addition, in Formulae (Ar-4) to (Ar-7), Ax represents an organic group having 2 to 30 carbon atoms which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms which may have a substituent.

Examples of Ax and Ay include those described in paragraphs [0039] to [0095] of WO2014/010325A.

In addition, examples of the alkyl group having 1 to 6 carbon atoms represented by Q³ include a methyl group, an ethyl group, a propyl group, an isopropyl group, an n-butyl group, an isobutyl group, a sec-butyl group, a tert-butyl group, an N-pentyl group, and an n-hexyl group, and examples of the substituent include the same substituents that in Formula (Ar-1) may have.

With regard to the definition and preferred range of each substituent of the liquid crystal compound represented by Formula till), the descriptions regarding D¹, D², G¹, G², L¹, L², R⁴, R⁵, R⁶, R⁷, X¹, Y¹, Q¹, and Q² for Compound (A) described in JP2012-021068A can be referred to for D₁, D₂, G₁, G₂, L₁, L₂, R¹, R², R³, R⁴, Q₁, Y₁, Z₁, and Z₂, respectively, the descriptions regarding A₁, A₂, and X for the compound represented by General Formula (I) described in JP2008-107767A can be referred to for A₁, A₂, and X, respectively; and the descriptions regarding Ax, Ay, and Q¹ for the compound represented by General Formula (I) described in WO 2013/018526A can be referred to for Ax, Ay, and Q³, respectively. The description of Q¹ for Compound (A) described in JP2012-021068A can be referred to for Z₃.

In particular, the organic groups represented by L¹ and L₂ are each preferably a group represented by -D₃-G₃-Sp-P₃.

D₃ has the same definition as in D₁.

G₃ represents a single bond, a divalent aromatic ring group or heterocyclic group having 6 to 12 carbon atoms, a group in which a plurality of the aromatic ring groups or heterocyclic groups are linked, a divalent alicyclic hydrocarbon group having 5 to 8 carbon atoms, or a group in which a plurality of the alicyclic hydrocarbon groups are linked, and the methylene group contained in the alicyclic hydrocarbon group may be substituted with —O—, —S—, or —NR⁷— where R⁷ represents a hydrogen atom or an alkyl group having 1 to 6 carbon atoms.

The group in which a plurality of the aromatic ring groups or heterocyclic groups are linked means a group in which divalent aromatic ring groups or heterocyclic groups having 6 to 12 carbon atoms are linked by a single bond. In addition, the group in which a plurality of the alicyclic hydrocarbon groups are linked means a group in which divalent alicyclic hydrocarbon groups having 5 to 8 carbon atoms are linked by a single bond.

G₃ is also preferably a group in which two cyclohexane rings are bonded through a single bond.

Sp represents a spacer group represented by a single bond, —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O—(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—N(R⁸)—(CH₂)ₙ—, —C(═O)—N(R⁸)—(CH₂)ₙ—O—, —C(═O)—N(R⁸)—(CH₂—O—)ₙ—, —C(═O)—N(R⁸)—(CH₂CH₂—O—)ₘ, or —(CH₂)ₙ—O—(C═O)—(CH₂)ₙ—C(═O)—O—(CH₂)ₙ—. Here, n represents an integer of 2 to 12, m represents an integer of 2 to 6, and R⁸ represents a hydrogen atom or an alkyl group having 1 to 6 carbon atoms. In addition, the hydrogen atom of —CH₂— in each of the above groups may be substituted with a methyl group.

P₃ represents a polymerizable group.

The polymerizable group is not particularly limited and is preferably a polymerizable group capable of radical polymerization or cationic polymerization.

Examples of the radically polymerizable group include known radically polymerizable groups, among which an acryloyl group or a methacryloyl group is preferable. The acryloyl group is generally known to have a high polymerization rate and therefore the acryloyl group is preferable from the viewpoint of improving productivity; whereas the methacryloyl group can also be used as the polymerizable group of a highly birefringent liquid crystal.

Examples of the cationically polymerizable group include known cationically polymerizable groups, examples of which include an alicyclic ether group, a cyclic acetal group, a cyclic lactone group, a cyclic thioether group, a spiroorthoester group, and a vinyloxy group. Of these, an alicyclic ether group or a vinyloxy group is preferable, and an epoxy group, an oxetanyl group, or a vinyloxy group is more preferable.

Particularly preferred examples of the polymerizable group include the following.

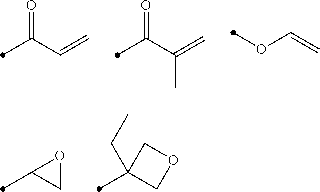

In the present specification, the “alkyl group” may be linear, branched, or cyclic, and examples thereof include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a cyclopropyl group, a cyclobutyl group, a cyclopentyl group, and a cyclohexyl group.

Preferred examples of the liquid crystal compound represented by Formula (III) are shown below, but the present invention is not limited to these liquid crystal compounds.

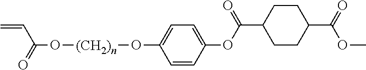

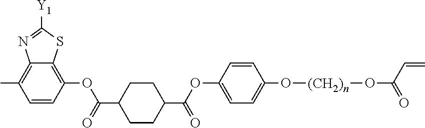

| No | Y1 | n |
|---|---|---|
| II-1-1 | 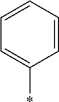 [SMILES: *c1ccccc1] | 6 |
| II-1-2 | 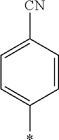 [SMILES: *c1ccc(C#N)cc1] | 6 |
| II-1-3 | 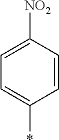 [SMILES: *c1ccc([N+](=O)[O-])cc1] | 6 |
| II-1-4 | 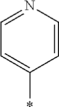 [SMILES: *c1ccncc1] | 6 |
| II-1-5 | 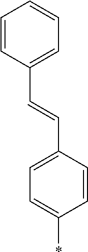 [SMILES: *c1ccc(/C=C/c2ccccc2)cc1] | 6 |
| II-1-6 | 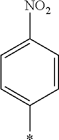 [SMILES: *c1ccc([N+](=O)[O-])cc1] | 11 |
| II-1-7 | 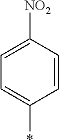 [SMILES: *c1ccc([N+](=O)[O-])cc1] | 8 |
| II-1-8 | 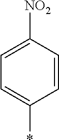 [SMILES: *c1ccc([N+](=O)[O-])cc1] | 4 |
| II-1-9 | 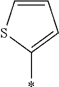 [SMILES: *c1cccs1] | 6 |
| II-1-10 | 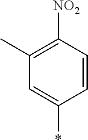 [SMILES: *c1ccc([N+](=O)[O-])c(C)c1] | 6 |
| II-1-11 | 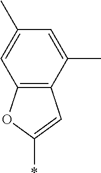 [SMILES: *c1cc2c(C)cc(C)cc2o1] | 6 |
| II-1-12 | 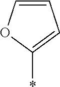 [SMILES: *c1ccco1] | 6 |
| II-1-13 | 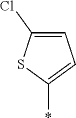 [SMILES: *c1ccc(Cl)s1] | 6 |
| II-1-14 | 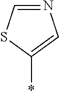 [SMILES: *c1cncs1] | 6 |
| II-1-15 | 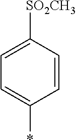 [SMILES: *c1ccc(S(C)(=O)=O)cc1] | 6 |

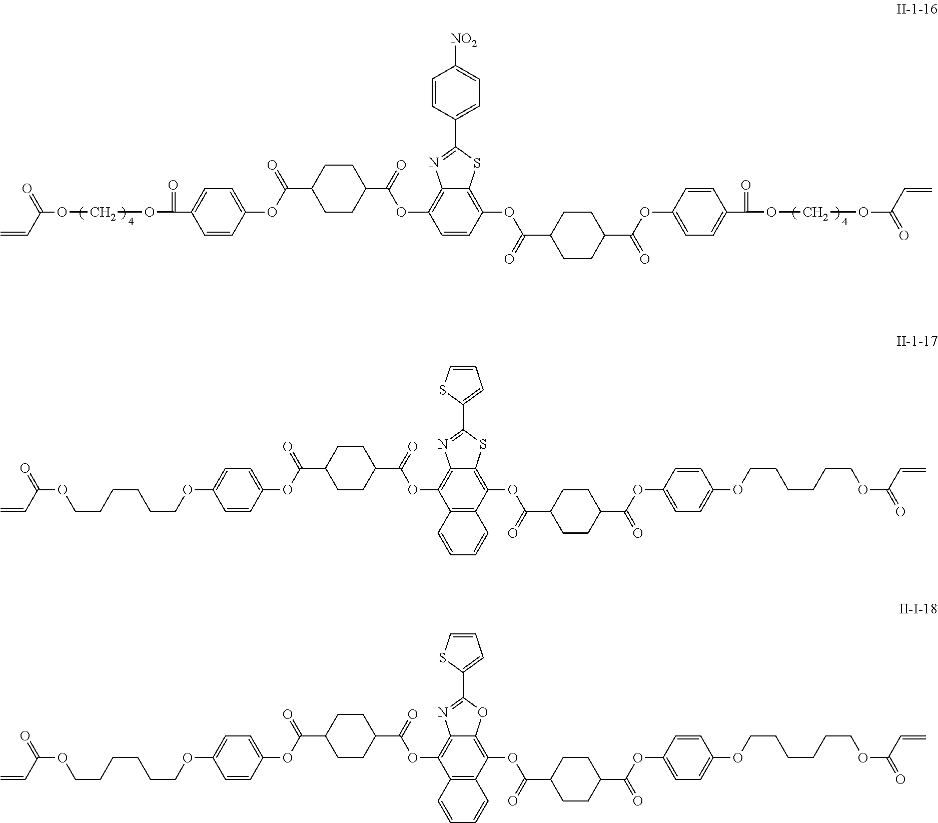

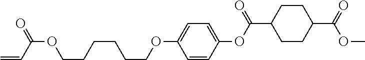 [SMILES: C=CC(=O)OCCCCCCOc1ccc(OC(=O)C2CCC(C(=O)OC)CC2)cc1]

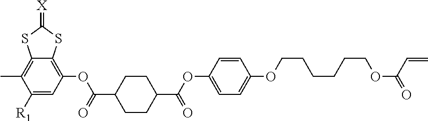

| No | X | R1 |
|---|---|---|
| II-2-1 | 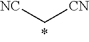 | H |
| II-2-2 | 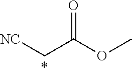 | H |
| II-2-3 | 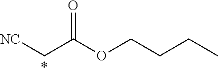 | H |
| II-2-4 | 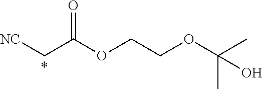 | H |
| II-2-5 | 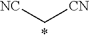 | CH₃ |
| II-2-6 | 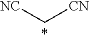 | 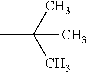 |
| II-2-7 | S | H |

In the above formulae, “*” represents a bonding position.

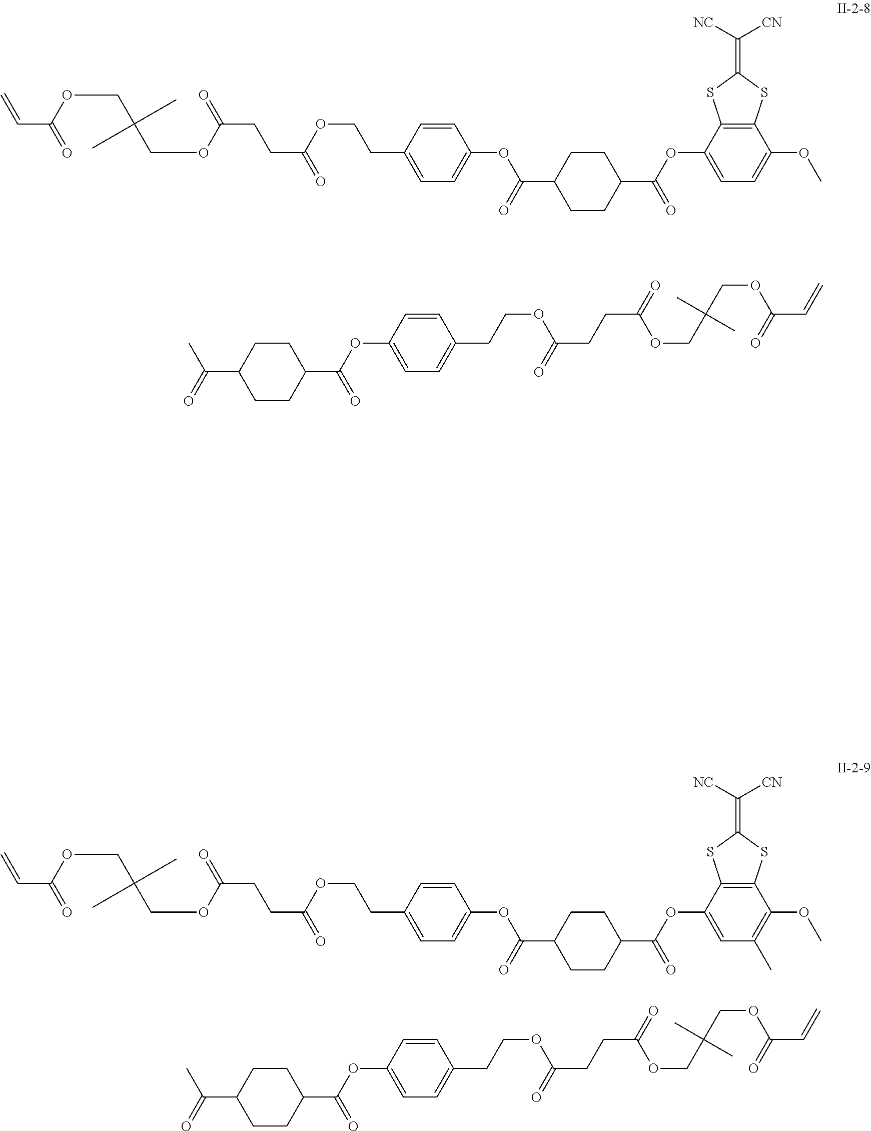

The group adjacent to the acryloyloxy group in Formulae II-2-8 and II-2-9 represents a propylene group (a group in which a methyl group is substituted with an ethylene group), and represents a mixture of regioisomers with different methyl group positions.

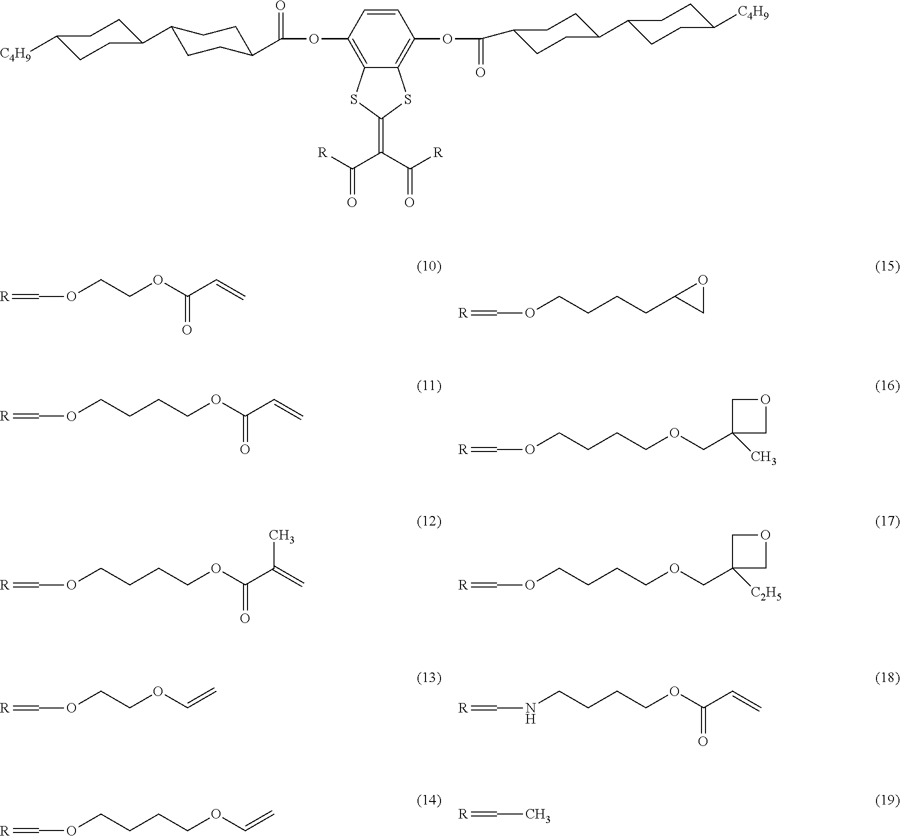

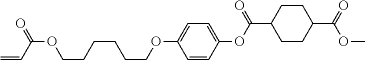 [SMILES: C=CC(=O)OCCCCCCOc1ccc(OC(=O)C2CCC(C(=O)OC)CC2)cc1]

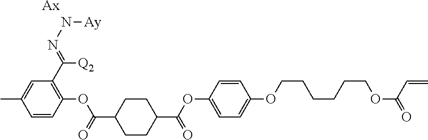

| No | Ax | Ay | Q2 |
|---|---|---|---|
| II-3-1 | 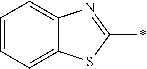 [SMILES: *c1nc2ccccc2s1] | H | H |
| II-3-2 | 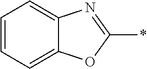 [SMILES: *c1nc2ccccc2o1] | H | H |
| II-3-3 | 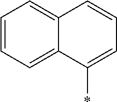 [SMILES: *c1cccc2ccccc12] | H | H |
| II-3-4 | Ph | Ph | H |
| II-3-5 | 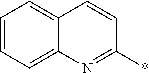 [SMILES: *c1ccc2ccccc2n1] | H | H |
| II-3-6 | 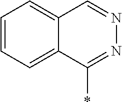 [SMILES: *c1nncc2ccccc12] | H | H |
| II-3-7 | 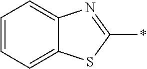 [SMILES: *c1nc2ccccc2s1] | CH₃ | H |
| II-3-8 | 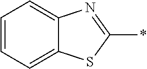 [SMILES: *c1nc2ccccc2s1] | C₄H₉ | H |
| II-3-9 | 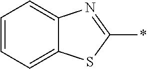 [SMILES: *c1nc2ccccc2s1] | C₆H₁₃ | H |
| II-3-10 | 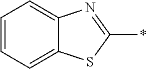 [SMILES: *c1nc2ccccc2s1] | 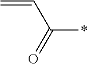 [SMILES: *C(=O)C=C] | H |
| II-3-11 | 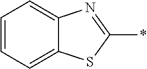 [SMILES: *c1nc2ccccc2s1] | 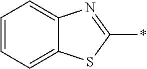 [SMILES: *c1nc2ccccc2s1] | H |
| II-3-12 | 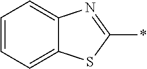 [SMILES: *c1nc2ccccc2s1] | CH₂CN | H |
| II-3-13 | 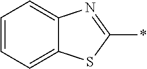 [SMILES: *c1nc2ccccc2s1] | 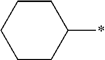 [SMILES: *C1CCCCC1] | H |
| II-3-14 | 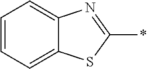 [SMILES: *c1nc2ccccc2s1] | 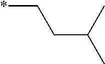 [SMILES: *CCC(C)C] | H |
| II-3-15 | 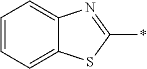 [SMILES: *c1nc2ccccc2s1] | CH₂CH₂OH | H |
| II-3-16 | 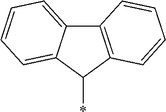 [SMILES: *C1c2ccccc2-c2ccccc21] | H | H |
| II-3-17 | 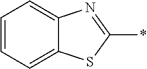 [SMILES: *c1nc2ccccc2s1] | CH₂CF₃ | H |
| II-3-18 | 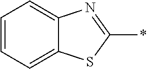 [SMILES: *c1nc2ccccc2s1] | H | CH₃ |
| II-3-19 | 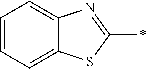 [SMILES: *c1nc2ccccc2s1] | 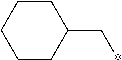 [SMILES: *CC1CCCCC1] | H |
| II-3-20 | 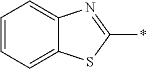 [SMILES: *c1nc2ccccc2s1] | 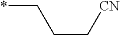 [SMILES: *CCCC#N] | H |
| II-3-21 | 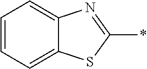 [SMILES: *c1nc2ccccc2s1] | 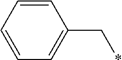 [SMILES: *Cc1ccccc1] | H |
| II-3-22 | 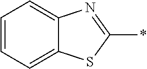 [SMILES: *c1nc2ccccc2s1] | 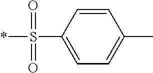 [SMILES: *S(=O)(=O)c1ccc(C)cc1] | H |
| II-3-23 | 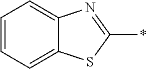 [SMILES: *c1nc2ccccc2s1] | 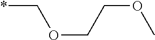 [SMILES: *COCCOC] | H |
| II-3-24 | 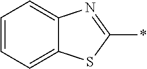 [SMILES: *c1nc2ccccc2s1] | 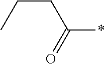 [SMILES: *C(=O)CCC] | H |
| II-3-25 | 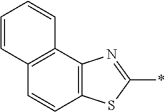 [SMILES: *c1nc2c(ccc3ccccc32)s1] | C₆H₁₃ | H |

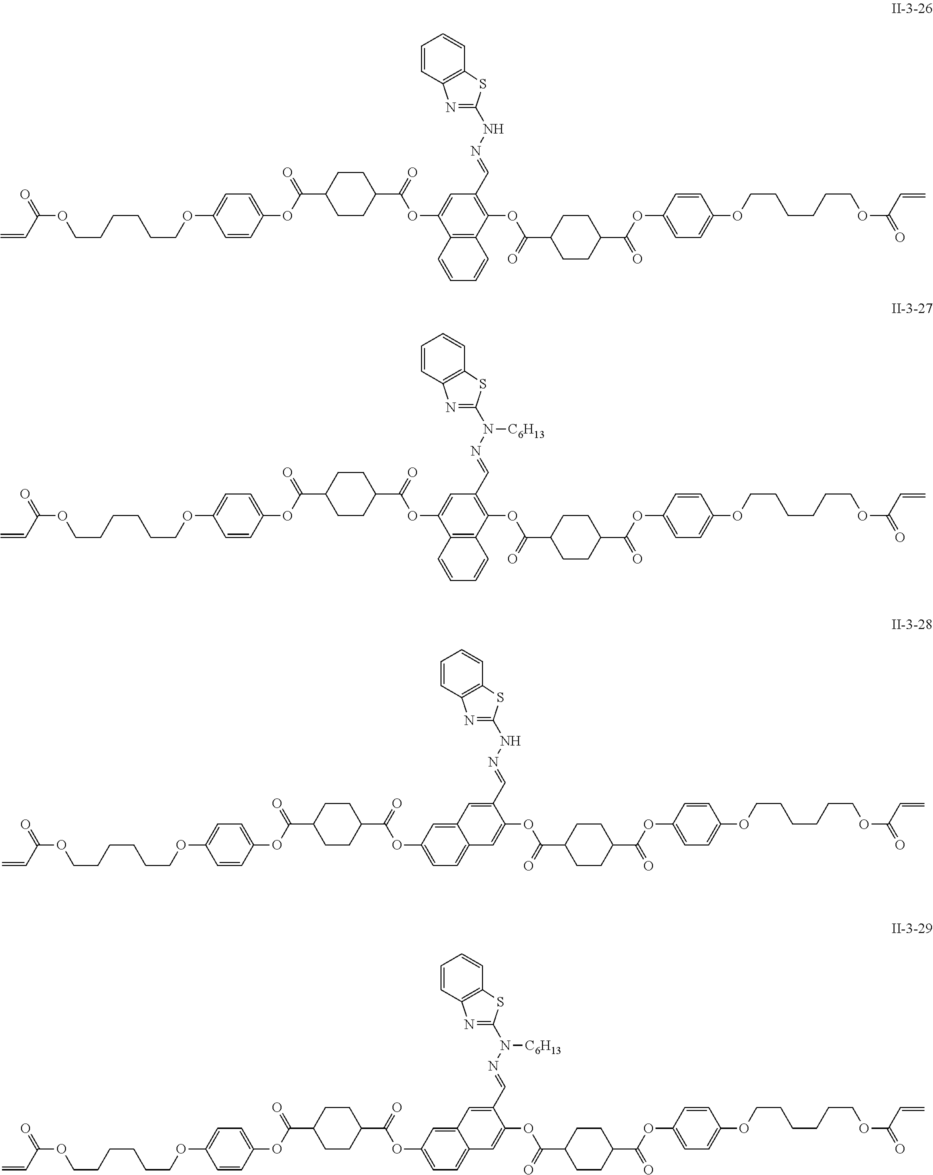

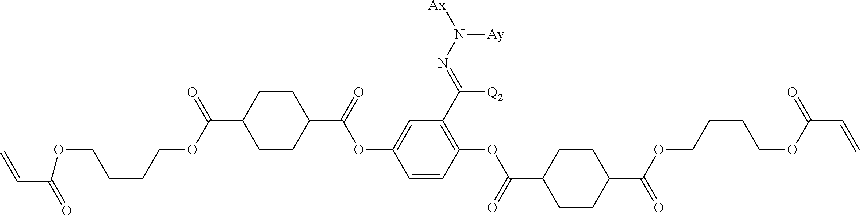

| No | Ax | Ay | Q2 |
|---|---|---|---|
| II-3-30 | 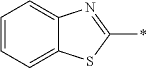 [SMILES: *c1nc2ccccc2s1] | H | H |
| II-3-31 | 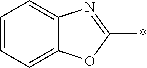 [SMILES: *c1nc2ccccc2o1] | H | H |
| II-3-32 | 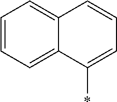 [SMILES: *c1cccc2ccccc12] | H | H |
| II-3-33 | Ph | Ph | H |
| II-3-34 | 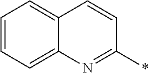 [SMILES: *c1ccc2ccccc2n1] | H | H |
| II-3-35 | 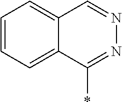 [SMILES: *c1nncc2ccccc12] | H | H |
| II-3-36 | 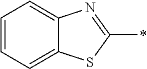 [SMILES: *c1nc2ccccc2s1] | CH₃ | H |
| II-3-37 | 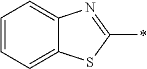 [SMILES: *c1nc2ccccc2s1] | C₄H₉ | H |
| II-3-38 | 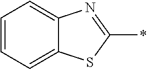 [SMILES: *c1nc2ccccc2s1] | C₆H₁₃ | H |
| II-3-39 | 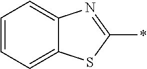 [SMILES: *c1nc2ccccc2s1] | 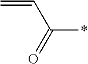 [SMILES: *C(=O)C=C] | H |
| II-3-40 | 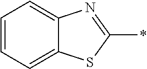 [SMILES: *c1nc2ccccc2s1] | 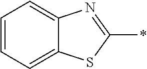 [SMILES: *c1nc2ccccc2s1] | H |
| II-3-41 | 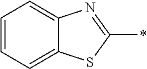 [SMILES: *c1nc2ccccc2s1] | CH₂CN | H |
| II-3-42 | 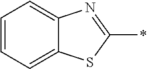 [SMILES: *c1nc2ccccc2s1] | 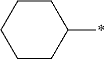 [SMILES: *C1CCCCC1] | H |
| II-3-43 | 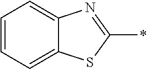 [SMILES: *c1nc2ccccc2s1] | 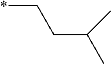 [SMILES: *CCC(C)C] | H |
| II-3-46 | 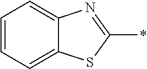 [SMILES: *c1nc2ccccc2s1] | CH₂CH₂OH | H |
| II-3-45 | 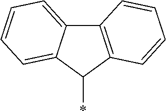 [SMILES: *C1c2ccccc2-c2ccccc21] | H | H |
| II-3-46 | 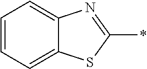 [SMILES: *c1nc2ccccc2s1] | CH₂CF₃ | H |
| II-3-47 | 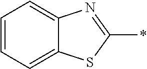 [SMILES: *c1nc2ccccc2s1] | H | CH₃ |
| II-3-48 | 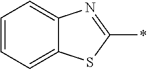 [SMILES: *c1nc2ccccc2s1] | 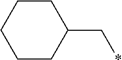 [SMILES: *CC1CCCCC1] | H |
| II-3-49 | 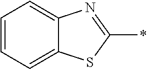 [SMILES: *c1nc2ccccc2s1] | 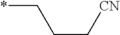 [SMILES: *CCCC#N] | H |
| II-3-50 | 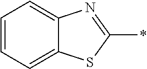 [SMILES: *c1nc2ccccc2s1] | 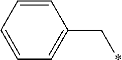 [SMILES: *Cc1ccccc1] | H |
| II-3-51 | 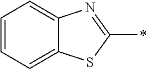 [SMILES: *c1nc2ccccc2s1] | 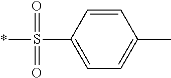 [SMILES: *S(=O)(=O)c1ccc(C)cc1] | H |
| II-3-52 | 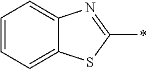 [SMILES: *c1nc2ccccc2s1] | 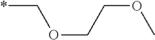 [SMILES: *COCCOC] | H |
| II-3-53 | 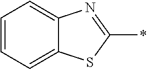 [SMILES: *c1nc2ccccc2s1] | 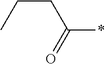 [SMILES: *C(=O)CCC] | H |
| II-3-54 | 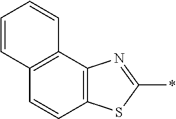 [SMILES: *c1nc2c(ccc3ccccc32)s1] | C₆H₁₃ | H |

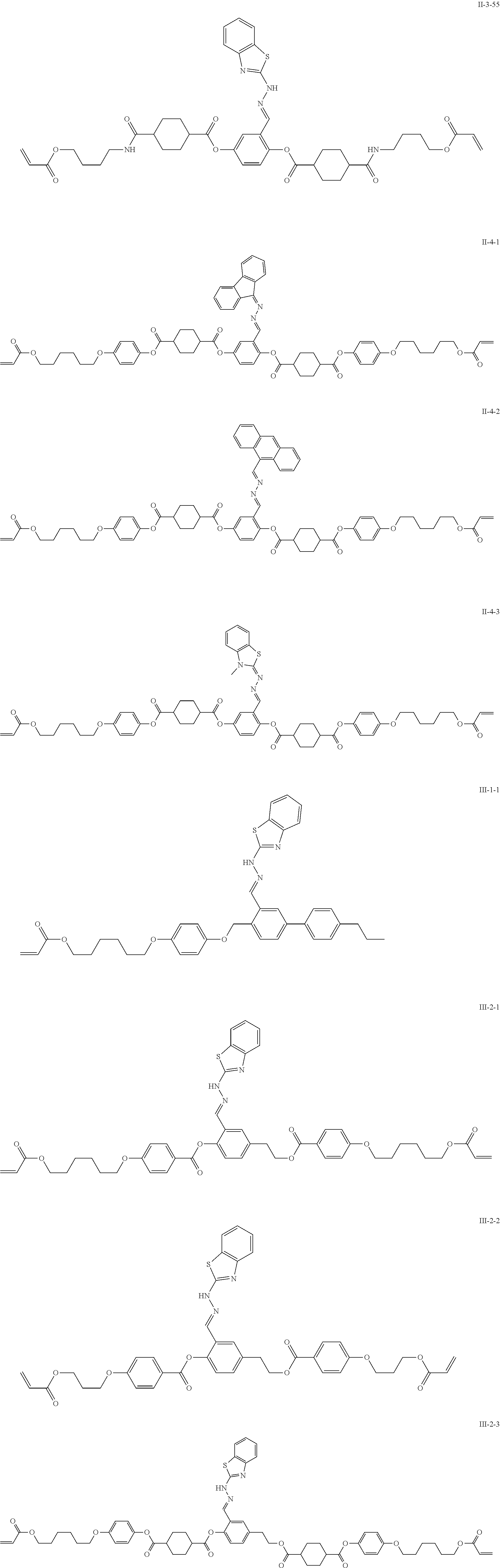

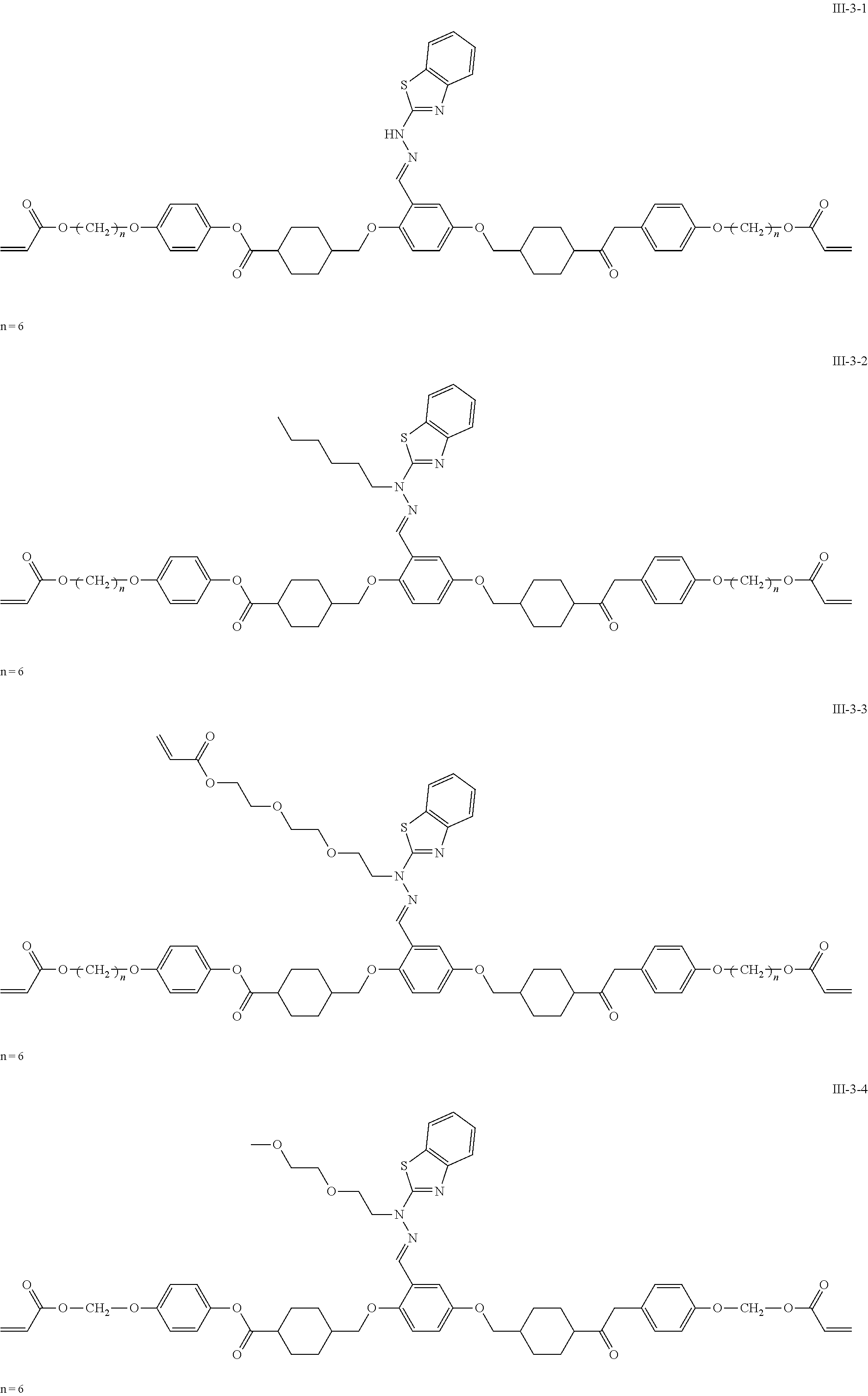

The content of the polymerizable liquid crystal compound represented by Formula (III) in the liquid crystal composition is not particularly limited, and is preferably 50% to 100% by mass and more preferably 70% to 99% by mass with respect to the total solid content in the liquid crystal composition.

The solid content means other components in the liquid crystal composition excluding a solvent, and the components are calculated as the solid content even in a case where the properties thereof are liquid.

The liquid crystal composition may contain a liquid crystal compound other than the polymerizable liquid crystal compound represented by Formula (III). Examples of the other liquid crystal compound include known liquid crystal compounds (a rod-like liquid crystal compound and a disk-like liquid crystal compound). The other liquid crystal compound may have a polymerizable group.

The content of the other liquid crystal compound in the liquid crystal composition is preferably 0% to 50% by mass and more preferably 10% to 40% by mass with respect to the total mass of the polymerizable liquid crystal compound, represented by Formula (III).

The other liquid crystal compound is preferably a liquid crystal compound having, as a part, a cyclohexane ring in which one hydrogen atom is substituted with a linear alkyl group.

Here, the “cyclohexane ring in which one hydrogen atom is substituted with a linear alkyl group” refers to a cyclohexane ring in which one hydrogen atom of a cyclohexane ring present on a molecular terminal side is substituted with a linear alkyl group, for example, in a ease of having two cyclohexane rings, as shown in Formula (2).

Examples of the above-mentioned compound include compounds having a group represented by Formula (2), among which a compound represented by Formula. (3) having a (meth)acryloyl group is preferable from the viewpoint that a laminate having excellent thermal durability can be obtained.

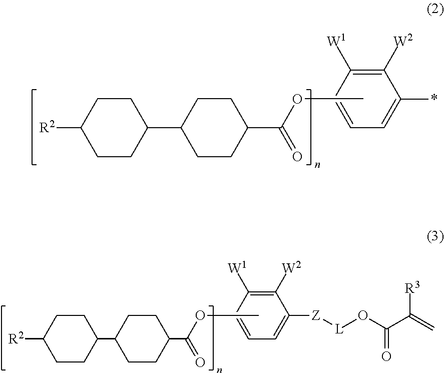

In Formula (2), * represents a bonding position.

In addition, in Formulae (2) and (3), R² represents an alkyl group having 1 to 10 carbon atoms, n represents 1 or 2, W¹ and W² each independently represent an alkyl group, an alkoxy group, or a halogen atom, and W¹ and W² may be bonded to each other to form, a ring structure which may have a substituent.

In addition, in Formula (3), Z represents —COO—, L represents an alkylene group having 1 to 6 carbon atoms, and R³ represents a hydrogen atom or a methyl group.

Examples of the above-mentioned compound include compounds represented by Formulae A-1 to A-5. In Formula A-3, R⁴ represents an ethyl group or a butyl group.

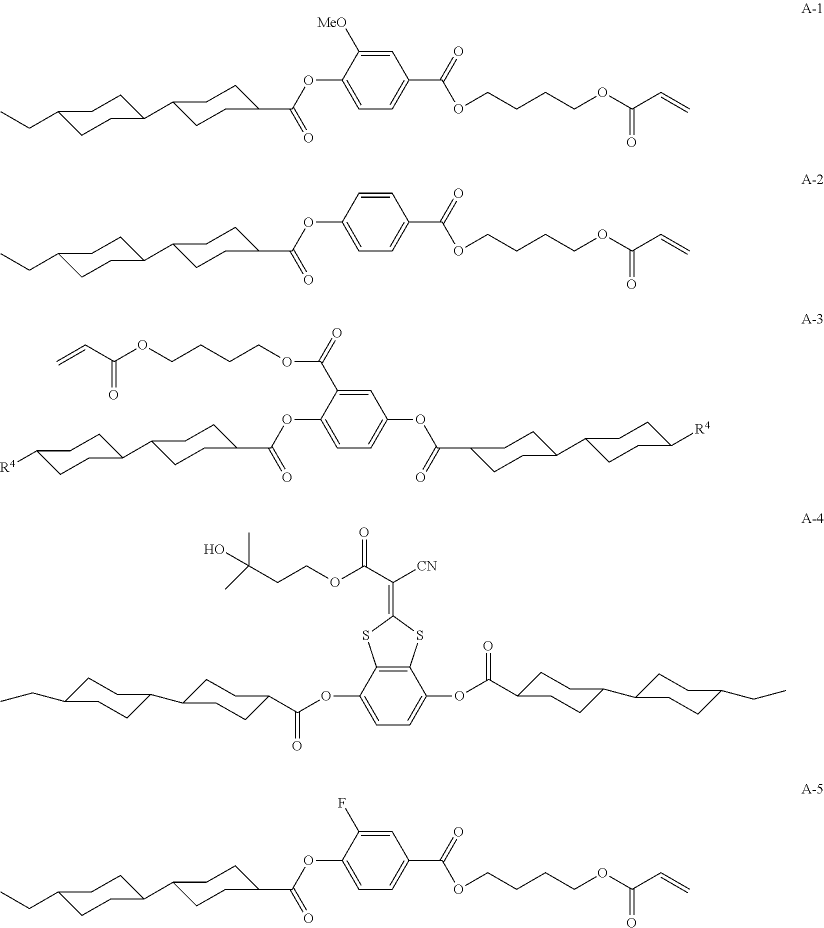

Examples of the other liquid crystal compound include a compound represented by Formula (M1), a compound represented by Formula (M2), and a compound represented by Formula (M3), described in paragraphs [0030] to [0033] of JP2014-077068A.

The liquid crystal composition may contain a polymerizable monomer other than the polymerizable liquid crystal compound represented by Formula (III) and the other liquid crystal compound having a polymerizable group. Above all, a polymerizable compound having two or more polymerizable groups (polyfunctional polymerizable monomer) is preferable from the viewpoint that the strength of an optically anisotropic layer is more excellent.

The polyfunctional polymerizable monomer is preferably a poly functional radically polymerizable monomer. Examples of the polyfunctional radically polymerizable monomer include polymerizable monomers described in paragraphs [0018] to [0020] in JP2002-296423A.

In addition, in a case where the liquid crystal composition contains a polyfunctional polymerizable monomer, the content of the polyfunctional polymerizable monomer is preferably 0.1% to 20% by mass, more preferably 0.1% to 10% by mass, and still more preferably 0.1% to 5% by mass with respect to the total solid content in the liquid crystal composition.

The liquid crystal composition may contain a polymerization initiator.

The polymerization initiator is preferably a photopolymerization initiator capable of initiating a polymerization reaction upon irradiation with ultraviolet rays.

Examples of the photopolymerization initiator include α-carbonyl compounds (as described in U.S. Pat. Nos. 2,367,661A and 2,367,670A), acyloin ethers (as described in U.S. Pat. No. 2,448,828A), α-hydrocarbon-substituted aromatic acyloin compounds (as described in U.S. Pat. No. 2,722,512A), polynuclear quinone compounds (as described in U.S. Pat. Nos. 3,046,127A and 2,951,758A), combinations of triarylimidazole dimers with p-aminophenyl ketones (as described m U.S. Pat. No. 3,549,367A), acridine and phenazine compounds (as described in JP1985-105667A (JP-S60-105667A) and U.S. Pat. No. 4,239,850A), oxadiazole compounds (as described in U.S. Pat. No. 4,212,970A), and acylphosphine oxide compounds (as described in JP1988-040799B (JP-S63-040799B), JP1993-029234B (JP-H05-029234B), JP1998-095788A (JP-H10-095788A), and JP1998-029997A(JP-H10-029997A)).

The polymerization initiator is preferably an oxime-type polymerization initiator and more preferably a compound represented by Formula (2).

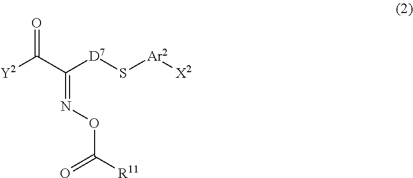

In Formula (2), X² represents a hydrogen atom or a halogen atom.

In addition, in Formula (2), Ar² represents a divalent aromatic group, and D⁷ represents a divalent organic group having 1 to 12 carbon atoms.

In addition, in Formula (2), R¹¹ represents an alkyl group having 1 to 12 carbon atoms, and Y² represents a monovalent organic group.

Examples of the halogen atom represented by X² in Formula (2) include a fluorine atom, a chlorine atom, a bromine atom, and an iodine atom, among which a chlorine atom is preferable.

In addition, examples of the divalent aromatic group represented by Ar² in Formula (2) include divalent groups which have an aromatic hydrocarbon ring such as a benzene ring, a naphthalene ring, an anthracene ring, or a phenanthroline ring; or an aromatic heterocyclic ring such as a furan ring, a pyrrole ring, a thiophene ring, a pyridine ring, a thiazole ring, or a benzothiazole ring.

In addition, examples of the divalent organic group having 1 to 12 carbon atoms represented by D⁷ in Formula (2) include a linear or branched alkylene group having 1 to 12 carbon atoms, specific examples of which include a methylene group, an ethylene group, and a propylene group.

In addition, examples of the alkyl group having 1 to 12 carbon atoms represented by R¹¹ in Formula (2) include a methyl group, an ethyl group, and a propyl group.

In addition, examples of the monovalent organic group represented by Y² in Formula (2) include a functional group containing a benzophenone skeleton ((C₆H₅)₂CO). Specifically, a functional group containing a benzophenone skeleton in which the terminal benzene ring is unsubstituted or monosubstituted is preferable such as a group represented by Formula (2a) and a group represented by Formula (2b). In Formula (2a) and Formula (2b), * represents a bonding position, that is, a bonding position to the carbon atom of the carbonyl group in Formula (2).

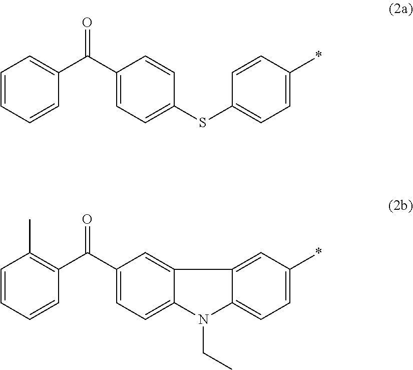 [SMILES: *c1ccc(Sc2ccc(C(=O)c3ccccc3)cc2)cc1 ; *c1ccc2c(c1)c1cc(C(=O)c3ccccc3C)ccc1n2CC]

Examples of the compound represented by Formula (2) include a compound represented by Formula S-1 and a compound represented by Formula S-2.

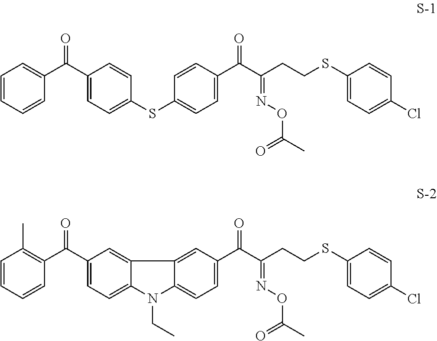 [SMILES: CC(=O)O/N=C(\CCSc1ccc(Cl)cc1)C(=O)c1ccc(Sc2ccc(C(=O)c3ccccc3)cc2)cc1 ; CCn1c2ccc(C(=O)/C(CCSc3ccc(Cl)cc3)=N/OC(C)=O)cc2c2cc(C(=O)c3ccccc3C)ccc21]

The content of the polymerization initiator in the liquid crystal composition is not particularly limited, and is preferably 0.01% to 20% by mass and more preferably 0.5% to 5% by mass with respect to the total solid content in the liquid crystal composition.

The liquid crystal composition may contain a solvent from the viewpoint of workability for forming an optically anisotropic layer.

Examples of the solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (tor example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolve (for example, methyl cellosolve and ethyl cellosolve), cellosolve acetates, sulfoxides (for example, dimethyl sulfoxide), and amides (for example, dimethyl formamide and dimethyl acetamide).

These solvent compounds may be used alone or in combination of two or more thereof.

The liquid crystal composition may contain a leveling agent from the viewpoint of keeping the surface of an optically anisotropic layer smooth.

The leveling agent is preferably a fluorine-based leveling agent or a silicon-based leveling agent from the viewpoint that the leveling effect is high relative to the amount added, and more preferably a fluorine-based leveling agent from the viewpoint that it is less likely to cause bleeding (bloom or bleed).

Examples of the leveling agent include the compounds described in paragraphs [0079] to [0102] of JP2007-069471A, the polymerizable liquid crystal compound represented by General Formula (III) described in JP2013-047204A (particularly, the compounds described in paragraphs [0020] to [0032]), the polymerizable liquid crystal compound represented by General Formula (III) described in JP2012-211306A (particularly, the compounds described in paragraphs [0022] to [0029]), the liquid crystal alignment accelerator represented by General Formula (III) described in JP2002-129162A (particularly, the compounds described in paragraphs [0076] to [0078] and [0082] to [0084]), and the compounds represented by General Formulae (I), (II), and (III) described in JP2005-099248A (particularly, the compounds described in paragraphs [0092] to [0096]). In addition, the leveling agent may also function as an alignment control agent which will be described later.

The liquid crystal composition may contain an alignment control agent, if necessary.

The alignment control agent can result in the formation of various alignment states such as homeotropic alignment (vertical alignment), tilt alignment, hybrid alignment, and cholesteric alignment in addition to homogeneous alignment, and makes it possible to achieve, more uniform and more precise control of a specific alignment state.

As the alignment control agent which accelerates the homogeneous alignment, for example, a low molecular weight alignment control agent or a high molecular weight alignment control agent can be used.

With regard to the low molecular weight alignment control agent, reference can be made to the description in, for example, paragraphs [0009] to [0083] of JP2002-020363A, paragraphs [0111] to [0120] of JP2006-106662A, and paragraphs [0021] to [0029] of JP2012-211306A, the contents of which are incorporated herein by reference.

In addition, with regard to the high molecular weight alignment control agent, reference can be made to the description in, for example, paragraphs [0021] to [0057] of JP2004-198511A and paragraphs [0121] to [0167] of JP2006-106662A, the contents of which are incorporated herein by reference.

In addition, examples of the alignment control agent that forms or accelerates the homeotropic alignment include a boronic acid compound and an onium salt compound, and specifically, reference can be made to the compounds described in paragraphs [0023] to [0032] of JP2008-225281A, paragraphs [0052] to [0058] of JP2012-208397A, paragraphs [0024] to [0055] of JP2008-026730A, and paragraphs [0043] to [0055] of JP2016-193869A, the contents of which are incorporated herein by reference.

In a case where the liquid crystal composition contains an alignment control agent, the content of the alignment control agent is not particularly limited, and is preferably 0.01% to 10% by mass and more preferably 0.05% to 5% by mass with respect to the total solid content in the liquid crystal composition.

The liquid crystal composition may contain components other than the above-mentioned components, examples of which include a surfactant, a tilt, angle control agent, an alignment assistant, a plasticizer, and a crosslinking agent.

(Method for Producing Optically Anisotropic Layer)

The method for producing an optically anisotropic layer is not particularly limited, and a known method can be mentioned.

For example, the liquid crystal composition is coated on a predetermined substrate (for example, a support layer which will be described later) to form a coating film, and the obtained coating film is subjected to a curing treatment (irradiation with active energy rays (light irradiation treatment) and/or heat treatment), whereby a cured coating film (optically anisotropic layer) can be produced, if necessary, an alignment layer which will be described later may be used.

The liquid crystal composition can be coated by a known method (for example, a wire bar coating method, an extrusion coating method, a direct gravure coating method, a reverse gravure coating method, or a die-coating method).

In the method for producing an optically anisotropic layer, it is preferable to carry out an alignment treatment of the liquid crystal compound contained in the coating film before subjecting the coating film to the curing treatment.

The alignment treatment can be carried out by drying or heating at room temperature (for example, 20° C. to 25° C.). In a case of a thermotropic liquid crystal compound, the liquid crystal phase formed by the alignment treatment can generally be transience by a change in temperature or pressure. In a case of a liquid crystal compound having lyotropic properties, the liquid crystal phase formed by the alignment treatment, can also be transferred by a composition ratio such as an amount of solvent.

In a case where the alignment treatment is a heat, treatment, the heating time (heat aging time) is preferably 10 seconds to 5 minutes, more preferably 10 seconds to 3 minutes, and still more preferably 10 seconds to 2 minutes.

The above-mentioned curing treatment (irradiation with active energy rays (light irradiation treatment) and/or heat treatment) on the coating film can also be said to be an immobilization treatment for fixing the alignment of the liquid crystal compound.

The immobilization treatment is preferably carried out by irradiation with active energy rays (preferably ultraviolet rays), and the liquid crystal is immobilized by the polymerization of the liquid crystal compound.

(Characteristics of Optically Anisotropic Layer)

The optically anisotropic layer is a film formed by using the above-mentioned composition.

The optical characteristics of the optically anisotropic layer are not particularly limited, and it is preferable that the optically anisotropic layer functions as a λ/4 plate.

The λ/4 plate is a plate having a function of converting linearly polarized light having a certain specific wavelength into circularly polarized light (or converting circularly polarized light into linearly polarized light), and refers to a plate (optically anisotropic layer) in which an in-plane retardation Re (λ) at a specific wavelength λ nm satisfies Re (λ)=λ/4.

This expression may be achieved at any wavelength in a visible light range (for example, 550 nm), but the in-plane retardation Re (550) at a wavelength of 550 nm preferably satisfies a relationship of 110 nm≤Re (550)≤160 nm, and more preferably a relationship of 110 nm≤Re (550)≤150 nm.

It is preferable that Re (450), which is the in-plane retardation of the optically anisotropic layer measured at a wavelength of 450 nm, Re (550), which is the in-plane retardation of the optically anisotropic layer measured at a wavelength of 550 nm, and Re (650), which is the in-plane retardation of the optically anisotropic layer measured at a wavelength of 650 nm, have a relationship of Re (450)≤Re (550)≤Re (650). That is, it can be said that this relationship represents the reverse wavelength dispersibility.

The optically anisotropic layer may be an A-plate or a C-plate, and is preferably a positive A-plate.

The positive A-plate can be obtained, for example, by horizontally aligning the polymerizable liquid crystal compound represented by Formula (III).

The optically anisotropic layer may have a monolayer structure or a polylayer structure. In a case of a polylayer structure, an A-plate (for example, a positive A-plate) and a C-plate (for example, a positive C-plate) may be laminated.

In a case where the optically anisotropic layer has a polylayer structure, each layer corresponds to a layer formed by using the above-mentioned composition.

In the present specification, the positive A-plate is defined as follows. The positive A-plate (A-plate which is positive) satisfies the relationship of Expression (A1) in a case where a refractive index in a film in-plane stow axis direction (in a direction in which an in-plane refractive index is maximum) is defined as nx, a refractive index in an in-plane direction orthogonal to the in-plane slow axis is defined as ny, and a refractive index in a thickness direction is defined as nz. In addition, the positive A-plate has an Rth showing a positive value.

nx>ny≈nz Expression (A1)

Furthermore, the symbol “≈” encompasses not only a case where the both sides are completely the same as each other hut also a case where the both sides are substantially the same as each other. The expression “substantially the same” means that, for example, a ease where (ny−nz)×d (in which d is a thickness of a film) is −10 to 10 nm and preferably −5 to 5 nm is also included in “ny≈nz”.

In the present specification, the positive C-plate is defined as follows. The positive C-plate (C-plate which is positive) satisfies the relationship of Expression (A2) in a ease where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz. In addition, the positive C-plate has an Rth showing a negative value.

nx≈ny<nz Expression (A2)

Furthermore, the symbol “≈” encompasses not only a case where the both sides are completely the same as each other but also a case where the both sides are substantially the same as each other. The expression “substantially the same” means that, for example, a case where (nx−ny)×d (in which d is a thickness of a film) is −10 to 10 nm and preferably −5 to 5 nm is also included in “nx≈ny”.

In addition, in the positive C-plate, Re≈0 according to the above definition.

The thickness of the optically anisotropic layer is not particularly limited, and is preferably 0.5 to 10 μm and more preferably 1.0 to 5 μm from the viewpoint of thinning.

In addition, the relationship between the transmission axis of the polarizer layer and the slow axis of the optically anisotropic layer in the laminate is not particularly limited.

In a case where the laminate is applied to antireflection applications, it is preferable that the optically anisotropic layer is a λ/4 plate and the angle formed by the transmission axis of the polarizer layer and the slow axis of the optically anisotropic layer is in a range of 45°±10° (35° to 55°).

In addition, in a case where the laminate is applied to an optical compensation application for an oblique viewing angle of an in-plane switching (IPS) liquid crystal, it is preferable that the optically anisotropic layer has a polylayer structure of a positive A-plate and a positive C-plate, each of which is a λ/4 plate, and the angle formed by the transmission axis of the polarizer layer and the slow axis of the optically anisotropic layer is in a range oi 0°±10° (−10° to 10°) or 90°±10° (80° to 100°).

<Alignment Layer>

The laminate according to the embodiment of the present invention may have an alignment, layer for aligning the above-mentioned liquid crystal.

Examples of the method for forming an alignment layer include methods such as rubbing treatment of a film surface of an organic compound (preferably a polymer), oblique vapor deposition of an inorganic compound, formation of a layer having microgrooves, and accumulation of an organic compound (for example, ω-tricosanoic acid, dioctadecylmethylammonium chloride, or methyl stearate) by the Langmuir-Blodgett (LB) film method. Further, there is also known, an alignment layer capable of expressing an alignment function by application of an electric field, application of a magnetic field, or light irradiation.

Above all, in the present invention, an alignment layer formed by the rubbing treatment is preferable from the viewpoint of easy control of the pretilt angle of the alignment layer; and a photoalignment layer formed by light irradiation is more preferable from the viewpoint of the uniformity of alignment, which is important for the present invention.

The polymer material used for the alignment layer formed by the rubbing treatment has been described in a large number of documents, and a large number of commercially available products can be obtained. In the present invention, a polyvinyl alcohol or polyimide and a derivative thereof are preferably used. For the alignment layer, reference can be made to the description on page 43, line 24 to page 49, line 8 of WO01/88574A1.

The thickness of the alignment layer is preferably 0.01 to 10 μm and more preferably 0.01 to 2 μm.

The photoalignment layer of the laminate according to the embodiment of the present invention is not particularly limited, and a known photoalignment layer can be used.

The material for forming the photoalignment layer is not particularly limited, and a compound having a photo-aligned group is usually used. The compound may be a polymer having a repeating unit containing a photo-aligned group.

The photo-aligned group is a functional group capable of imparting anisotropy to a film upon irradiation with light. More specifically, the photo-aligned group is a group whose molecular structure can be changed upon irradiation with light (for example, linearly polarized light). Typically, the photo-aligned group refers to a group that causes at least one photoreaction selected from a photoisomerization reaction, a photodimerization reaction, and a photodecomposition reaction upon irradiation with light (for example, linearly polarized light).

Among these photo-aligned groups, a group that causes a photoisomerization reaction (a group having a structure capable of photoisomerization) and a group that causes a photodimerization reaction (a group having a structure capable of photodimerization) are preferable, and a group that causes a photodimerization reaction is more preferable.

The photoisomerization reaction refers to a reaction that causes stereoisomerization or structural isomerization by the action of light. As a substance that causes such a photoisomerization reaction, for example, a substance having an azobenzene structure (K. Ichimura et al., Mol. Cryst. Liq. Cryst. 298, page 221 (1997)), a substance having a hydrazono-β-ketoester structure (S. Yamamura et al., Liquid Crystals, Vol. 13, No. 2, page 189 (1993)), a substance having a stilbene structure (J. G. Victor and J. M. Torkelson, Macromolecules, 20, page 2241 (1987)), and a substance having a spiropyran structure (K. Ichimura et al., Chemistry Letters, page 1063 (1992); K. Ichimura et al., Thin Solid Films, Vol. 235, page 101 (1993)) are known.

The group that causes the photoisomerization reaction is preferably a group containing a C═C bond or an N═N bond that causes a photoisomerization reaction, examples of which include a group having an azobenzene structure (skeleton), a group having a hydrazono-β-ketoester structure (skeleton), a group having a stilbene structure (skeleton), and a group having a spiropyran structure (skeleton).

The photodimerization reaction refers to a reaction in which an addition reaction occurs between two groups by the action of tight and then a ring structure is typically formed. As a substance that causes such photodimerization, for example, a substance having a cinnamic acid structure (M. Schadt et al, J. Appl. Phys., Vol. 31, No. 7, page 2155 (1992)), a substance having a coumarin structure (M. Schadt et al., Nature, Vol. 381, page 212 (1996)), a substance having a chalcone structure (Toshibiro Ogawa et al., Pre-Text of Liquid Crystal Discussion Meeting, 2AB03 (1997)), and a substance having a benzophenone structure (Y. K. Jang et al., SID Int. Symposium Digest, P-53 (1997)) are known.

Examples of the group that causes the photodimerization reaction include a group having a cinnamic acid (cinnamoyl) structure (skeleton), a group having a coumarin structure (skeleton), a group having a chalcone structure (skeleton), a benzophenone structure (skeleton), and a group having an anthracene structure (skeleton). Among these groups, a group having a cinnamoyl structure or a group having a coumarin structure is preferable, and a group having a cinnamoyl structure is more preferable.

In addition, the compound having a photo-aligned group may further have a crosslinkable group.

The crosslinkable group is preferably a thermally crosslinkable group that causes a curing reaction by the action of heat or a photocrosslinkable group that causes a curing reaction by the action of light, and may be a crosslinkable group having both a thermally crosslinkable group and a photocrosslinkable group.

The crosslinkable group may be, for example, at least one selected from the group consisting of an epoxy group, an oxetanyl group, a group represented by —NH—CH₂—O—R (where R represents a hydrogen atom or an alkyl group having 1 to 20 carbon atoms), a group having an ethylenically unsaturated double bond, and a blocked isocyanate group. Of these, an epoxy group, an oxetanyl group, or a group having an ethylenically unsaturated double bond is preferable.

A 3-membered cyclic ether group is also referred to as the epoxy group, and the 4-membered cyclic ether group is also referred to as the oxetanyl group.

In addition, examples of the group having an ethylenically unsaturated double bond include a vinyl group, an allyl group, a styryl group, an acryloyl group, and a methacryloyl group, among which an acryloyl group or a methacryloyl group is preferable.

One of the suitable aspects of the photoalignment layer may be, for example, a photoalignment layer formed by using a composition for forming a photoalignment layer containing a polymer A having a repeating unit a1 containing a cinnamate group and a low-molecular-weight compound B having a cinnamate group and having a molecular weight smaller than that of the polymer A.

Here, in the present specification, the cinnamate group is a group having a cinnamic acid structure containing cinnamic acid or a derivative thereof as a basic skeleton, and refers to a group represented by Formula (I) or Formula (II).

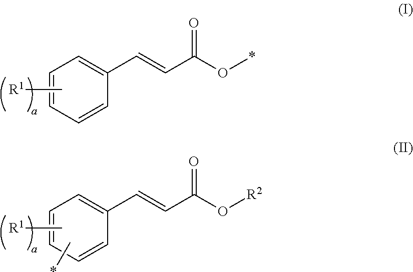

In the formulae, R¹ represents a hydrogen atom or a monovalent organic group, and R represents a monovalent organic group. In Formula (I), a represents an integer of 0 to 5, and in Formula. (II), a represents 0 to 4. In a case where a is 2 or more, a plurality of R¹'s may be the same or different from each other. * indicates that it is a bonding site.

The polymer A is not particularly limited as long as it is a polymer having the repeating unit a1 containing a cinnamate group, and a conventionally known polymer can be used.

The weight-average molecular weight of the polymer A is preferably 1,000 to 500,000, more preferably 2,000 to 300,000, and still more preferably 3,000 to 200,000.

Here, the weight-average molecular weight is defined as a value in terms of polystyrene (PS) by GPC measurement. The measurement by GPC in the present invention can be carried out using HLC-8220 GPC (manufactured by Tosoh Corporation) and using TSKgel Super HZM-H, HZ4000, and HZ2000 as columns.

Examples of the repeating unit a1 containing a cinnamate group contained in the polymer A include repeating units represented by Formulae (A1) to (A4).

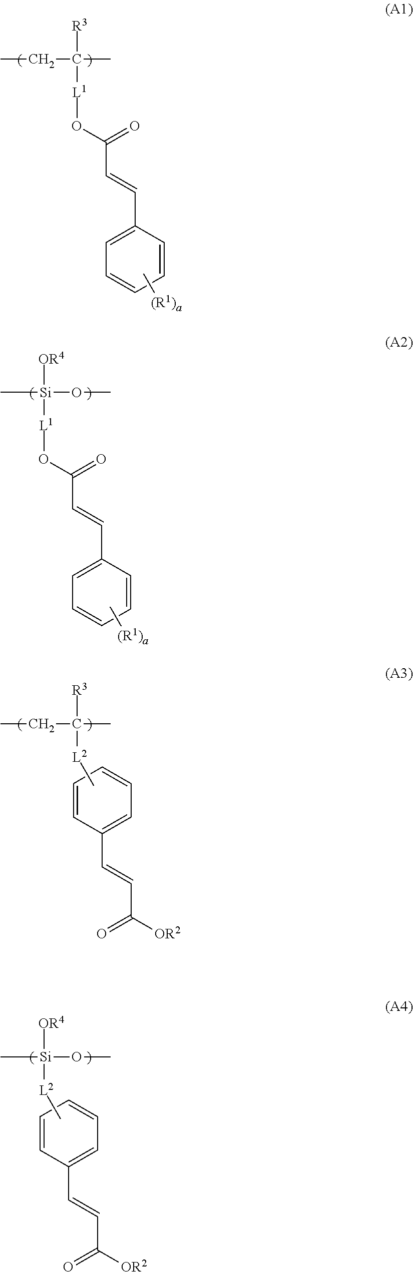

Here, in Formula (A1) and Formula (A3), R³ represents a hydrogen atom or a methyl group, and in Formula (A2) and Formula (A4), R⁴ represents an alkyl group having 1 to 6 carbon atoms.

In Formula (A1) and Formula (A2), L¹ represents a single bond or a divalent linking group, a represents an integer of 0 to 5, and R¹ represents a hydrogen atom or a monovalent organic group.

In Formula (A3) and Formula (A4), L² represents a divalent linking group and R² represents a monovalent organic group.

In addition, examples of L¹ include —CO—O-Ph-, —CO—O-Ph-Ph-, —CO—O—(CH₂)ₙ—, —CO—O—(CH₂)ₙ-Cy-, and —(CH₂)ₙ-Cy-. Here, Ph represents a divalent benzene ring (for example, a phenylene group) which may have a substituent, Cy represents a divalent cyclohexane ring (for example, cyclohexane-1,4-diyl group) which may have a substituent, and n represents an integer of 1 to 4.

In addition, examples of L² include —O—CO— and —O—CO—(CH₂)ₘ—O—. Here, m represents an integer of 1 to 6.

In addition, examples of the monovalent organic group of R¹ include a chain-like or cyclic alkyl group having 1 to 20 carbon atoms, an alkoxy group having 1 to 20 carbon atoms, and an aryl group having 6 to 20 carbon atoms which may have a substituent.

In addition, examples of the monovalent organic group of R² include a chain-like or cyclic alkyl group having 1 to 20 carbon atoms and an aryl group having 6 to 20 carbon atoms which may have a substituent.

In addition, a is preferably 1 and R¹ is preferably in a para position.

In addition, examples of the substituent that the Ph, Cy, and aryl group may have include an alkyl group, an alkoxy group, a hydroxyl group, a carboxyl group, and an amino group.

The polymer A preferably further has a repeating unit a2 containing a crosslinkable group from the viewpoint of further improving the aligning properties of the liquid crystal compound and further improving the adhesiveness to the optically anisotropic layer.

The definition and suitable aspect of the crosslinkable group are as described above.

Above all, the repeating unit a2 containing a crosslinkable group is preferably a repeating unit having an epoxy group, an oxetanyl group, or a group having an ethylenically unsaturated double bond.

Preferred specific examples of the repeating unit having an epoxy group, an oxetanyl group, or a group having an ethylenically unsaturated double bond include the following repeating units. It should be noted that R³ and R⁴ have the same definition as in R³ and R⁴ in Formula (A1) and Formula (A2), respectively.

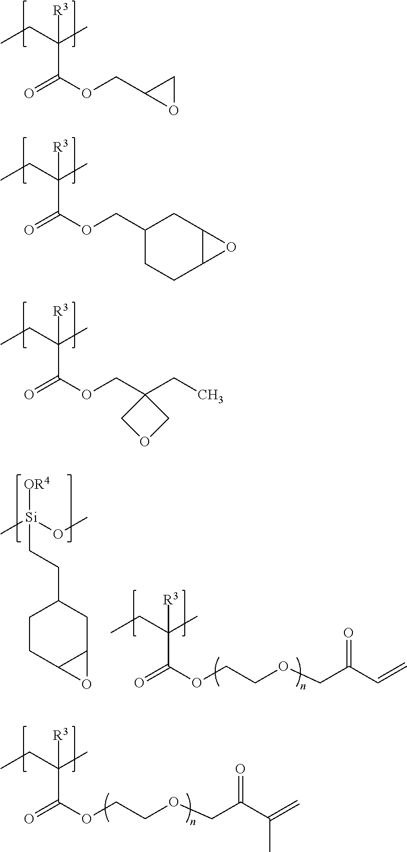

The polymer A may have a repeating unit other than the repeating unit a1 and the repeating unit a2.

Examples of the monomer forming the other repeating unit include an acrylic acid ester compound, a methacrylic acid ester compound, a maleimide compound, an acrylamide compound, an acrylonitrile, a maleic acid anhydride, a styrene compound, and a vinyl compound.

The content of the polymer A in the composition for forming a photoalignment layer is preferably 0.1 to 50 parts by mass and more preferably 0.5 to 10 parts by mass with, respect to 100 parts by mass of the solvent in a case where an organic solvent which will be described later is contained.

The low-molecular-weight compound B is a compound having a cinnamate group and having a molecular weight smaller than that of the polymer A. Using the low-molecular-weight compound B improves the aligning properties of the photoalignment layer to be prepared.

The molecular weight of the low-molecular-weight compound B is preferably 200 to 500 and more preferably 200 to 400, from the viewpoint of further improving the aligning properties of the photoalignment layer.

Examples of the low-molecular-weight compound B include a compound represented by Formula (B1).

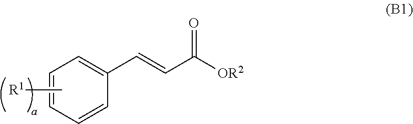

In Formula (B1), a represents an integer of 0 to 5, R¹ represents a hydrogen atom or a monovalent organic group, and R² represents a monovalent organic group. In a case where a is 2 or more, a plurality of R¹'s may be the same or different from each other.

In addition, examples of the monovalent organic group of R¹ include a chain-like or cyclic alkyl group having 1 to 20 carbon atoms, an alkoxy group having 1 to 20 carbon atoms, and an aryl group having 6 to 20 carbon atoms which may have a substituent, among winch an alkoxy group having 1 to 20 carbon atoms is preferable, an alkoxy group having 1 to 6 carbon atoms is more preferable, and a methoxy group or an ethoxy group is still more preferable.

In addition, examples of the monovalent organic group of include a chain-like or cyclic alkyl group having 1 to 20 carbon atoms and an aryl group having 6 to 20 carbon atoms which may have a substituent, among which a chain-like alkyl group having 1 to 20 carbon atoms is preferable, and a branched alkyl group having 1 to 10 carbon atoms is more preferable.

In addition, a is preferably 1 and R¹ is preferably in a para position.

In addition, examples of the substituent that the aryl group may have include an alkyl group, an alkoxy group, a hydroxyl group, a carboxyl group, and an amino group.

The content of the low-molecular-weight compound B in the composition for forming a photoalignment layer is preferably 10% to 500% by mass and more preferably 30% to 300% by mass with respect to the mass of the repeating unit a1 of the polymer A.

The composition for forming a photoalignment layer preferably contains a crosslinking agent C having a crosslinkable group in addition to the polymer A having the repeating unit a2 containing a crosslinkable group, from the viewpoint of further improving the aligning properties.

The molecular weight of the crosslinking agent C is preferably 1,000 or less and more preferably 100 to 500.

Examples of the crosslinking agent C include a compound having two or more epoxy groups or oxetanyl groups in a molecule thereof, a blocked isocyanate compound (a compound having a protected isocyanate group), and an alkoxymethyl group-containing compound.

Of these, a compound having two or more epoxy groups or oxetanyl groups in a molecule thereof, or a blocked isocyanate compound is preferable.

In a case where the composition for forming a photoalignment layer contains the crosslinking agent C, the content of the crosslinking agent C is preferably 1 to 1,000 parts by mass and more preferably 10 to 500 parts by mass with respect to 100 parts by mass of the repeating unit a1 of the polymer A.

The composition for forming a photoalignment layer preferably contains a solvent, from the viewpoint of workability for preparing the photoalignment layer. Examples of the solvent include water and an organic solvent.

Examples of the organic solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethyl formamide and dimethyl acetamide).

The solvents may be used alone or in combination of two or more thereof.

The composition for forming a photoalignment layer may contain components other than the above-mentioned components, examples of which include a crosslinking catalyst, an adhesion improver, a leveling agent, a surfactant, and a plasticizer.

(Method for Forming Photoalignment Layer)

The method for forming a photoalignment layer is not particularly limited. For example, the photoalignment layer can be produced by a production method including a coating step of coating the above-mentioned composition for forming a photoalignment layer on a surface of a support and a light irradiation step of irradiating the coating film of the composition for forming a photoalignment layer with polarized light or with, non-polarized light from an oblique direction with respect to the surface of the coating film.

Examples of the support include a glass substrate and a polymer film.

Examples of the polymer film material include cellulose-based polymers: acrylic polymers; thermoplastic norbornene-based polymers; polycarbonate-based polymers, polyester-based polymers such as polyethylene terephthalate and polyethylene napthalate, styrene-based polymers such as polystyrene and acrylonitrile-styrene copolymer, polyolefin-based polymers such as polyethylene, polypropylene, and ethylene-propylene copolymer; vinyl chloride-based polymers; amide-based polymers such as nylon and aromatic polyamide; imide-based polymers; sulfone-based polymers; polyether sultone-based polymers, polyether ether ketone-based polymers; polyphenylene sulfide-based polymers; vinylidene chloride-based polymers; vinyl alcohol-based polymers: vinyl butyral-based polymers, allylate-based polymers; polyoxymethylene-based polymers; epoxy-based polymers; and polymers in which these polymers are mixed.

The thickness of the support is not particularly limited, and is preferably 5 to 60 μm and more preferably 5 to 30 μm.

<Polarizer Layer>

The laminate preferably has a polarizer layer (light absorption anisotropic layer). The polarizer layer is a so-called linear polarizer having a function of converting light into specific linearly polarized light.

The polarizer layer generally includes, but is not limited to, a polyvinyl alcohol-based resin and a dichroic substance.

The polyvinyl alcohol-based resin is a resin containing a repeating unit of —CH₂—CHOH—, and examples thereof include a polyvinyl alcohol and an ethylene-vinyl alcohol copolymer.

The polyvinyl alcohol-based resin can be obtained, for example, by saponifying a polyvinyl acetate-based resin. Examples of the polyvinyl acetate-based resin include polyvinyl acetate, which is a homopolymer of vinyl acetate, and a copolymer of vinyl acetate and another monomer copolymerizable therewith.

Examples of the other monomer copolymerizable with vinyl acetate include unsaturated carboxylic acids, olefins, vinyl ethers, unsaturated sulfonic acids, and acrylamides having an ammonium group.

The saponification degree of the polyvinyl alcohol-based resin is not particularly limited, and is preferably 85 to 100 mol % and more preferably 95.0 to 99.95 mol %. The saponification degree can be determined according to JIS K 6726-1994.

The average degree of polymerization of the polyvinyl alcohol-based resin is not particularly limited, and is preferably 100 to 10,000 and more preferably 1,500 to 8,000. The average degree of polymerization can be determined according to JIS K. 6726-1994 in the same manner as the saponification degree.

The content of the polyvinyl alcohol-based resin in the polarizer layer is not particularly limited, and it is preferable that the polyvinyl alcohol-based resin is contained as the main component in the polarizer layer. The main component means that the content of the polyvinyl alcohol-based resin is 50% by mass or more with respect to the total mass of the polarizer layer. The content of the polyvinyl alcohol-based resin is preferably 90% by mass or more with respect to the total mass of the polarizer layer. The upper limit of the content of the polyvinyl alcohol-based resin is not particularly limited, and is often 99.9% by mass or less.

The polarizer layer preferably further contains a dichroic substance. The dichroic substance is preferably iodine, and an organic dye (dichroic coloring agent) can also be used. That is, it is preferable that the polarizer contains a polyvinyl alcohol-based resin as a main component and iodine as a dichroic substance.

The method for producing the polarizer layer is not particularly limited, and a known method can be mentioned. For example, there is a method of adsorbing a dichroic substance on a substrate containing a polyvinyl alcohol-based resin and stretching the thus-treated substrate.

The thickness of the polarizer layer is not particularly limited, and is often. 20 μm or less and more often 15 μm or less. The lower limit of the thickness of the polarizer layer is not particularly limited, and is often 2 μm or more and more often 3 μm or more. For example, the thickness of the polarizer layer is preferably 2 to 15 μm.

It is also a preferred aspect that the polarizer layer of the laminate according to the embodiment of the present invention contains a dichroic coloring agent.

The dichroic coloring agent is not particularly limited, and a conventionally known dichroic coloring agent can be used.

Examples of the dichroic coloring agent include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] to [0065] of JP2013-037353A, paragraphs [0049] to [0073] of JP2012-063387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0022] to [0080] of JP2015-001425, paragraphs [0005] to [0051] of JP2016-006502, paragraphs [0005] to [0041] of WO2016/060173A, paragraphs [0008] to [0062] of WO 2016/136561 A, paragraphs [0014] to [0033] of JP2016-044909, paragraphs [0014] to [0033] of JP2016-044910, paragraphs [0013] to [0037] of JP2016-095907, and paragraphs [0014] to [0034] of JP2017-045296.

In the present invention, two or more dichroic coloring agents may be used in combination. For example, it is preferable to use at least one dichroic coloring agent having a maximal absorption wavelength in a wavelength range of 370 to 550 nm and at least one dichroic coloring agent having a maximal absorption wavelength in a wavelength range of 500 to 700 run in combination.

The dichroic coloring agent preferably has a crosslinkable group.

Examples of the crosslinkable group include an acryloyl group, a methacryloyl group, an epoxy group, an oxetanyl group, and a styryl group, among which an acryloyl group or a methacryloyl group is preferable.

In a case where the polarizer layer contains a dichroic coloring agent, the content of the dichroic coloring agent is preferably 2% to 40% by mass and more preferably 5% to 30/o by mass with respect to the total mass (solid content) of the polarizer layer.

Since the dichroic coloring agent is an organic compound and therefore may be decomposed by light, a layer configuration in which a specific compound is present on the outside light side of the layer in which the dichroic coloring agent is present is preferable.

Since the light resistance of the dichroic coloring agent is inferior particularly in a case where the content of the dichroic coloring agent with respect to the solid content is 10% by mass or less, it is more preferable that a sufficient amount of a specific compound is present on the outside light side of the layer in which the dichroic coloring agent is present.

The polarizer layer is preferably a layer formed by a coating method, and is specifically more preferably a layer formed by coating a composition containing a dichroic coloring agent and the like (hereinafter, also referred to simply as “composition for forming a light absorption anisotropic layer”).

In addition, as another name for the polarizer layer formed by coating, it is also referred to as a light absorption anisotropic layer below.

The composition for forming a light absorption anisotropic layer preferably contains a liquid crystal compound, from the viewpoint of aligning the dichroic coloring agent. The liquid crystal compound is a liquid crystal compound that does not exhibit dichroism.

The liquid crystal compound preferably exhibits a smectic alignment from the viewpoint of improving the alignment degree of the light absorption anisotropic layer.

Both a low molecular weight liquid crystal compound and a high molecular weight liquid crystal compound can be used as the liquid crystal compound. Here, the “low molecular weight liquid crystal compound” refers to a liquid crystal compound having no repeating unit in a chemical structure thereof. In addition, the “high molecular weight liquid crystal compound” refers to a liquid crystal compound having a repeating unit in a chemical structure thereof.

Examples of the low molecular weight liquid crystal compound include liquid crystal compounds described in JP2013-228706A.

Examples of the high molecular weight liquid crystal compound include thermotropic liquid crystalline polymers described in JP2011-237513A. In addition, the high molecular weight liquid crystal compound may have a crosslinkable group (for example, an aery lord group and a methacryloyl group) at a terminal thereof.

The liquid crystal compounds may be used alone or in combination of two or more thereof.

The content of the liquid crystal compound is preferably 25 to 2,000 parts by mass, more preferably 33 to 1,000 parts by mass, and still more preferably 50 to 500 parts by mass with respect to 100 parts by mass of the content of the dichroic coloring agent in the composition for forming a light absorption anisotropic layer.

The composition for forming a light absorption anisotropic layer may contain a polymerization initiator, a solvent, and the like.

Specific examples of these components include those described in the above-mentioned liquid crystal composition.

Examples of the coating method of the composition for forming a light absorption anisotropic layer include known methods such as a roll coating method, a gravure printing method, a spin coating method, a wire bar coating method, an extrusion coating method, a direct gravure coating method, a reverse gravure coating method, a die-coating method, a spray method, and an inkjet method.

In a case where the composition for forming a light absorption anisotropic layer contains the above-mentioned dichroic coloring agent and liquid crystal compound, the composition may be subjected to an alignment treatment for aligning these components after coating.

The alignment treatment may have a drying step. Components such as a solvent can be removed from the coating film by the drying step. The drying step may be carried out by a method of allowing the coating film to stand at room temperature for a predetermined time (for example, natural drying), or by a method of heating and/or blowing air on the coating film.

In addition, the alignment treatment preferably has a heating step. As a result, the dichroic coloring agent contained in the coating film is more aligned, and therefore the alignment degree of the obtained light absorption anisotropic layer becomes higher. The heating step is preferably carried out at 10° C. to 250° C. and more preferably 25° C. to 190° C. from the viewpoint of manufacturing suitability and the like. In addition, the heating time is preferably 1 to 300 seconds and more preferably 1 to 60 seconds.

In addition, the alignment treatment may have a cooling step which is carried out after the heating step. The cooling step is a treatment oi cooling the heated coating film to about room temperature (20° C. to 25° C.) As a result, the alignment of the dichroic coloring agent contained in the coating film is more fixed, and therefore the alignment degree of the obtained light absorption anisotropic layer becomes higher. The cooling means is not particularly limited and the cooling can be earned out by a known method.

In the present invention, the thickness of the light absorption anisotropic layer is not particularly limited, and is preferably 0.1 to 5.0 μm and more preferably 0.3 to 1.5 μm.

<Adhesive Layer>

The laminate according to the embodiment of the present invention may have an adhesive layer.

The adhesive, contained in the adhesive layer exhibits adhesiveness by drying oi reaction after bonding.

The adhesive is preferably a polyvinyl alcohol-based adhesive (PVA-based adhesive). The PYA-based adhesive develops adhesiveness by drying, and makes it possible to bond materials together.

Specific examples of the curable adhesive that develops adhesiveness by reaction include an active energy ray-curable adhesive such as a (meth)acrylate-based adhesive and a cationic polymerization curable adhesive. The (meth)acrylate means acrylate and/oi methacrylate. Examples of the curable component in the (meth)acrylate-based adhesive include a compound having a (meth)acryloyl group and a compound having a vinyl group.

In addition, examples of the cationic polymerization curable adhesive include compounds having an epoxy group or an oxetanyl group. The compound having an epoxy group is not particularly limited as long as it is a compound having at least two epoxy groups in a molecule thereof, and various generally known curable epoxy compounds can be used. Examples of a preferred epoxy compound include a compound having at least two epoxy groups and at least one aromatic ring in a molecule thereof (aromatic epoxy compound), and a compound that has at least two epoxy groups in a molecule thereof, at least one of which is formed between two adjacent carbon atoms constituting an alicyclic ring (alicylic epoxy compound).

<Pressure Sensitive Adhesive Layer>

The laminate according to the embodiment of the present invention may have a pressure sensitive adhesive layer containing no specific compound used in the present invention, from the viewpoint of bonding the above-mentioned optically anisotropic layer, polarizer layer, and other functional layers.

Examples of the pressure sensitive adhesive contained in the pressure sensitive adhesive layer include a rubber-based pressure sensitive adhesive, a (meth)acrylic pressure sensitive adhesive, a silicone-based pressure sensitive adhesive, an urethane-based pressure sensitive adhesive, a vinyl alkyl ether-based pressure sensitive adhesive, a polyvinyl alcohol-based pressure sensitive adhesive, a polyvinyl pyrrolidone-based pressure sensitive adhesive, a polyacrylamide-based pressure sensitive adhesive, and a cellulose-based pressure sensitive adhesive.

Of these, a (meth)acrylic pressure sensitive adhesive is preferable from the viewpoint of transparency, weather fastness, heat resistance, and the like.

The pressure sensitive adhesive layer can be formed by, for example, a method in which a solution of a pressure sensitive adhesive is coated and dried on a release sheet, and then transferred to a surface of a transparent resin layer; or a method in which a solution of a pressure sensitive adhesive is directly coated and dried on a surface of a transparent resin layer.

The solution of a pressure sensitive adhesive is prepared as a solution of about 10% to 40% by mass of the pressure sensitive adhesive in which the pressure sensitive adhesive is dissolved or dispersed in a solvent such as toluene or ethyl acetate.

Examples of the coating method include a roll coating method such as reverse coating or gravure coating, a spin coating method, a screen coating method, a fountain coating method, a dipping method, and a spray method.

In addition, examples of the release sheet include appropriate thin sheet bodies, for example, synthetic resin films such as polyethylene, polypropylene, and polyethylene terephthalate; rubber sheets; paper; cloth: nonwoven fabrics; networks, foamed sheets, and metal foils.

The thickness of the optional pressure sensitive adhesive layer is not particularly limited, and is preferably 3 to 50 μm, more preferably 4 to 40 μm, and still more preferably 5 to 30 μm.

The laminate according to the embodiment of the present invention may have a surface protective layer, in addition to the above-mentioned components.

The surface protective layer is a layer arranged on the outermost surface side or the laminate.

The configuration of the surface protective layer is not particularly limited, and may be, for example, a so-called transparent support or hard coat layer, or a laminate of the transparent support and the hard coat layer.

<Use>

In a case where the laminate according to the embodiment of the present invention has a polarizer layer, the laminate can be used as a polarizing element (polarizing plate), and can be used, for example, as a circularly polarizing plate having an antireflection function.

(Image Display Apparatus)

The image display apparatus according to the embodiment of the present invention has the above-mentioned laminate according to the embodiment of the present invention.

The display element used in the image display apparatus according to the embodiment of the present invention is not particularly limited, and examples thereof include a liquid crystal cell, an organic EL display panel, and a plasma display panel.

Of these, a liquid crystal cell or an organic EL display panel is preferable, and a liquid crystal cell is more preferable. That is, the image display apparatus according to the embodiment of the present invention is preferably a liquid crystal display device using a liquid crystal cell as the display element or an organic EL display device using an organic EL display panel as the display element, and more preferably a liquid crystal display device.

(Liquid Crystal Display Device)

The liquid crystal display device which is an example of the image display apparatus according to the embodiment of the present invention is a liquid crystal display device having the above-mentioned laminate according to the embodiment of the present invention and a liquid crystal cell.

In the present invention, with regard to the laminates provided on both sides of the liquid crystal cell, it is preferable that, the laminate according to the embodiment of the present invention is used as a front-side polarizing element and it is more preferable that the laminate according to the embodiment of the present invention is used as a front-side polarizing element and a rear-side polarizing element.

Hereinafter, the liquid crystal cell constituting the liquid crystal display device will be described in detail.

The liquid crystal cell used for the liquid crystal display device is preferably in a vertical alignment (VA) mode, an optically compensated bend (OCB) mode, an in-plane-switching (IPS) mode, or a twisted nematic (TN) mode, but the present, invention is not limited thereto.

In a TN mode liquid crystal cell, rod-like liquid crystalline molecules (rod-like liquid crystal compound) are substantially horizontally aligned in a case where no voltage is applies and are further twist-aligned at 60° to 120°. The TN mode liquid crystal cell is most often used as a color TFT liquid crystal display device and has been described in many documents.

In a VA mode liquid crystal cell, rod-like liquid crystalline molecules are substantially vertically aligned in a case where no voltage is applied. The concept of the VA mode liquid crystal cell includes (1) a narrowly-defined VA mode liquid crystal cell in which rod-like liquid crystalline molecules are substantially vertically aligned in a case where no voltage is applied and are substantially horizontally aligned in a case where a voltage is applied (described in JP1990-176625A (JP-H02-176625A)), (2) a multi-domain vertical alignment (MVA) mode liquid crystal cell in which the VA mode is made into multi-domains in order to expand a viewing angle (SID97, described in Digest of Tech. Papers (proceedings) 28 (1997) 845), (3) an axially symmetric aligned microcell (n-ASM) mode liquid crystal cell in which rod-like liquid crystalline molecules are substantially vertically aligned in a case where no voltage is applied and are twist-aligned in multi-domains in a case where a voltage is applied (described in proceedings of Japanese Liquid Crystal Conference, pp, 58 to 59 (1998)), and (4) a SURVIVAL mode liquid crystal cell (presented at Liquid Crystal Display (LCD) International 98). In addition, the liquid crystal cell may be any of a patterned vertical alignment (PVA) type, a photoalignment (optical alignment) type, and a polymer-sustained alignment (PSA) type. The details of these modes are described, in JP2006-215326A and JP2008-538819A.

In an IPS mode liquid crystal cell, rod-like liquid crystalline molecules are aligned substantially parallel with respect to a substrate, and the liquid crystalline molecules respond in a planar manner in a case where a voltage parallel to the substrate surface is applied. The IPS mode displays black in a case where no voltage is applied, and absorption axes of a pair of upper and lower polarizing plates are orthogonal to each other. A method of reducing leakage light during black display in an oblique direction to improve a viewing angle using an optical compensation sheet is disclosed in JP1998-054982A (JP-H10-054982A), JP1999-202323A (JP-H11-202323A), JP1997-292522A (JP-H09-292522A), JP1999-133408A (JP-H11-133408A), JP1999-305217A (JP-H11-305217A), and JP1998-307291A (JP-H10-307291 A).

(Organic EL Display Device)

The organic EL display device which is an example of the image display apparatus according to the embodiment of the present invention is suitably an aspect of a display device having the above-mentioned laminate according to the embodiment of the present Invention (including a pressure sensitive adhesive sheet and a λ/4 plate) and an organic EL display panel in this order from the visual recognition side. In this case, a pressure sensitive adhesive sheet provided as needed, a barrier layer provided as needed, a cured layer provided as needed, a polarizer layer, a pressure sensitive adhesive sheet, and a λ/4 plate (optically anisotropic layer) are arranged in this order in the laminate from the visual recognition side.

In addition, the organic EL display panel is a display panel configured oy using an organic EL display element in which an organic light emitting layer (organic EL layer) is interposed between electrodes (between a cathode and an anode). The configuration of the organic EL display panel is not particularly limited, and a known configuration is adopted.

### EXAMPLES

Hereinafter, the present invention will be specifically described with reference to Examples. The materials, reagents, substance amounts and ratios thereof, operations, and the like shown in the following examples can be appropriately changed without departing from the spirit, of the present invention. Therefore, the present invention is not limited to the following examples.

### Polymerization Example 1

A mixed solution of ethyl acetate (81.8 parts by mass) as a solvent, butyl acrylate (70.4 parts by mass), methyl acrylate (20.0 parts by mass), and 2-phenoxyethyl acrylate (8.0 parts by mass) as a monomer (A-1), and 2-hydroxyethyl acrylate (1.0 parts by mass) and acrylic acid (0.6 parts by mass) as a monomer (A-2) was charged in a reaction container equipped with a cooling pipe, a nitrogen introduction pipe, a thermometer, and a stirrer, and the internal temperature of the reaction container was raised to 55° C. while substituting the air in the reaction container with nitrogen gas to make it oxygen-free. Then, a total solution of 2,2′-azobisisobutyronitrile (polymerization initiator, 0.14 parts by mass) dissolved in ethyl acetate (10 parts by mass) was added to the mixed solution. After the addition of the polymerization initiator, the temperature was maintained at this temperature for 1 hour, and then ethyl acetate was continuously added into the reaction container at an addition rate of 17.3 parts by mass/hr while maintaining the internal temperature at 54° C. to 56° C. In a case where the concentration of the produced acrylic resin reached 35% by mass, the addition of ethyl acetate was stopped, and the temperature was maintained at this temperature until 12 hours had passed from the start of the addition of ethyl acetate. Finally, ethyl acetate was added to adjust, the concentration of the acrylic resin to 20% by mass to prepare an ethyl acetate solution of the acrylic resin.

The obtained acrylic resin had a weight-average molecular weight Mw of 1,420,000 in terms of polystyrene and Mw/Mn of 5.2, as measured by GPC. The obtained acrylic resin is referred to as acrylic resin A.

### Polymerization Example 2

A mixed solution of ethyl acetate (8 LB parts by mass) as a solvent, butyl acrylate (96.0 parts by mass) as a monomer (A-1), and acrylic acid (4.0 parts by mass) as a monomer (A-2) was charged in a reaction container equipped with a cooling pipe, a nitrogen introduction pipe, a thermometer, and a stirrer, and the internal temperature of the reaction, container was raised to 55° C. while substituting the air in the reaction container with nitrogen gas to make it oxygen-free. Then, a total solution of 2,2-azobisisobutyronitrile (polymerization initiator, 0.14 parts by mass) dissolved in ethyl acetate (10 parts by mass) was added to the mixed solution. After the addition of the polymerization initiator, the temperature was maintained at this temperature for 1 hour, and then ethyl acetate was continuously added into the reaction container at an addition rate of 17.3 parts by mass/hr while maintaining the internal temperature at 54° C. to 56° C. In a case where the concentration of the produced acrylic resin reached 35% by mass, the addition of ethyl acetate was stopped, and the temperature was maintained at this temperature until 12 hours had passed from the start of the addition of ethyl acetate, finally, ethyl acetate was added to adjust the concentration of the acrylic resin to 20% by mass to prepare an ethyl acetate solution of the acrylic resin.

The obtained acrylic resin had a weight-average molecular weight Mw of 756,000 in terms of polystyrene and Mw/Mn of 4.1, as measured by GPC. The obtained acrylic resin is referred to as acrylic resin B.

### Polymerization Example 3

A mixed solution of ethyl acetate (81.8 parts by mass) as a solvent, 2-ethylhexyl acrylate (69.0 parts by mass) and 2-methoxyethyl acrylate (29.0 parts by mass) as a monomer (A-1), and 2-hydroxybutyl acrylate (1.0 parts by mass) and acrylic acid (1.0 parts by mass) as a monomer (A-2) was charged in a reaction container equipped with a cooling pipe, a nitrogen introduction pipe, a thermometer, and a stirrer, and an ethyl acetate solution of acrylic resin was prepared in the same manner as in Polymerization Example 1.

The obtained acrylic resin had a weight-average molecular weight Mw of 2,000,000 in terms of polystyrene and Mw/Mn of 5.8, as measured by GPC. The obtained acrylic resin is referred to as acrylic resin C.

### Polymerization Example 4

A mixed solution of ethyl acetate (81.8 parts by mass) as a solvent, lauryl acrylate (96.0 parts by mass) as a monomer (A-1) and acrylic acid (4.0 parts by mass) as a monomer (A-2) was charged in a reaction container equipped with a cooling pipe, a nitrogen introduction pipe, a thermometer, and a stirrer, and an ethyl acetate solution of acrylic resin was prepared in the same manner as in Polymerization Example 1.

The obtained acrylic resin had a weight-average molecular weight Mw of 850,000 in terms of polystyrene and Mw/Mn of 4.3, as measured by GPC. The obtained acrylic resin is referred to as acrylic resin D.

<Preparation of Pressure Sensitive Adhesive Sheets 1 to 15>

As shown in Table 1 below, an acrylic resin (“A” represents an acrylic resin A, B represents an acrylic resin B, “C” represents an acrylic resin C, and “D” represents an acrylic resin D), a crosslinking agent, a silane-based compound, and a specific compound were mixed to prepare compositions 1 to 15 for forming a pressure sensitive adhesive sheet, respectively. The number of parts to be added of each component is shown in Table 1 as the number of parts by mass with respect to 100 parts by mass of the solid content in the acrylic resin prepared in each of Polymerization Examples 1 to 4. Here, 2-butanone was added to the components shown in Table 1 such that the concentration of solid contents of each of compositions 1 to 15 for forming a pressure sensitive adhesive sheet was 14% by mass. Then, the obtained mixture was stirred and mixed using a stirrer (THREE-ONE MOTOR BL-300, manufactured by Yamato Scientific Co., Ltd.) at 300 rpm for 30 minutes to prepare compositions 1 to 15 for forming a pressure sensitive adhesive sheet.

The various components used are shown below.

Specific compounds UV-1 to UV-6 (Note that the wavelength in each of the following structural formulae represents the maximal absorption wavelength of the specific compound).

In addition, the Hammett's substituent constant op value of the group corresponding to EWG₁ of the specific compound UV-1 was 0.68, and the Hammett's substituent constant op value of the group corresponding to EWG₂ was 0.45.

In addition, the Hammett's substituent constant op value of the group corresponding to EWG₁ of the specific compound UV-2 was 0.68, and the Hammett's substituent constant op value of the group corresponding to EWG₂ was 0.45.

In addition, the Hammett's substituent constant op value of the group corresponding to EWG₁ of the specific compound UV-3 was 0.62, and the Hammett's substituent constant op value of the group corresponding to EWG₂ was 0.44.

In addition, the Hammett's substituent constant op value of the group corresponding to EWG₁ of the specific compound UV-4 was 0.66, and the Hammett's substituent constant op value of the group corresponding to EWG₂ was 0.45.

In addition, the Hammett's substituent constant op value of the group corresponding to EWG₁ of the specific compound UV-5 was 0.45, and the Hammett's substituent constant op value of the group corresponding to EWG₂ was 0.45.

In addition, the Hammett's substituent constant op value of the group corresponding to EWG₁ of the specific compound UV-6 was 0.43, and the Hammett's substituent constant op value of the group corresponding to EWG₂ was 0.45.

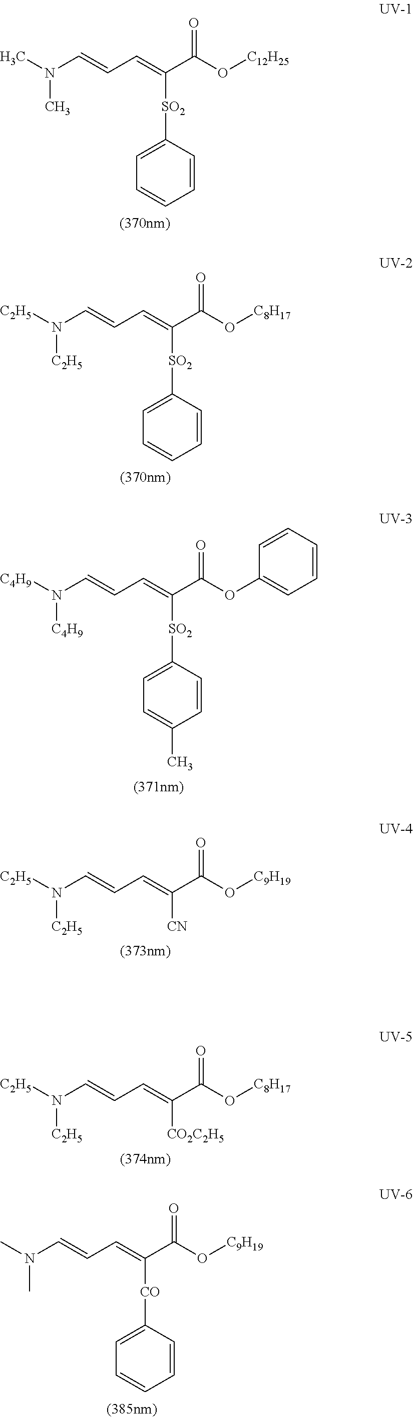

(Crosslinking Agent)

CORONATE L: an ethyl acetate solution of a trimethylolpropane adduct of tolylene diisocyanate (concentration of solid contents: 75% by mass), manufactured by Nippon Polyurethane Industry Co., Ltd.

(Silane-Based Compound)

KBM-403: 3-glycidoxypropyltrimethoxysilane, manufactured by Shin-Etsu Chemical Co., Ltd.

Each of compositions 1 to 15 for forming a pressure sensitive adhesive sheet prepared above was coated on a release-treated surface of a polyethylene terephthalate film (SP-PLR382050, manufactured by Lintec Corporation, hereinafter referred to simply as a separator) that has been subjected to a release treatment using an applicator such that the thickness of the pressure sensitive adhesive sheet after drying was 15 μm. This was followed by drying at 100° C. for 1 minute to prepare pressure sensitive adhesive sheets 1 to 15.

(Evaluation of Light Resistance)

The light resistance of the pressure sensitive adhesive sheets 1 to 15 was evaluated under the following light resistance evaluation conditions.

Testing machine: low temperature cycle xenon weather meter (XL75, manufactured by Suga Test Instruments Co., Ltd.)

Irradiation conditions: 100 lux (40 W/m²)

Temperature and humidity: 23° C., 50% RH

Irradiation time: 20 h

The absorbance retention rate of the pressure sensitive adhesive sheet at a wavelength of 380 nm before and after the light resistance evaluation {(absorbance after light resistance evaluation/absorbance before light resistance evaluation)×100} was calculated and evaluated according to the following standards. The evaluation results are shown in Table 1.

AA: The absorbance retention rate is 90% or more

A: The absorbance retention rate is 85% or more and less than 90%

B: The absorbance retention rate is 80% or more and less than 85%

C: The absorbance retention rate is less than 80%

In Table 1, the column of “log P” represents a log P value of each compound.

The column of “Δ log P” represents an absolute value of the difference between the log P of the (meth)acrylic resin and the log P of the specific compound.

TABLE 1

| | | | | Crosslinking | Silane | | | | | Light | |
|---|---|---|---|---|---|---|---|---|---|---|---|
| Pressure-sensitive | (Meth)acrylic resin | | | agent | compound | Specific compound | | | | resistance | |
| adhesive sheet | Type | logP | Amount | Amount | Amount | Type | logP | Amount | ΔlogP | evaluation | Remarks |
| 1 | A | 1.87 | 100 | 1 | 0.2 | UV-1 | 7.66 | 2.5 | 5.79 | AA | Inventive |
| 2 | C | 2.87 | 100 | 1 | 0.2 | UV-1 | 7.66 | 2.5 | 4.79 | AA | Inventive |
| 3 | A | 1.87 | 100 | 1 | 0.2 | UV-2 | 6.69 | 2.5 | 4.82 | AA | Inventive |
| 4 | B | 2.15 | 100 | 1 | 0.2 | UV-2 | 6.69 | 2.5 | 4.54 | AA | Inventive |
| 5 | C | 2.87 | 100 | 1 | 0.2 | UV-2 | 6.69 | 2.5 | 3.82 | A | Inventive |
| 6 | D | 5.95 | 100 | 1 | 0.2 | UV-2 | 6.69 | 2.5 | 0.74 | C | Comparative |
| 7 | A | 1.87 | 100 | 1 | 0.2 | UV-3 | 7.20 | 2.5 | 5.33 | AA | Inventive |
| 8 | B | 2.15 | 100 | 1 | 0.2 | UV-3 | 7.20 | 2.5 | 5.05 | AA | Inventive |
| 9 | D | 5.95 | 100 | 1 | 0.2 | UV-3 | 7.20 | 2.5 | 1.25 | C | Comparative |
| 10 | A | 1.87 | 100 | 1 | 0.2 | UV-4 | 5.45 | 2.5 | 3.58 | A | Inventive |
| 11 | A | 1.87 | 100 | 1 | 0.2 | UV-5 | 5.92 | 2.5 | 4.05 | A | Inventive |
| 12 | C | 2.87 | 100 | 1 | 0.2 | UV-5 | 5.92 | 2.5 | 3.05 | B | Inventive |
| 13 | D | 5.95 | 100 | 1 | 0.2 | UV-5 | 5.92 | 2.5 | 0.03 | C | Comparative |
| 14 | A | 1.87 | 100 | 1 | 0.2 | UV-6 | 6.26 | 2.5 | 4.39 | A | Inventive |
| 15 | D | 5.95 | 100 | 1 | 0.2 | UV-6 | 6.26 | 2.5 | 0.31 | C | Comparative |

As shown in the above table, the pressure sensitive adhesive sheet according to the embodiment of the present invention showed excellent light resistance.

In particular, it was confirmed that the effect was more excellent in a case where the absolute value of the difference between the log P value of the (meth)acrylic resin and the log P value, of the specific compound was 3.50 or more (preferably 4.50 or more).

### Preparation Examples 16 to 22

The pressure sensitive adhesive composition was adjusted as shown in Table 2 to prepare pressure sensitive adhesive sheets 16 to 22 in the same manner as m Preparation Example 1, except that the composition was coated such that the thickness of the pressure sensitive adhesive sheet after drying was 5 μm.

The pressure sensitive adhesive sheets 16 to 22 were subjected to a heat shock resistance test that repeats a process of heating to 70° C., lowering to −40° C., and then, raising to 70° C. as one cycle (30 minutes) for a total of 100 cycles (Hereinafter, referred to simply as “HS resistance”). The pressure sensitive adhesive sheets after the test were visually observed, and the presence or absence of crystal precipitation in the sheet was evaluated according to the following standards. The evaluation results are shown in Table 2.

(Evaluation Standards for Crystal Precipitation)

A: Almost no change in appearance such as turbidity due to crystal precipitation is observed.

B: Changes in appearance such as turbidity due to crystal precipitation are observed.

TABLE 2

| | | | Crosslinking | Silane | | | Crystal |
|---|---|---|---|---|---|---|---|
| Pressure-sensitive | (Meth)acrylic resin | | agent | compound | Specific compound | | precipitation |
| adhesive sheet | Type | Amount | Amount | Amount | Type | Amount | evaluation |
| 16 | A | 100 | 1 | 0.2 | UV-1 | 5.6 | A |
| 17 | B | 100 | 1 | 0.2 | UV-1 | 5.6 | A |
| 18 | A | 100 | 1 | 0.2 | UV-2 | 5.6 | A |
| 19 | B | 100 | 1 | 0.2 | UV-2 | 5.6 | A |
| 20 | C | 100 | 1 | 0.2 | UV-2 | 5.6 | A |
| 21 | B | 100 | 1 | 0.2 | UV-3 | 5.6 | A |
| 22 | B | 100 | 1 | 0.2 | UV-4 | 2.8 | A |
| 23 | B | 100 | 1 | 0.2 | UV-4 | 5.6 | B |
| 24 | B | 100 | 1 | 0.2 | — | None | A |

Specific compounds of UV-1 to UV-3 of the present invention (EWG₁ represents SO₂R⁷, EWG₂ represents COOR⁶, R⁶ and R⁷ each independently represent an alkyl group, an aryl group, or a heteroaryl group) did not cause crystal precipitation even in a case where the compound was used in an amount of 5.5 parts by mass or more with respect to 100 parts by mass of the acrylic resin.

### Preparation Examples 25 to 38

(Preparation of Optically Anisotropic Film 1)

The following composition was put into a mixing tank and stirred to prepare a cellulose acetate solution to be used as a core layer cellulose acylate dope.

Core layer cellulose acylate dope

| | |
|---|---|
| Cellulose acetate having an acetyl | 100 parts by mass |
| substitution degree of 2.88 | |
| Polyester compound B described | 12 parts by mass |
| in Examples of JP2015-227955A | |
| Compound G shown below | 2 parts by mass |
| Methylene chloride (first solvent) | 430 parts by mass |
| Methanol (second solvent) | 64 parts by mass |

Compound G

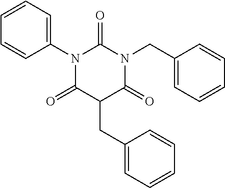 [SMILES: O=C1C(Cc2ccccc2)C(=O)N(c2ccccc2)C(=O)N1Cc1ccccc1]

10 parts by mass of the following matte agent solution were added to 90 parts by mass of the core layer cellulose acylate dope to prepare a cellulose acetate solution to be used as an outer layer cellulose acylate dope.

Matte agent solution

| | | |
|---|---|---|
| Silica particles having an average | 2 | parts by mass |
| particle size of 20 nm | | |
| (AEROSIL R972, manufactured by | | |
| Nippon Aerosil Co., Ltd.) | | |
| Methylene chloride (first solvent) | 76 | parts by mass |
| Methanol (second solvent) | 11 | parts by mass |
| Core layer cellulose acylate dope | 1 | part by mass |
| described above | | |

After filtering the core layer cellulose acylate dope and the outer layer cellulose acylate dope through a filter paper having an average pore size of 34 μm and a sintered metal filter having an average pore size of 10 μm, the core layer cellulose acylate dope and the outer layer cellulose acylate dope on both sides thereof were simultaneously cast in three layers on a drum at 20° C. from a casting port (band casting machine). The film was peeled oft from the drum with a solvent content of about 20% by mass, both ends of the film in a width direction were fixed with tenter clips, and the film was dried while being stretched in a transverse direction at a stretching ratio of 1.1 times. Then, the obtained film was transported between rolls of a heat treatment apparatus to be further dried to prepare a transparent resin film 1 having a thickness of 40 μm. The Re (550) of the obtained transparent resin film 1 was 0 nm.

A coating liquid 1 for forming an alignment layer, which will be described later, was continuously coated on the transparent resin film 1 with a wire bar of #2.4. The support on which the coating film was formed was dried with hot air at 140° C. for 120 seconds, and then the coating film was irradiated with polarized ultraviolet rays (10 mJ/cm², using an ultra-high pressure mercury lamp) to form a photoalignment layer 1, thereby obtaining a TAC film with the photoalignment layer 1.

Coating liquid 1 for forming an alignment layer

| | |
|---|---|
| Polymer PA-1 shown below | 100.00 parts by mass |
| Acid generator PAG-1 shown below | 1.00 parts by mass |
| Isopropyl alcohol | 16.50 parts by mass |
| Butyl acetate | 1072.00 parts by mass |
| Methyl ethyl ketone | 268.00 parts by mass |

Polymer PA-1 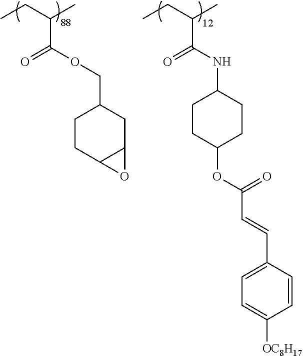
Acid generator PAG-1

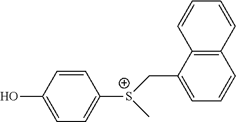 [SMILES: C[S+](Cc1cccc2ccccc12)c1ccc(O)cc1]

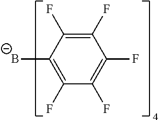

Subsequently, the following coating liquid A-1 for forming a positive A-plate was prepared.

Coating liquid A-1 for forming a positive A-plate

| | |
|---|---|
| Liquid crystal compound L-1 shown below | 70.00 parts by mass |
| Liquid crystal compound L-2 shown below | 30.00 parts by mass |
| Polymerization intiator S-1 shown below | 0.60 parts by mass |
| Leveling agent (compound T-1 shown below) | 0.10 parts by mass |
| Methyl ethyl ketone (solvent) | 200.00 parts by mass |
| Cyclopentanone (solvent) | 200.00 parts by mass |

Liquid crystal compound L-1 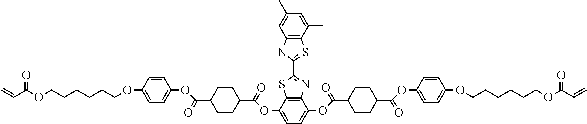
Liquid crystal compound L-2 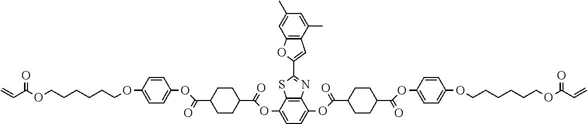 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]
The leveling agent T-1 (The numerical value in each repeating unit represents the
content (% by mass) with respect to all the repeating units, the content of the repeating unit on
the left side is 32.5% by mass, and the content of the repeating unit on the right side is 67.5%
by mass.) 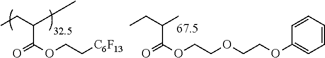
Polymerization initiator S-1

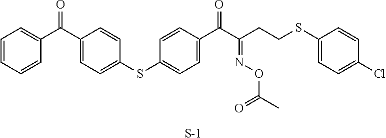

Next, the coating liquid A-1 for forming a positive A-plate was coated on the photoalignment layer 1 using a bar coater. The obtained coating film was heat-aged at a film surface temperature of 100° C. for 20 seconds, cooled to 90° C., and then irradiated with ultraviolet rays of 300 mJ/cm² using an air-cooled metal halide lamp (manufactured by Eye Graphics Co., Ltd.) under air to immobilize the nematic alignment state to form an optically anisotropic layer 1 (positive A-plate A1), thereby obtaining an optically anisotropic film 1.

The formed optically anisotropic layer 1 had a Re (550) of 150 run, a Re (550)/Re (450) of 1.18, a Re (650)/Re (550) of 1.03 and a tilt angle of an optical axis of 0°, and the liquid crystal compound had a homogeneous alignment.

(Preparation of Optically Anisotropic Film 2)

An optically anisotropic film 2 was prepared according to the same procedure as in the section of (Preparation of optically anisotropic film 1), except that a coating liquid A-2 for forming a positive A-plate shown below was used instead of the coating liquid A-1 for forming a positive A-plate.

Coating liquid A-2 for forming a positive A-plate

| | | |
|---|---|---|
| Liquid crystal compound L-2 as | 100.00 | parts by mass |
| described above | | |
| Polymerization initiator S-1 as | 0.60 | parts by mass |
| described above | | |
| Leveling agent (compound T-1 as | 0.10 | parts by mass |
| described above) | | |
| Methyl ethyl ketone (solvent) | 200.00 | parts by mass |
| Cyclopentanone (solvent) | 200.00 | parts by mass |

(Preparation of Optically Anisotropic Film 3)

An optically anisotropic film 3 was prepared according to tire same procedure as in the section of (Preparation of optically anisotropic film 1), except that, a coating liquid A-3 for forming a positive A-plate shown below was used instead of the coating liquid A-1 for forming a positive A-plate.

Coating liquid A-3 for forming a positive A-plate

| | |
|---|---|
| Liquid crystal compound L-3 shown below | 100.00 parts by mass |
| Polymerization intiator S-1 as described above | 0.60 parts by mass |
| Leveling agent (compound T-1 as described above) | 0.10 parts by mass |
| Methyl ethyl ketone (solvent) | 200.00 parts by mass |
| Cyclopentanone (solvent) | 200.00 parts by mass |

Liquid crystal compound L-3

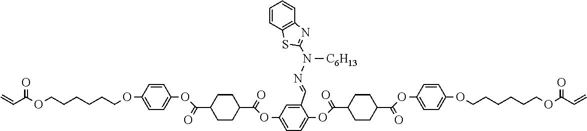

(Preparation of Optically Anisotropic Film 4)

An optically anisotropic film 4 was prepared according to the same procedure as in the section of (Preparation of optically anisotropic film 1), except that a coating liquid A-4 for forming a positive A-plate shown below was used instead of the coating liquid A-1 for forming a positive A-plate.

Coating liquid A-4 for forming a positive A-plate

| | |
|---|---|
| Liquid crystal compound L-4 shown below | 100.00 parts by mass |
| Polymerization initiator S-1 as described above | 0.60 parts by mass |
| Leveling agent (compound T-1 as described above) | 0.10 parts by mass |
| Methyl ethyl ketone (solvent) | 200.00 parts by mass |
| Cyclopentanone (solvent) | 200.00 parts by mass |

Liquid crystal compound L-4

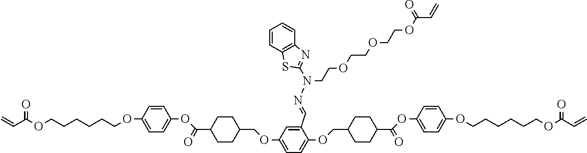 [SMILES: C=CC(=O)OCCCCCCOc1ccc(OC(=O)C2CCC(COc3ccc(OCC4CCC(C(=O)Oc5ccc(OCCCCCCOC(=O)C=C)cc5)CC4)c(/C=N/N(CCOCCOCCOC(=O)C=C)c4nc5ccccc5s4)c3)CC2)cc1]

(Preparation of Optically Anisotropic Film 5)

An optically anisotropic film 5 was prepared according to the same procedure as in the section of (Preparation of optically anisotropic film 1), except that a coating liquid A-5 for forming a positive A-plate shown below was used instead of the coating liquid A-1 for forming a positive A-plate.

Coating liquid A-5 for forming a positive A-plate

| | |
|---|---|
| Liquid crystal compound L-5 shown below | 50.00 parts by mass |
| Liquid crystal compound L-6 shown below | 50.00 parts by mass |
| Polymerization initiator S-1 as described above | 0.60 parts by mass |
| Leveling agent (compound T-1 as described above) | 0.10 parts by mass |
| Methyl ethyl ketone (solvent) | 200.00 parts by mass |
| Cyclopentanone (solvent) | 200.00 parts by mass |

Liquid crystal compound L-5 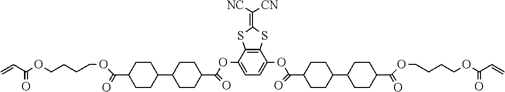 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Liquid crystal compound L-6

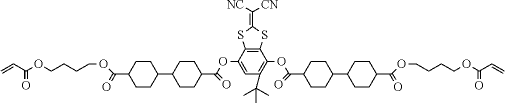 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]

(Preparation of Laminate 25B)

The pressure sensitive adhesive sheet 17 was bonded to tire optically anisotropic layer side of the optically anisotropic film 1 to prepare a laminate 25B.

(Preparation of Polarizing Plate)

A polyvinyl alcohol film having a thickness of 30 μm (average degree of polymerization of about 2,400, saponification degree of 99.9 mol % or more) was monoaxially stretched about 4 times by dry stretching, immersed in pure water at 40° C. for 40 seconds while maintaining a state of tension, and then immersed in a dyeing aqueous solution having a mass ratio of iodine/potassium iodide/water of 0.044/5.7/100 at 28° C. for 30 seconds for a dyeing treatment. Then, the obtained film was immersed in a boric acid aqueous solution having a mass ratio of potassium iodide/boric acid/water of 11.0/6.2/100 at 70° C. for 120 seconds. Subsequently, the obtained film was washed with pure water at 8° C. for 15 seconds, and then dried at 60° C. for 50 seconds and then at 75° C. for 20 seconds while being held at a tension of 300 N to obtain a polarizer layer having a thickness of 12 μm in which iodine was adsorbed and aligned on the polyvinyl alcohol film.

A water-based adhesive was injected between the obtained polarizer layer and the cycloolefin polymer film (COP film, ZF-4 manufactured by Zeon Corporation (having no UV absorption characteristics), thickness: 30 μm), followed by bonding with a nip roll. While maintaining the tension of the obtained bonded structure at 430 N/m, the bonded structure was dried at 60° C. for 2 minutes to obtain a 42 μm polarizing plate having a COP film as a protective film on one side thereof.

The water-based adhesive was prepared by adding a carboxyl group-modified polyvinyl alcohol (KURARAY POYAL KL318, manufactured by Kuraray Co., Ltd.) (3 parts by mass) and a water-soluble polyamide epoxy resin (SUMIREZ RESIN 650; an aqueous solution having a concentration of solid contents of 30% by mass, manufactured by Sumika Chemtex Co., Ltd.) (1.5 parts by mass) to water (100 parts by mass).

(Preparation of Laminate 25)

The polarizer layer side of the above prepared polarizing plate on which the COP film was arranged on one side thereof was corona-treated, and the pressure sensitive adhesive sheet of the laminate 25B was bonded to prepare a laminate 25.

At this time, the bonding was carried out such that the angle formed by the absorption axis of the polarizer layer and the slow axis of the positive A-plate contained in the optically anisotropic film contained in the laminate 25B was 45°.

(Preparation of Laminates 26 to 38)

Laminates 26 to 38 were prepared in the same manner as in the laminate 25, except that the type of the pressure sensitive adhesive sheet and the type of the optically anisotropic layer were changed as shown in Table 3.

(Evaluation of Light Resistance)

Under the following light resistance evaluation conditions, the light resistance of the optically anisotropic layer was evaluated by irradiation with light from the COP side of each of the laminates 25 to 38.

Testing machine: low temperature cycle xenon weather meter (XL75, manufactured by Suga Test Instruments Co., Ltd.)

Irradiation conditions: 100 lux (40 W/m²)

Temperature and humidity: 23° C., 1-50% RH

Irradiation, time: 4 days

Using an AxoScan (OPMF-1, manufactured by Axometrics, Inc.), the durability of the in-plane retardation (Re) of the optically anisotropic layer at a wavelength of 550 nm was evaluated by the following indicator. The following rate of change of Re is a value calculated by {(Re before light resistance evaluation−Re after light resistance evaluation)/Re before light resistance evaluation}×100. The results are shown in Table 3.

AA: The rate of change of Re is less than 1.5%

A: The rate of change of Re is 1.5% or more and less than 3%

B: The rate of change of Re is 3% or more

TABLE 3

| | Pressure-sensitive adhesive sheet | | | | | | | |
|---|---|---|---|---|---|---|---|---|
| | | Type of | | | Optically anisotropic layer | | Light | |
| | Thickness | (meth)acrylic | Specific compound | | Coating | Liquid crystal | resistance | Remarks |
| Laminate | (μm) | resin | Type | Amount | liquid | compound | evaluation | Inventive |
| 1 | 5 | B | UV-1 | 5.6 | A-1 | L-1/L-2 | A | Invertive |
| 2 | 5 | B | UV-2 | 5.6 | A-1 | L-1/L-2 | A | Inventive |
| 3 | 10 | B | UV-2 | 5.6 | A-1 | L-1/L-2 | AA | Inventive |
| 4 | 20 | B | UV-2 | 5.6 | A-1 | L-1/L-2 | AA | Inventive |
| 5 | 10 | B | UV-2 | 2.8 | A-1 | L-1/L-2 | A | Inventive |
| 6 | 20 | B | UV-2 | 2.8 | A-1 | L-1/L-2 | AA | Inventive |
| 7 | 5 | B | UV-3 | 5.6 | A-1 | L-1/L-2 | A | Inventive |
| 8 | 5 | B | — | — | A-1 | L-1/L-2 | B | Inventive |
| 9 | 5 | B | UV-2 | 5.6 | A-2 | L-2 | A | Comparative |
| 10 | 5 | B | UV-2 | 5.6 | A-3 | L-3 | A | Inventive |
| 11 | 5 | B | UV-2 | 5.6 | A-4 | L-4 | A | Inventive |
| 12 | 5 | B | UV-2 | 5.6 | A-5 | L-5/L-6 | AA | Inventive |
| 13 | 5 | A | UV-2 | 5.6 | A-1 | L-1/L-2 | A | Inventive |
| 14 | 5 | C | UV-2 | 5.6 | A-1 | L-1/L-2 | A | Inventive |

The amount of the specific compound in Table 3 represents parts by mass with respect to 100 parts by mass of the (meth)acrylic resin.

The laminate containing the pressure sensitive adhesive sheet according to the embodiment of the present invention showed an excellent effect of improving light resistance. It was confirmed that a sufficient effect can be obtained with an addition amount that does not cause precipitation of the specific compound, even in a case where the thickness of the pressure sensitive adhesive sheet is 5 μm.

### Preparation Example 39

(Preparation of Positive C-Plate C1)

The transparent resin film 1 was used as a temporary support.

After passing the transparent resin film 1 through a dielectric heating roll at a temperature of 60° C. to raise the film surface temperature to 40° C., an alkaline solution having the composition shown below was coated on one side of the film using a bar coater at a coating amount of 14 ml/m², followed by heating to 110° C., and transportation under a steam type far-infrared heater manufactured by Noritake Company Limited for 10 seconds.

Next, pure water was coated on the film at 3 ml/m² using the same bar coater.

Next, after repeating washing with water with a fountain coater and draining with an air knife three times, the film was transported to a drying zone at 70° C. for 10 seconds and dried to prepare a transparent resin film 1 subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Fluorine-based surfactant SF-1 | | |
| (C₁₄H₂₉O(CH₂CH₂₀)₂₀H) | 1.0 | parts by mass |
| Propylene glycol | 14.8 | parts by mass |

A coating liquid 2 for forming an alignment layer having the following composition was continuously coated on the transparent resin film 1 which had been subjected to an alkali saponification treatment, using a wire bar of #8. The obtained film was (dried with hot air at 60° C. for 60 seconds and further with hot air at 100° C. for 120 seconds to form an alignment layer.

Coating liquid 2 for forming an alignment layer

| | | |
|---|---|---|
| Polyvinyl alcohol | 2.4 | parts by mass |
| (PVA103, manufactured by Kuraray | | |
| Co., Ltd.) | | |
| Isopropyl alcohol | 1.6 | parts by mass |
| Methanol | 36 | parts by mass |
| Water | 60 | parts by mass |

A coating liquid C1 for forming a positive C-plate, which will be described later, was coated on the alignment layer. The obtained coating film was aged at 60° C. for 60 seconds, and then, irradiated with ultraviolet rays of 1,000 mJ/cm² using an air-cooled metal halide lamp (manufactured by Eye Graphics Co., Ltd.) of 70 mW/cm² under air to immobilize an alignment state thereof to bring the liquid crystal compound into vertical alignment to prepare an optical film 1 containing a positive C-plate C1 having a thickness of 0.5 μm.

The Rth (550) of the obtained positive C-plate was −60 nm.

Coating liquid C1 for forming a positive C-plate

| | | |
|---|---|---|
| Liquid crystal compound L-11 shown below | 80 | parts by mass |
| Liquid crystal compound L-12 shown below | 20 | parts by mass |
| Liquid crystal compound vertical alignment agent (S01) shown below | 1 | part by mass |
| Ethylene oxide-modified trimethylolpropane triacrylate | | |
| (V# 360, manufactured by Osaka Organic Chemical Industry Ltd.) | 8 | parts by mass |
| IRGACURE 907 (manufactured by BASF SE) | 3 | parts by mass |
| KAYACURE DETX (manufactured by Nippon Kayaku Co., Ltd.) | 1 | part by mass |
| Compound B03 shown below | 0.4 | parts by mass |
| Methyl ethyl ketone | 170 | parts by mass |
| Cyclohexanone | 30 | parts by mass |

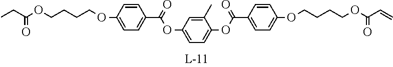 [SMILES: C=CC(=O)OCCCCOc1ccc(C(=O)Oc2ccc(OC(=O)c3ccc(OCCCCOC(=O)CC)cc3)cc2C)cc1]

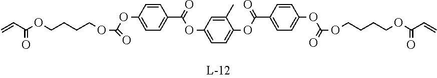 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

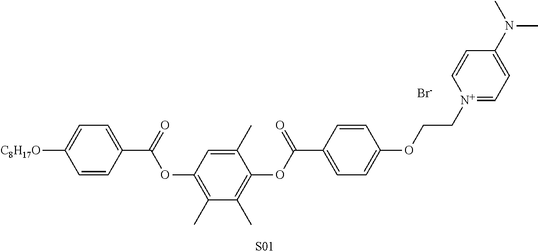

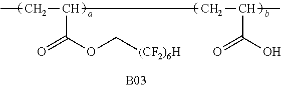

The above a and h represent the content (% by mass) of each repeating unit with respect to all the repeating units, a represents 90% by mass, and b represents 10% by mass.

(Preparation of UV Adhesive)

The following UV adhesive was prepared.

UV adhesive

| | |
|---|---|
| CEL2021P (manufactured by Daicel Corporation) | 70 parts by mass |
| 1,4-Butanediol diglycidyl ether | 20 parts by mass |
| 2-Ethylhexyl glycidyl ether | 10 parts by mass |
| CPI-100P | 2.25 parts by mass |

CPI-100P

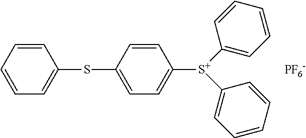

(Preparation of Retardation Plate 1)

The optically anisotropic layer side of the optically anisotropic film 1 and the positive C-plate C1 side of the optical film 1 were bonded to each other by UV light irradiation of 600 mJ/cm² using the UV adhesive. Hereinafter, the UV adhesive was used under the same conditions. The thickness of the UV adhesive layer was 3 μm. The surfaces to be bonded with the UV adhesive were each subjected to a corona treatment (the same applies hereinafter). Next, the photoalignment layer 1 on the optically anisotropic film 1 side and the transparent resin film 1 were removed to obtain a retardation plate 1.

(Preparation of Polarizing Film 1 Using Dichroic Coloring Agent)

A composition E1 for forming a photoalignment layer was prepared with the following composition, dissolved for 1 hour with stirring, and filtered through a 0.45 μm filter.

Composition E1 for forming a photoalignment layer

| | |
|---|---|
| Photoactive compound E-4 shown below | 5.0 parts by mass |
| Cyclopentanone | 95.0 parts by mass |

Photoactive compound E-4 (weight-average molecular weight: 51,000)

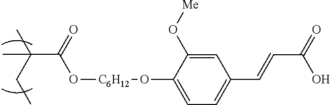

A composition P1 for forming a tight absorption anisotropic layer was prepared with the following composition, dissolved by heating at 80° C. for 2 hours with stirring, and filtered through a 0.45 μm filter.

Composition P1 for forming a light absorption anisotropic layer

| | |
|---|---|
| Dichroic coloring agent D1 shown below | 2.7 parts by mass |
| Dichroic coloring agent D2 shown below | 2.7 parts by mass |
| Dichroic coloring agent D3 shown below | 2.7 parts by mass |
| Liquid crystal compound M1 shown below | 73.0 parts by mass |
| Polymerization initiator IRGACURE 369 (manufactured by BASF SE) | 3.0 parts by mass |
| BYK361N (manufactured by BYK-Chemie Japan KK) | 0.9 parts by mass |
| Cyclopentanone | 925.0 parts by mass |

Dichroic coloring agent D1 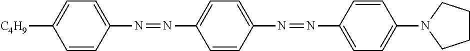
Dichroic coloring agent D2 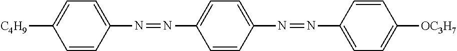
Dichroic coloring agent D3 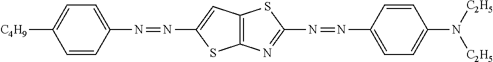
Liquid crystal compound M1 (mixture of compound A/compound B = 75/25)
(Compound A) 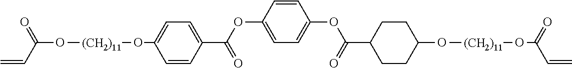
(Compound B)

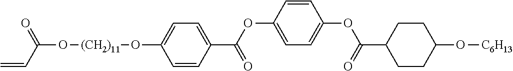

The composition E1 for forming a photoalignment layer was coated on the transparent resin film 1 and dried at 60° C. for 2 minutes. Then, the obtained coating film was irradiated with linearly polarized ultraviolet rays (illuminance: 4.5 mW, irradiation amount: 500 mJ/cm²) using a polarized ultraviolet exposure device to prepare a photoalignment layer E1.

The composition P1 for forming a light absorption anisotropic layer was coated on the obtained photoalignment layer E1 with a wire bar. Next, the obtained coating film was heated at 120° C. for 60 seconds and cooled to room temperature.

Then, a light absorption anisotropic layer P1 having a thickness of 1.7 μm was formed by irradiating with a high-pressure mercury lamp for 60 seconds under an irradiation condition of an illuminance of 28 m W/cm².

It was confirmed that the liquid crystal of the light absorption anisotropic layer was a smectic B phase.

(Formation of Protective Layer)

A solution (composition for forming a protective layer), which was prepared by dissolving dipentaerythritol hexaacrylate (ARONIX M-403, manufactured by Toagosei Co., Ltd.) (50 parts by mass), an acrylate resin (EBECRYL 4858, manufactured by Daicel-UCB Co., Ltd.) (50 parts by mass), and 2-[4-(methylthio)benzoyl]-2-(4-morpholinyl)propane (IRGACURE 907, manufactured by BASF SE) (3 parts by mass) in isopropanol (250 parts by mass), was coated on the formed light absorption anisotropic layer FI by a bar coating method, and heated and dried in a drying oven at 50° C. for 1 minute.

The obtained coating film was irradiated with ultraviolet rays using an ultraviolet (UV) irradiation device (SPOT CURE SP-7, manufactured by Ushio Inc.) at an exposure amount of 400 mJ/cm² (365 nm standard) to form a protective layer on the light absorption anisotropic layer P1 to prepare a polarizing film 1 containing the light absorption anisotropic layer P1.

(Preparation of Laminate of Preparation Example 39)

The protective layer side of the polarizing film 1 was bonded to the support side of a low-reflection surface film. CV-LC5 (manufactured by FUJIFILM Corporation.) using the pressure sensitive adhesive sheet 19. Next, the transparent resin film 1 of the polarizing film 1 and the photoalignment layer E1 were removed, and the removed surface and the positive A-plate A1 side of the retardation plate 1 were bonded to each other using the pressure sensitive adhesive sheet 19 to prepare a laminate 39 having the low-reflection surface film CV-LC5, the pressure sensitive adhesive sheet 19, the protective layer, the light absorption anisotropic layer P1, the pressure sensitive adhesive sheet 19, the positive A-plate A1, and the positive C-plate C1 in this order. At this time, the bonding was carried out such that the angle formed by the absorption axis of the light absorption anisotropic layer and the slow axis of the positive A-plate A1 was 45°.

### Preparation Example 40

The protective layer side of the polarizing film 1 was bonded to the support side of a low-reflection, surface film CV-LC5 (manufactured by FUJIFILM Corporation) using the pressure sensitive adhesive sheet 19. Next, the transparent resin film 1 and the photoalignment layer E1 were removed, and the removed surface and the positive. A-plate A1 side of the retardation plate 1 were bonded to each other using the pressure sensitive adhesive sheet 24 to prepare a laminate 40 having the low-reflection surface film CV-LC5, the pressure sensitive adhesive sheet 19, the protective layer, the light absorption anisotropic layer P1, the pressure sensitive adhesive sheet 24, the positive A-plate A1, and the positive C-plate C1 in. this order. At this time, the bonding was carried out such that the angle formed by the absorption axis of the light absorption anisotropic layer and the slow axis of the positive. A-plate A1 was 45°.

### Preparation Example 41

A coating liquid PA1 for forming an alignment layer, which will be described later, was continuously coated on the transparent, resin film 1 with a wire bar. The support on which the coating film was formed was dried with hoi air at 140° C. for 120 seconds, and then the coating film was irradiated with polarized ultraviolet rays (10 mJ/cm², using an ultra-high pressure mercury lamp) to form a photoalignment layer PA1, thereby obtaining a TAG film with the photoalignment layer PA1.

The film thickness of the photoalignment layer PA1 was 1.0 μm.

Coating liquid PA1 for forming an alignment layer

| | |
|---|---|
| Polymer PA-1 shown below | 100.00 parts by mass |
| Acid generator PAG-1 shown below | 5.00 parts by mass |
| Acid generator CPI-110TF shown below | 0.005 parts by mass |
| Xylene | 1220.00 parts by mass |
| Methyl isobutyl ketone | 122.00 parts by mass |

Polymer PA-1 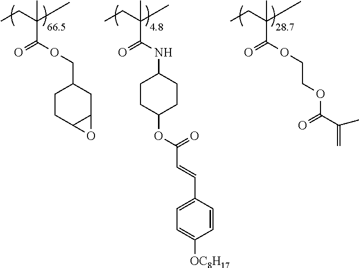
Acid generator PAG-1 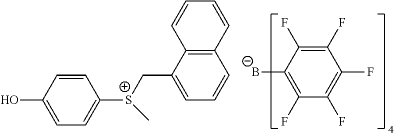
Acid generator CPI-110F

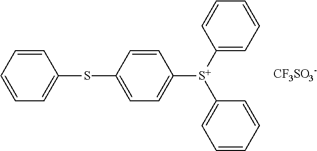

In the above formulae, the numerical value in each repeating unit represents the content (% by mass) with respect to all the repeating units, the content of the repeating unit on the left side is 66.5% by mass, the content of the repeating unit in the middle is 4.8% by mass, and the content of the repeating unit on the right side is 28.7% by mass.

The following composition P2 for forming a light absorption anisotropic layer was continuously coated on the obtained photoalignment layer PA1 with a wire bar to form a coating film P2.

Next, the coating film P2 was heated at 140° C. for 30 seconds, and then the coating film P2 was cooled to room temperature (23° C.).

Next, the obtained coating film P2 was heated at 90° C. for 60 seconds and cooled again, to room temperature.

Then, a light absorption anisotropic layer P2 was prepared on the photoalignment layer PA1 by irradiating with a light emitting diode (LED) lamp (central wavelength: 365 nm) for 2 seconds under an irradiation condition of an illuminance of 200 mW/cm².

The film thickness of the light absorption anisotropic layer P2 was 0.4 μm.

Composition P2 for forming a light absorption anisotropic layer

| | |
|---|---|
| Dichroic coloring agent D-4 shown below | 0.36 parts by mass |
| Dichroic coloring agent D-5 shown below | 0.53 parts by mass |
| Dichroic coloring agent D-6 shown below | 0.31 parts by mass |
| High molecular weight liquid crystal compound P-1 shown below | 3.58 parts by mass |
| Polymerization initiator IRGACURE OXE-02 (manufactured by BASF SE) | 0.050 parts by mass |
| Surfactant F-1 shown below | 0.026 parts by mass |
| Cyclopentanone | 45.00 parts by mass |
| Tetrahydrofuran | 45.00 parts by mass |
| Benzyl alcohol | 5.00 parts by mass |

Dichroic coloring agent D-4 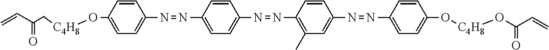
Dichroic coloring agent D-5 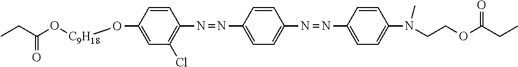
Dichroic coloring agent D-6 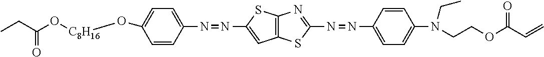
High molecular weight liquid crystal compound P-1

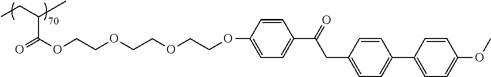

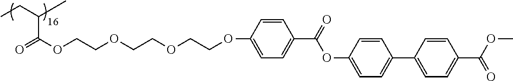

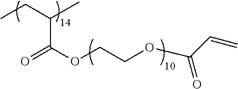

In the above formulae, the numerical value in each repeating unit represents the content (% by mass) with respect to all the repeating units, the content of the top repeating unit is 70% by mass, the content of the middle repeating unit is 16% by mass, and the content of the bottom repeating unit is 14% by mass.

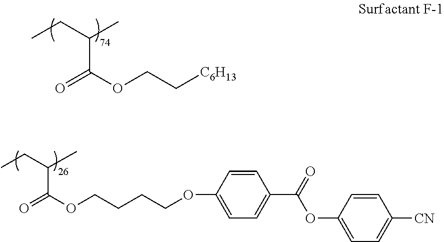

In the above formulae, the numerical value in each repeating unit represents the content (% by mass) with respect to all the repeating units, the content of the repeating unit on the left side is 74% by mass, and the content of the repeating unit on the right side is 26% by mass.

The following composition N1 for forming a cured layer was continuously coated on the obtained light absorption anisotropic layer P2 with a wire bar to form a coating film.

Next, the coating film was dried at room temperature, and then irradiated for 15 seconds under an irradiation condition of an illuminance of 28 mW/emf using a high-pressure mercury lamp to prepare a cured layer N1 on the light, absorption anisotropic layer P2.

The film thickness of the cured layer N1 was 0.05 μm.

Composition N1 for forming a cured layer

| | |
|---|---|
| Mixture L1 of rod-like liquid crystal compounds shown below | 2.61 parts by mass |
| Modified trimethylolpropane triacrylate shown below | 0.11 parts by mass |
| Photopolymerization initiator I-1 shown below | 0.05 parts by mass |
| Surfactant F-3 shown below | 0.21 parts by mass |
| Methyl isobutyl ketone | 297 parts by mass |

Mixture L1 of rod-like liquid crystal compounds (The numerical value in the following
formulae represents % by mass, and R represents a group bonded through an oxygen atom.) 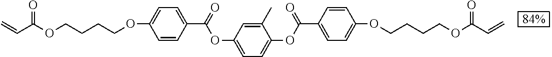 [SMILES: C=CC(=O)OCCCCOc1ccc(C(=O)Oc2ccc(OC(=O)c3ccc(OCCCCOC(=O)C=C)cc3)c(C)c2)cc1] 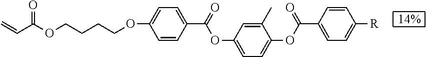 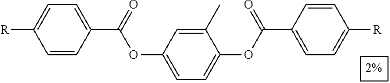 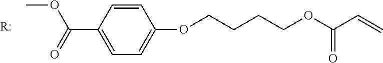
Modified trimethylolpropane triacrylate 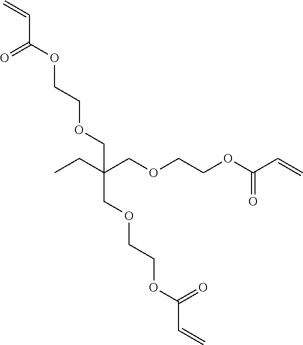 [SMILES: C=CC(=O)OCCOCC(CC)(COCCOC(=O)C=C)COCCOC(=O)C=C]
Photopolymerization initiator I-1 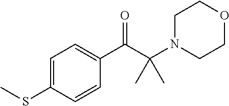 [SMILES: CSc1ccc(C(=O)C(C)(C)N2CCOCC2)cc1]
Surfactant F-3

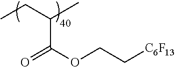

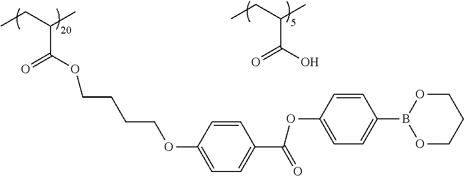

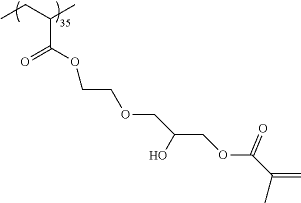

In the above formulae, the numerical value in each repeating unit represents the content (% by mass) with respect to all the repeating units, and the content of each repeating unit is 40% by mass, 20% by mass, 5% by mass, and 35% by mass from the left side.

The following composition B1 for forming an oxygen blocking layer was continuously coated on the cured layer N1 with a wire bar. This was followed by drying with hot air at 100° C. for 2 minutes to prepare a polarizing film 2 having an oxygen blocking layer having a thickness of 1.0 μm formed on the cured layer N1.

Composition B1 for forming an oxygen blocking layer

| | |
|---|---|
| Modified polyvinyl alcohol shown below | 3.80 parts by mass |
| Initiator Irg2959 | 0.20 parts by mass |
| Water | 70 parts by mass |
| Methanol | 30 parts by mass |

Modified polyvinyl alcohol

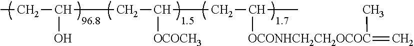

The oxygen blocking layer side of the polarizing film 2 was bonded to the support side of a low-reflection surface film CV-LC5 (manufactured by FUJIFILM Corporation) using the pressure sensitive adhesive sheet 19. Next, only the transparent resin film 1 of the polarizing film 2 was removed, and the removed surface and the positive A-plate A1 side of the retardation plate 1 were bonded to each other using the pressure sensitive adhesive sheet 19 to prepare a laminate 41 having the low-reflection surface film CV-LC5, the pressure sensitive adhesive sheet 19, the oxygen blocking layer, the cured layer N1, the light absorption anisotropic layer P2, the pressure sensitive adhesive sheet 19, the positive A-plate A1, and the positive C-plate C1 in this order. At this time, the bonding was carried out such that the angle formed by the absorption axis of the light absorption anisotropic layer and the slow axis of the positive A-plate A1 was 45°.

### Preparation Example 42

The oxygen blocking layer side of the polarizing film 2 was bonded to the support side of a low-reflection surface film CV-LC5 (manufactured by FUJIFILM Corporation) using the pressure sensitive adhesive sheet 24. Next, only the transparent resin film 1 of the polarizing film 2 was removed, and the removed surface and the positive A-plate A1 side of the retardation plate 1 were bonded to each other using the pressure sensitive adhesive sheet 19 to prepare a laminate 17 having the low-reflection surface film CV-LC5, the pressure sensitive adhesive sheet 24, the oxygen blocking layer, the cured layer N1, the light absorption anisotropic layer P2, the pressure sensitive adhesive sheet 19, the positive A-plate A1, and the positive C-plate C1 in this order. At this time, the bonding was carried out such that the angle formed by the absorption axis of the light absorption anisotropic layer and the slow axis of the positive A-plate A1 was 45°.

<Evaluation>

(Preparation of Organic EL Display Device)

The SAMSUNG GALAXY S4 equipped with an organic EL display panel (organic EL display element) was disassembled, a touch panel with a circularly polarizing plate was peeled off from the organic EL display device, and the circularly polarizing plate was further peeled off from the touch panel to isolate the organic EL display element, the touch panel, and the circularly polarizing plate, respectively. Next, the isolated touch panel was bonded again to the organic EL display element, and each of the laminates 39 to 42 was further bonded to the touch panel using the pressure sensitive adhesive N1 prepared by the following procedure, whereby organic EL display devices 39 to 42 were prepared.

At this time, the optically anisotropic layer was arranged closer to the organic EL display panel than the light absorption, anisotropic layer.

(Preparation of Pressure Sensitive Adhesive Sheet N1)

Next, an acrylate-based polymer was prepared according to the following procedure.

Butyl acrylate (95 parts by mass) and acrylic acid (5 parts by mass) were polymerized by a solution polymerization method in a reaction container equipped with a cooling pipe, a nitrogen introduction pipe, a thermometer, and a stirrer to obtain an acrylate-based polymer (A1) having an average molecular weight of 2,000,000 and a molecular weight distribution (Mw/Mn) of 3.0.

Next, the obtained acrylate-based polymer (A1) (100 parts by mass), an isocyanate-based crosslinking agent (1 part by mass) shown below, and a silane coupling agent (0.2 parts by mass) were mixed to prepare a composition. This composition was coated on a separate film surface-treated with a silicone-based release agent using a die coater, and the obtained coating film was dried in an environment of 90° C. for 1 minute to obtain a pressure sensitive adhesive sheet N1. The film thickness of the pressure sensitive adhesive sheet N1 was 25 μm.

Isocyanate-based crosslinking agent: trimethylolpropane-modified tolylene diisocyanate

(“CORONATE L” manufactured by Nippon Polyurethane Industry Co., Ltd.)

Silane coupling agent: 3-glycidoxypropyltrimethoxysilane (“KBM-403” manufactured by Shin-Etsu Chemical Co., Ltd.)

(Evaluation of Reflectivity)

In order to exclude the influence of surface reflection, the value measured by pasting a black glue (containing carbon black) having a high absorbance and not reflecting at all on the support side of a low-reflection surface film CV-LC5 (manufactured by FUJIFILM Corporation) was taken as the surface reflectivity.

The reflectivity (total reflection) of the organic EL display devices 39 to 42 was measured, and the value obtained by subtracting the surface reflectivity therefrom was taken as the effective reflectivity. Tills effective reflectivity serves as an indicator of an antireflection function of a circularly polarizing plate consisting of the light absorption anisotropic layer and the optically anisotropic layer.

For the total reflectivity, using a spectrophotometric colorimeter (manufactured by Konica Minolta, Inc.), the Y value of a display system under an observation condition of visual field of 10° and an observation light, source of D65 was taken as the total reflectivity.

(Evaluation of Photodurability)

Using a Super Xenon Weather Meter SX75 (manufactured by Suga Test Instruments Co., Ltd.), and in an environment of 60° C. and 50% RH, xenon irradiation for 150 hours at 150 W/m² was earned out on the laminates 39 to 42 from the low-reflection surface film side. Then, the effective reflectivity was evaluated in the same manner as above and the difference in effective reflectivity before and after xenon irradiation was evaluated according to the following standards.

A: The reflectivity difference is 0.2% or less

B: The reflectivity difference is greater than 0.2% and 0.5% or less

C: The reflectivity difference is greater than 0.5%

The amount of the specific compound in Table 4 represents parts by mass with respect to 100 parts by mass of the (meth)acrylic resin.

TABLE 4

| | | | | Light | | | | | |
|---|---|---|---|---|---|---|---|---|---|
| | | | | absorption | | | | Optically | |
| | Pressure sensitive adhesive sheet | | | anisotropic | Pressure-sensitive adhesive sheet | | | anisotropic layer | |
| | Thickness | Specific compound | | layer | Thickness | Specific compound | | Liquid crystal | Photodurability |
| Laminate | (μm) | Designation | Amount | Designation | (μm) | Designation | Amount | compound | evaluation |
| 39 | 5 | UV-2 | 5.6 | P1 | 5 | UV-2 | 5.6 | L-1/L-2 | A |
| 40 | 5 | UV-2 | 5.6 | P1 | 5 | — | | L-1/L-2 | B |
| 41 | 5 | UV-2 | 5.6 | P2 | 5 | UV-2 | 5.6 | L-1/L-2 | A |
| 42 | 5 | — | None | P2 | 5 | UV-2 | 5.6 | L-1/L-2 | B |

It was found that the antireflection function of the circularly polarizing plate can be maintained more even after xenon irradiation, by arranging the pressure sensitive adhesive sheet containing the specific compound used in the present invention on the low-reflection surface film side of the light absorption anisotropic layer, as shown in the laminates 39 and 41.

### EXPLANATION OF REFERENCES

100, 200, 300: laminate
1: pressure sensitive adhesive sheet
2: optically anisotropic layer
3: polarizer layer
4: pressure sensitive adhesive sheet
5: surface protective layer

What is claimed is:

1. A pressure sensitive adhesive sheet comprising:
a (meth)acrylic pressure sensitive adhesive; and
a compound represented by Formula (I),
wherein the (meth)acrylic pressure sensitive adhesive is formed of a (meth)acrylic resin, and
an absolute value of a difference between a log P value of the (meth)acrylic resin and a log P value of the compound represented by Formula (I) is 2.50 or more, 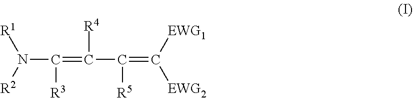
in Formula (I), EWG₁ and EWG₂ each independently represent a group having a Hammett's substituent constant op value of 0.20 or more, provided that EWG₁ and EWG₂ are not bonded to each other to form, a ring structure, R¹ and R² each independently represent an alkyl group, an aryl group, or a heteroaryl group, provided that R¹ and R² are not bonded to each other to form a ring structure, and R³, R⁴, and R⁵ each independently represent a hydrogen atom or a substituent.

2. The pressure sensitive adhesive sheet according to claim 1,
wherein the absolute value of the difference is 3.50 or more.

3. The pressure sensitive adhesive sheet according to claim 1,
wherein a maximal absorption wavelength of the compound represented by Formula (I) is in a range of 365 to 385 nm.

4. The pressure sensitive adhesive sheet according to claim 1,
wherein a content of the compound represented by Formula (I) is 2.5% to 30% by mass with respect to a total mass of the (meth)acrylic resin.

5. The pressure sensitive adhesive sheet according to claim 1,
wherein a content of the compound represented by Formula (I) is 5.5% to 20% by mass with respect to a total mass of the (meth)acrylic resin.

6. The pressure sensitive adhesive sheet according to claim 1,
wherein EWG₁ and EWG₂ each independently represent COOR⁶, SO₂R⁷, CN, or COR⁸, and
R⁶, R⁷, and R⁸ each independently represent, an alkyl group, an aryl group, or a heteroaryl group.

7. The pressure sensitive adhesive sheet according to claim 1,
wherein EWG₁ represents SO₂R⁷, EWG₂ represents COOR⁶, and R⁶ and R⁷ each independently represent an alkyl group, an aryl group, or a heteroaryl group.

8. The pressure sensitive adhesive sheet according to claim 1,
wherein the (meth)acrylic resin has a repeating unit derived from a (meth)acrylic acid ester monomer represented by Formula (A-1),
a content of the repeating unit derived from the (meth)acrylic acid ester monomer represented by Formula (A-1) is 70.0% to 99.9% by mass with respect to all the repeating units of the (meth)acrylic resin, and
a weight-average molecular weight of the (meth)acrylic resin is 300,000 to 3,000,000, 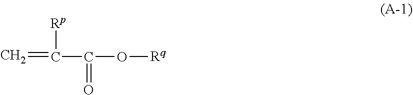
in Formula (A-1), R^{p} represents a hydrogen atom or a methyl group, R^{q} represents an alkyl group having 1 to 8 carbon atoms or an aralkyl group having 1 to 8 carbon atoms, a hydrogen atom constituting the alkyl group and the aralkyl group may be substituted with —O—(C₂H₄O)ₙ—R^{r}, n represents an integer of 0 to 4, and R^{r} represents an alkyl group having 1 to 12 carbon atoms or an aryl group having 1 to 12 carbon atoms.

9. The pressure sensitive adhesive sheet according to claim 1,
wherein the (meth)acrylic resin has a repeating unit derived from butyl acrylate, and
a content of the repeating unit derived from butyl acrylate is 50% to 99.9% by mass with respect to all the repeating units of the (meth)acrylic resin.

10. The pressure sensitive adhesive sheet according to claim 1,
wherein a thickness of the pressure sensitive adhesive sheet is less than 20 μm.

11. The pressure sensitive adhesive sheet according to claim 1,
wherein a thickness of the pressure sensitive adhesive sheet is less than 10 μm.

12. The pressure sensitive adhesive sheet according to claim 1,
wherein a thickness of the pressure sensitive adhesive sheet is 5 μm or less.

13. A laminate comprising:
the pressure sensitive adhesive sheet according to claim 1; and
an optically anisotropic layer formed of a composition containing a polymerizable liquid crystal compound exhibiting reverse wavelength dispersibility.

14. The laminate according to claim 13,
wherein the polymerizable liquid crystal compound includes a polymerizable liquid crystal compound having a partial structure represented by Formula (II):
*-D₁-Ar-D₂-* (II)
in Formula (II),
D₁ and D₂ each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR⁴—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms, and in a case where there are a plurality of each of R¹'s, R²'s, R³'s, and R⁴'s the plurality of R¹'s, the plurality of R²'s, the plurality of R³'s, and the plurality of R⁴'s each may be the same as or different from each other, and
Ar represents any aromatic ring selected from the group consisting of groups represented by Formulae (Ar-1) to (Ar-7), 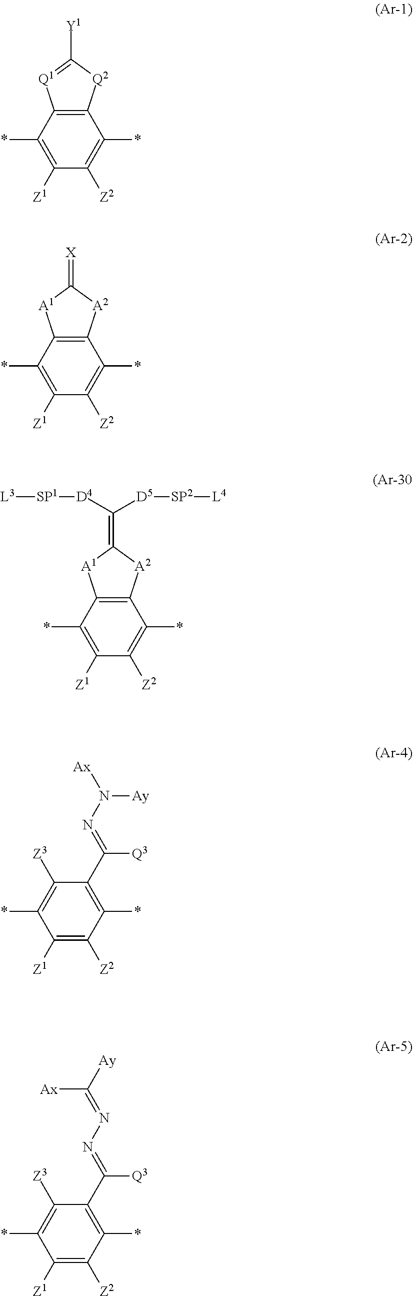 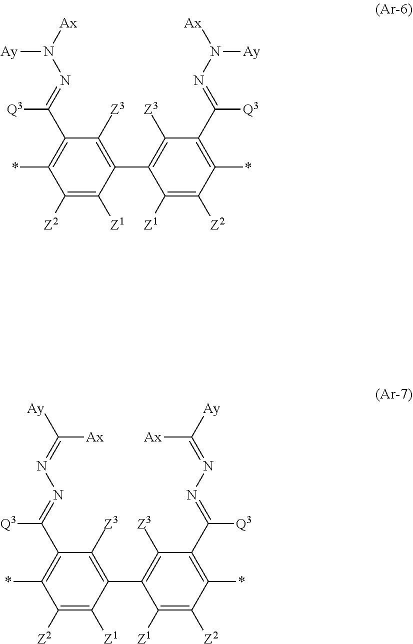
Q¹ represents N or CH,
Q² represents —S—, —O—, or —N(R⁷)—, and R⁷ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring,
A¹ and A² each independently represent a group selected from the group consisting of —O—, —N(R¹²)—, —S—, and —CO—, and R¹² represents a hydrogen atom or a substituent,
X represents a non-metal atom of Groups 14 to 16 to which a hydrogen atom, or a substituent may be bonded,
D⁴ and D⁵ each independently represent a single bond or —CO—, —O—, —S—, —C(═S)—, —CR^{1a}R^{2a}—, —CR^{3a}═CR^{4a}—, —NR^{5a}—, or a divalent linking group consisting of two or more combinations of these groups, and R^{1a} to R^{5a} each independently represent a hydrogen atom, a fluorine atom, or an alkyl group having 1 to 4 carbon atoms,
SP¹ and SP² each independently represent a single bond, a linear or branched alkylene group having 1 to 12 carbon atoms, or a divalent linking group in which one or more of —CH₂— constituting a linear or branched alkylene group having 1 to 12 carbon atoms are substituted with —O—, —S—, —NH—, —N(Q)-, or —CO—, and Q represents a substituent,
L³ and L⁴ each independently represent a monovalent organic group,
Ax represents an organic group having 2 to 30 carbon atoms which has at least one aromatic ring selected from the group consisting of an aromatic hydrocarbon ring and an aromatic heterocyclic ring,
Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring,
the aromatic rings in Ax and Ay may have a substituent, and Ax and Ay may be bonded to each other to form a ring,
Q³ represents a hydrogen atom or an alkyl group having 1 to 6 carbon atoms which may have a substituent, and
represents a bonding position.

15. The laminate according to claim 13, further comprising a polarizer layer.

16. The laminate according to claim 15,
wherein the laminate has the polarizer layer, the pressure sensitive adhesive sheet, and the optically anisotropic layer in this order.

17. The laminate according to claim 15,
wherein the polarizer layer is a polarizer layer having a dichroic coloring agent.

18. The laminate according to claim 15,
wherein the laminate has a first pressure sensitive adhesive sheet, the polarizer layer, a second pressure sensitive adhesive sheet, and the optically anisotropic layer in this order, and
at least one of the first pressure sensitive adhesive sheet or the second pressure sensitive adhesive sheet is the pressure sensitive adhesive sheet.

19. A display device comprising the laminate according to claim 13.

20. An organic electroluminescent display device comprising the laminate according to claim 13.
